(19) United States
(12) Patent Application Publication
(10) Pub. No.: US 2025/0022796 A1
(43) Pub. Date: Jan. 16, 2025

(54) SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP); Keigo MINODE, Kyoto-shi (JP)

(73) Assignee: ROHM CO., LTD., Kyoto-shi (JP)

(21) Appl. No.: 18/900,908

(22) Filed: Sep. 30, 2024

Related U.S. Application Data
(63) Continuation of application No. PCT/JP2023/006632, filed on Feb. 24, 2023.

(30) Foreign Application Priority Data
Mar. 31, 2022 (JP) 2022-061315

(51) Int. Cl. H01L 23/522; H01L 27/088; H01L 29/16; H01L 29/423; H01L 29/78

(52) U.S. Cl. CPC H01L 23/5228; H01L 27/088; H01L 29/4236; H01L 29/7813; H01L 29/1608

(57) ABSTRACT

A semiconductor device includes a chip having a main surface, a trench resistance structure formed in the main surface, a gate pad that has a resistance value lower than that of the trench resistance structure and that is arranged on the trench resistance structure so as to be electrically connected to the trench resistance structure, and a gate wiring line that has a resistance value lower than that of the trench resistance structure and that is arranged on the trench resistance structure so as to be electrically connected to the gate pad via the trench resistance structure.

### CROSS-REFERENCE TO RELATED APPLICATIONS

The present application is a bypass continuation of International Patent Application No. PCT/JP2023/006632, filed on Feb. 24, 2023, which claims priority to Japanese Patent Application No. 2022-061315 filed on Mar. 31, 2022, the entire disclosures of those applications are incorporated herein by reference.

### BACKGROUND

### 1. Field of the Disclosure

The present disclosure relates to a semiconductor device.

### 2. Description of the Related Art

US2017/0040423A1 discloses a semiconductor device that includes a semiconductor substrate, a plurality of trench structures, and a gate pad portion. The plurality of trench structures are formed in a front surface of the semiconductor substrate. The gate pad portion is arranged on the semiconductor substrate so as to cover the plurality of trench structures.

### BRIEF DESCRIPTION OF THE DRAWINGS

FIG. 1 is a plan view showing a semiconductor device according to an embodiment.

FIG. 2 is a cross-sectional view along line II-II shown in FIG. 1.

FIG. 3 is a plan view showing a layout of a gate electrode and a source electrode.

FIG. 4 is a plan view showing a layout of a first main surface.

FIG. 5 is an enlarged plan view showing a neighborhood of a resistive region.

FIG. 6 is an enlarged plan view showing a layout near the resistive region.

FIG. 7 is a cross-sectional view along line VII-VII shown in FIG. 6.

FIG. 8 is an enlarged plan view showing a layout of the resistive region and an active region.

FIG. 9 is an enlarged plan view showing a layout of the active region and a peripheral edge region.

FIG. 10 is a cross-sectional view along line X-X shown in FIG. 8.

FIG. 11 is a cross-sectional view along line XI-XI shown in FIG. 8.

FIG. 12 is a cross-sectional view along line XII-XII shown in FIG. 8.

FIG. 13 is a cross-sectional view along line XIII-XIII shown in FIG. 8.

FIG. 14 is a cross-sectional view along line XIV-XIV shown in FIG. 9.

FIG. 15 is a cross-sectional view along line XV-XV shown in FIG. 9.

FIG. 16 is a cross-sectional view along line XVI-XVI shown in FIG. 9.

FIG. 17 is a cross-sectional view along line XVII-XVII shown in FIG. 9.

FIG. 18 is an enlarged plan view showing a layout of the resistive region, the active region, and a dummy region.

FIG. 19 is an enlarged plan view showing a layout of the active region, the peripheral edge region, and the dummy region.

FIG. 20 is a cross-sectional view along line XX-XX shown in FIG. 18.

FIG. 21 is a cross-sectional view along line XXI-XXI shown in FIG. 18.

FIG. 22 is a cross-sectional view along line XXII-XXII shown in FIG. 18.

FIG. 23 is an enlarged plan view showing a layout of a termination region.

FIG. 24 is a cross-sectional view along line XXIV-XXIV shown in FIG. 23.

FIG. 25 is a cross-sectional view showing a structure of an outer peripheral region.

FIG. 26 is an electric circuit diagram showing a connection mode of the gate electrode and a gate resistance.

FIG. 27 is a cross-sectional view showing a trench resistance structure according to a first modification.

FIG. 28 is a cross-sectional view showing a trench resistance structure according to a second modification.

FIG. 29 is a cross-sectional view showing a trench resistance structure according to a third modification.

FIG. 30 is a cross-sectional view showing a trench resistance structure according to a fourth modification.

FIG. 31 is a cross-sectional view showing a chip according to the first modification.

FIG. 32 is a cross-sectional view showing a chip according to the second modification.

### DETAILED DESCRIPTION OF THE PREFERRED EMBODIMENTS

Embodiments will be hereinafter described in detail with reference to the accompanying drawings. The accompanying drawings are schematic views, and are not strictly shown, and do not necessarily coincide with each other in reduced scale and the like. Also, the same reference sign is assigned to a constituent that corresponds to each constituent in the accompanying drawings, and a duplicated description of this constituent is omitted or simplified. A description of a structure, which has not yet been omitted or simplified, is applied to a corresponding structure a description of which has been omitted or simplified.

If the term “substantially equal” is used in a description of the presence of a comparison target, this term also includes a numerical error (form error) within the range of ±10% based on a numerical value (form) of the comparison target in addition to the fact that this term includes a numerical value (form) equal to the numerical value (form) of the comparison target. Although the terms “first,” “second,” “third,” etc., are used in the embodiment, these are symbols assigned to the name of each structure in order to clarify the descriptive sequence, and are not assigned to the effect that these terms limit the name of each structure.

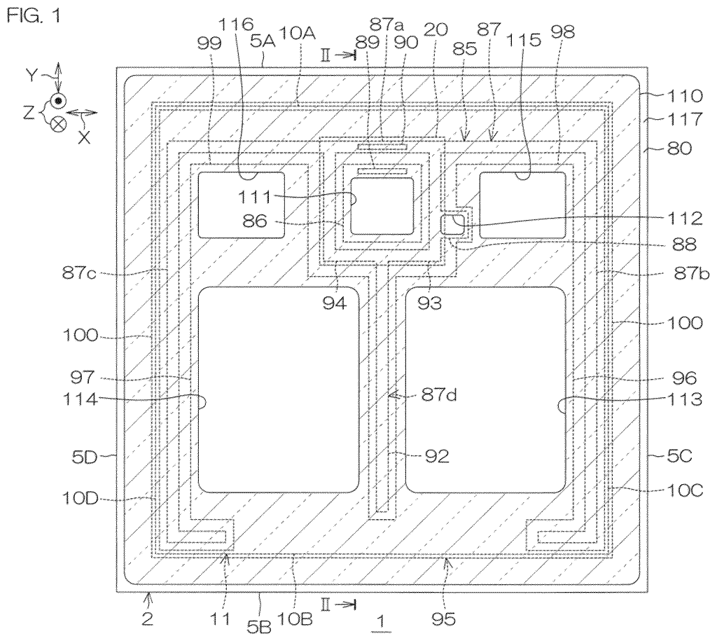

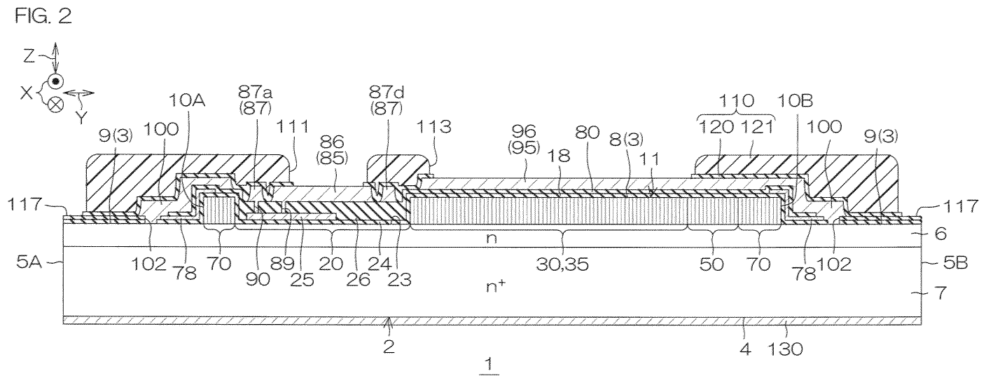

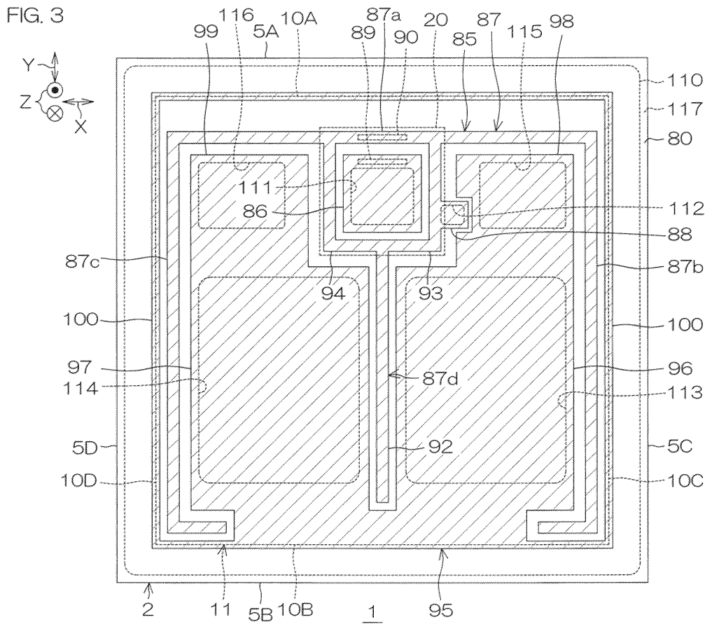

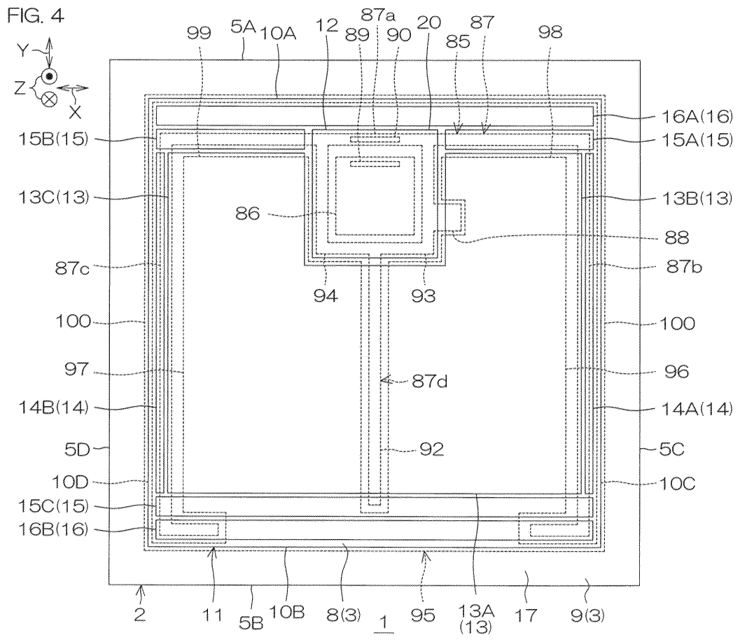

FIG. 1 is a plan view showing a semiconductor device 1 according to an embodiment. FIG. 2 is a cross-sectional view along line II-II shown in FIG. 1. FIG. 3 is a plan view showing a layout of a gate electrode 85 and a source electrode 95. FIG. 4 is a plan view showing a layout of a first main surface 3. The semiconductor device 1 is a semiconductor switching device including a MISFET (Metal Insulator Semiconductor Field Effect Transistor).

Referring to FIG. 1 to FIG. 4, the semiconductor device 1 includes a chip 2 that includes a single crystal of a wide bandgap semiconductor, and that formed in a hexahedral shape (in detail, rectangular parallelepiped shape) in this embodiment. That is, the semiconductor device 1 is a “wide bandgap semiconductor device.” The chip 2 may be referred to as a “semiconductor chip” or a “wide bandgap semiconductor chip.” The wide bandgap semiconductor is a semiconductor having a bandgap exceeding the bandgap of Si (silicon). GaN (gallium nitride), SiC (silicon carbide), and C (diamond) are exemplified as the wide bandgap semiconductor.

In this embodiment, the chip 2 is an “SiC chip” including a hexagonal SiC single crystal as an example of the wide bandgap semiconductor. That is, the semiconductor device 1 is an “SiC semiconductor device.” The semiconductor device 1 may be referred to as an “SiC-MISFET.” The hexagonal SiC single crystal has a plurality of kinds of polytypes including a 2H (Hexagonal)-SiC single crystal, a 4H-SiC single crystal, a 6H-SiC single crystal, etc. The chip 2 may include another polytype although an example is shown in which the chip 2 includes the 4H-SiC single crystal in this embodiment.

The chip 2 has a first main surface 3 on one side, a second main surface 4 on the other side, and first to fourth side surfaces 5A to 5D connecting the first main surfaces 3 and second main surfaces 4. The first main surfaces 3 and second main surfaces 4 are each formed in a quadrangular shape in a plan view seen from their normal directions Z (hereinafter, referred to simply as a “plan view”). The normal direction Z is also a thickness direction of the chip 2. Preferably, the first main surfaces 3 and second main surfaces 4 are formed by a c-plane of the SiC single crystal.

In this case, preferably, the first main surface 3 is formed by a silicon surface ((0001) plane) of the SiC single crystal, and the second main surface 4 is formed by a carbon surface ((000-1) plane) of the SiC single crystal. The first main surfaces 3 and second main surfaces 4 may each have an off-angle that is inclined at a predetermined angle in a predetermined off-direction with respect to the c-plane. Preferably, the off-direction is an a-axial direction ([11-20] direction) of the SiC single crystal. The off-angle may be more than 0° and not more than 10°. Preferably, the off-angle is 5° or less.

The first side surface 5A and the second side surface 5B extend in a first direction X along the first main surface 3, and face a second direction Y that intersects (in detail, perpendicularly intersects) the first direction X. The third side surface 5C and the fourth side surface 5D extend in the second direction Y, and face the first direction X. The first direction X may be an m-axial direction of the SiC single crystal ([1-100] direction), and the second direction Y may be the a-axial direction of the SiC single crystal. As a matter of course, the first direction X may be the a-axial direction of the SiC single crystal, and the second direction Y may be the m-axial direction of the SiC single crystal.

The chip 2 may have a thickness of not less than 5 μm and not more than 200 μm. The thickness of the chip 2 may be set at a value falling within the range of any one of not less than 5 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, and not less than 175 μm and not more than 200 μm. Preferably, the thickness of the chip 2 is 100 μm or less.

The first to fourth side surfaces 5A to 5D may each have a length of not less than 0.5 mm and not more than 20 mm in the plan view. The lengths of the first to fourth side surfaces 5A to 5D may be each set at a value falling within the range of any one of not less than 0.5 mm and not more than 5 mm, not less than 5 mm and not more than 10 mm, not less than 10 mm and not more than 15 mm, and not less than 15 mm and not more than 20 mm. Preferably, the length of each of the first to fourth side surfaces 5A to 5D is 5 mm or more.

The semiconductor device 1 includes an n-type first semiconductor region 6 formed in a region (surface layer portion) on the first main surface 3 side in the chip 2. The first semiconductor region 6 is formed in a layer shape extending along the first main surface 3, and is exposed from the first main surface 3 and from the first to fourth side surfaces 5A to 5D. In this embodiment, the first semiconductor region 6 is made of an epitaxial layer (in detail, SiC epitaxial layer). The first semiconductor region 6 may have a thickness of not less than 1 μm and not more than 50 μm. Preferably, the thickness of the first semiconductor region 6 is not less than 3 μm and not more than 30 μm. Particularly preferably, the thickness of the first semiconductor region 6 is not less than 5 μm and not more than 25 μm.

The semiconductor device 1 includes an n-type second semiconductor region 7 formed in a region (surface layer portion) on the second main surface 4 side in the chip 2. The second semiconductor region 7 is formed in a layer shape extending along the second main surface 4, and is exposed from the second main surface 4 and from the first to fourth side surfaces 5A to 5D. The second semiconductor region 7 has an n-type impurity concentration higher than the first semiconductor region 6, and is electrically connected to the first semiconductor region 6. In this embodiment, the second semiconductor region 7 is made of a semiconductor substrate (in detail, SiC semiconductor substrate). That is, the chip 2 has a layered structure including a semiconductor substrate and an epitaxial layer.

The second semiconductor region 7 may have a thickness of not less than 1 μm and not more than 200 μm. The thickness of the second semiconductor region 7 may be 150 μm or less, 100 μm or less, 50 μm or less, or 40 μm or less. The thickness of the second semiconductor region 7 may be 5 μm or more. Preferably, the thickness of the second semiconductor region 7 is 10 μm or more. In this embodiment, the second semiconductor region 7 has a thickness exceeding the thickness of the first semiconductor region 6.

The semiconductor device 1 includes an active surface 8 formed in the first main surface 3, an outer peripheral surface 9, and first to fourth connecting surfaces 10A to 10D. The active surface 8, the outer peripheral surface 9, and the first to fourth connecting surfaces 10A to 10D define an active mesa 11 in the first main surface 3. The active surface 8 may be referred to as a “first surface portion,” and the outer peripheral surface 9 may be referred to as a “second surface portion,” and the first to fourth connecting surfaces 10A to 10D may be referred to as “connecting surface portions.” The active surface 8, the outer peripheral surface 9, and the first to fourth connecting surfaces 10A to 10D (i.e., active mesa 11) may be regarded as components of the chip 2 (first main surface 3).

The active surface 8 is formed at a distance inwardly from the peripheral edge (first to fourth side surfaces 5A to 5D) of the first main surface 3. The active surface 8 has a flat surface extending in the first direction X and second direction Y. In this embodiment, the active surface 8 is formed by the c-plane (Si plane). In this embodiment, the active surface 8 is formed in a quadrangular shape having four sides parallel to the first to fourth side surfaces 5A to 5D in the plan view.

The outer peripheral surface 9 is located outside the active surface 8, and is hollowed in the thickness direction (second main surface 4 side) of the chip 2 from the active surface 8. In detail, the outer peripheral surface 9 is hollowed at a depth less than the thickness of the first semiconductor region 6 so as to expose the first semiconductor region 6. The outer peripheral surface 9 extends in a band shape along the active surface 8 in the plan view, and is formed in an annular shape (in detail, rectangularly annular shape) surrounding the active surface 8.

The outer peripheral surface 9 has a flat surface extending in the first direction X and second direction Y, and is formed in substantially parallel with the active surface 8. In this embodiment, the outer peripheral surface 9 is formed by the c-plane (Si plane). The outer peripheral surface 9 is continuous with the first to fourth side surfaces 5A to 5D. The outer peripheral surface 9 has an outer peripheral depth DO. The outer peripheral depth DO may be not less than 0.1 μm and not more than 5 μm. Preferably, the outer peripheral depth DO is 2.5 μm or less.

The first to fourth connecting surfaces 10A to 10D extend in the normal direction Z, and connect the active surface 8 and the outer peripheral surface 9. The first connecting surface 10A is located on the first side surface 5A side, the second connecting surface 10B is located on the second side surface 5B side, the third connecting surface 10C is located on the third side surface 5C side, and the fourth connecting surface 10D is located on the fourth side surface 5D side. The first connecting surface 10A and the second connecting surface 10B extend in the first direction X, and face the second direction Y. The third connecting surface 10C and the fourth connecting surface 10D extend in the second direction Y, and face the first direction X.

The first to fourth connecting surfaces 10A to 10D may extend substantially perpendicularly between the active surface 8 and the outer peripheral surface 9 so as to define the active mesa 11 having a quadrangle columnar shape. The first to fourth connecting surfaces 10A to 10D may be diagonally downwardly inclined from the active surface 8 toward the outer peripheral surface 9 so as to define the active mesa 11 having a quadrangular frustum shape. As thus described, the semiconductor device 1 includes the active mesa 11 protrudently defined in the first semiconductor region 6 in the first main surface 3. The active mesa 11 is formed only in the first semiconductor region 6, and is not formed in the second semiconductor region 7.

Referring to FIG. 4, the semiconductor device 1 includes a resistive region 12, an active region 13, a peripheral edge region 14, a dummy region 15, a termination region 16, and an outer peripheral region 17. The resistive region 12 is provided at the active surface 8. In detail, the resistive region 12 is provided at an inward portion of the active surface 8 at a distance from a peripheral edge (first to fourth connecting surfaces 10A to 10D) of the active surface 8. In this embodiment, the resistive region 12 is provided in a region along a central portion of the first connecting surface 10A in the plan view. The resistive region 12 is provided in a quadrangular shape having four sides parallel to the first to fourth side surfaces 5A to 5D in the plan view.

The active region 13 is a region that generates a drain current IDS by the control of a channel. The active region 13 is provided around the resistive region 12 in the active surface 8. In detail, the active region 13 is provided at the inward portion of the active surface 8 in a region located outside the resistive region 12 at a distance from the peripheral edge of the active surface 8. The active region 13 includes a first active region 13A, a second active region 13B, and a third active region 13C.

The first active region 13A is provided on the second connecting surface 10B side (on the inward portion side of the active surface 8) with respect to the resistive region 12, and faces the resistive region 12 in the second direction Y. The first active region 13A is provided in a quadrangular shape having four sides parallel to the peripheral edge of the active surface 8 in the plan view. The first active region 13A is provided more widely in the first direction X than the resistive region 12.

The second active region 13B is provided in a region between the resistive region 12 and the third connecting surface 10C, and faces the resistive region 12 in the first direction X. The third active region 13C is provided in a region between the resistive region 12 and the fourth connecting surface 10D, and faces the second active region 13B across the resistive region 12 in the first direction X.

The peripheral edge region 14 is provided at the active surface 8 so as to sandwich the active region 13 from both sides in the first direction X. The peripheral edge region 14 includes a first peripheral edge region 14A and a second peripheral edge region 14B. The first peripheral edge region 14A is provided in a region between the active region 13 and the third connecting surface 10C, and extends in a band shape in the second direction Y so as to face the first active region 13A and the second active region 13B in the first direction X. The second peripheral edge region 14B is provided in a region between the active region 13 and the fourth connecting surface 10D, and extends in a band shape in the second direction Y so as to face the first active region 13A and the third active region 13C in the first direction X.

The dummy region 15 is provided at the active surface 8 so as to sandwich the active region 13 from both sides in the second direction Y. The dummy region 15 includes a first dummy region 15A, a second dummy region 15B, and a third dummy region 15C. The first dummy region 15A is provided in a region between the resistive region 12 and the third connecting surface 10C. The first dummy region 15A extends in a band shape in the first direction X so as to face the resistive region 12 in the first direction X and so as to face the second active region 13B and the first peripheral edge region 14A in the second direction Y.

The second dummy region 15B is provided in a region between the resistive region 12 and the fourth connecting surface 10D. The second dummy region 15B extends in a band shape in the first direction X so as to face the resistive region 12 in the first direction X and so as to face the third active region 13C and the second peripheral edge region 14B in the second direction Y. The third dummy region 15C is provided in a region between the first active region 13A and the second connecting surface 10B. The third dummy region 15C extends in a band shape in the first direction X so as to face the first active region 13A, the first peripheral edge region 14A, and the second peripheral edge region 14B in the second direction Y.

Preferably, the planar area of the first dummy region 15A is less than the planar area of the second active region 13B. That is, preferably, the facing area of the first dummy region 15A with respect to the resistive region 12 is less than the facing area of the second active region 13B with respect to the resistive region 12. Preferably, the planar area of the second dummy region 15B is less than the planar area of the third active region 13C. That is, preferably, the facing area of the second dummy region 15B with respect to the resistive region 12 is less than the facing area of the third active region 13C with respect to the resistive region 12.

The termination region 16 is provided at the active surface 8 so as to sandwich the dummy region 15 from both sides in the second direction Y. The termination region 16 includes a first termination region 16A and a second termination region 16B. The first termination region 16A is provided in a region between the resistive region 12 and the first connecting surface 10A.

The first termination region 16A extends in a band shape in the first direction X so as to face the resistive region 12, the first dummy region 15A, and the second dummy region 15B in the second direction Y. The second termination region 16B is provided in a region between the third dummy region 15C and the second connecting surface 10B. The second termination region 16B extends in a band shape in the first direction X so as to face the third dummy region 15C in the second direction Y.

The outer peripheral region 17 is provided at the outer peripheral surface 9. In this embodiment, the outer peripheral region 17 is provided in an annular shape (in detail, rectangularly annular shape) surrounding the active surface 8 (active mesa 11) in the plan view. That is, the outer peripheral region 17 collectively surrounds the resistive region 12, the active region 13, the peripheral edge region 14, the dummy region 15, and the termination region 16.

The semiconductor device 1 includes a main surface insulating film 18 covering the first main surface 3. The main surface insulating film 18 selectively covers the active surface 8, the outer peripheral surface 9, and the first to fourth connecting surfaces 10A to 10D. The main surface insulating film 18 may include at least one among a silicon oxide film, a silicon nitride film, and a silicon oxynitride film.

In this embodiment, the main surface insulating film 18 has a single-layer structure made of a silicon oxide film. Particularly preferably, the main surface insulating film 18 includes a silicon oxide film made of an oxide of the chip 2. In this embodiment, the main surface insulating film 18 is continuous with the first to fourth side surfaces 5A to 5D. As a matter of course, a wall portion of the main surface insulating film 18 may be formed at a distance inwardly from a peripheral edge of the outer peripheral surface 9, and may expose the first semiconductor region 6 from a peripheral edge portion of the outer peripheral surface 9.

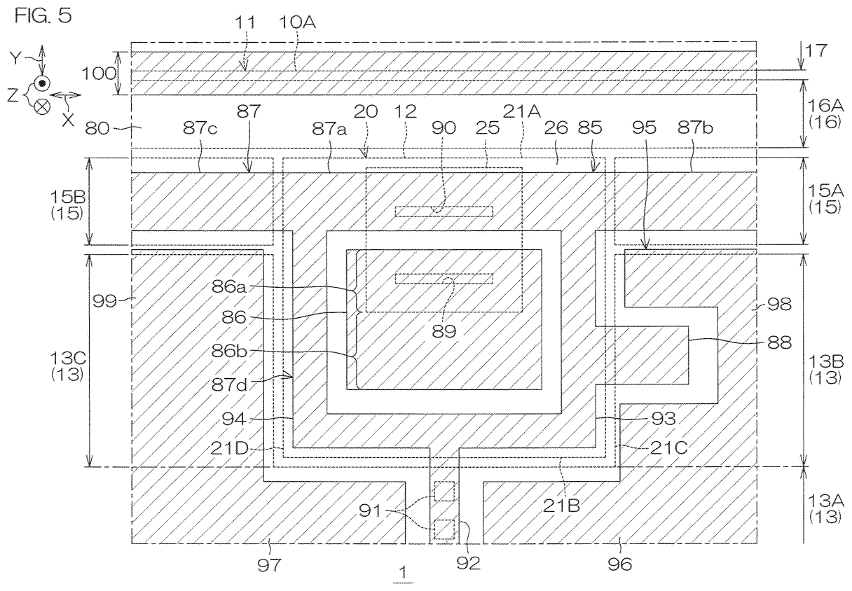

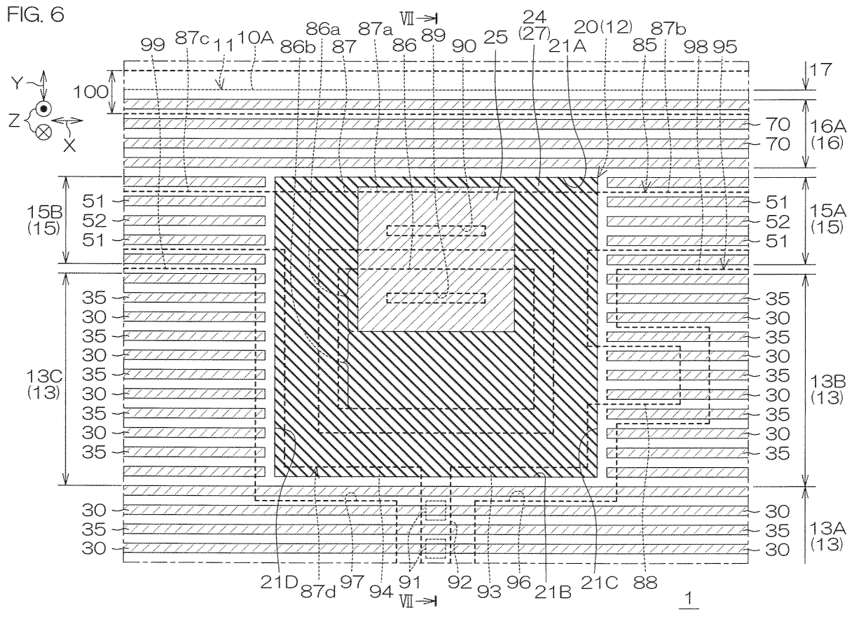

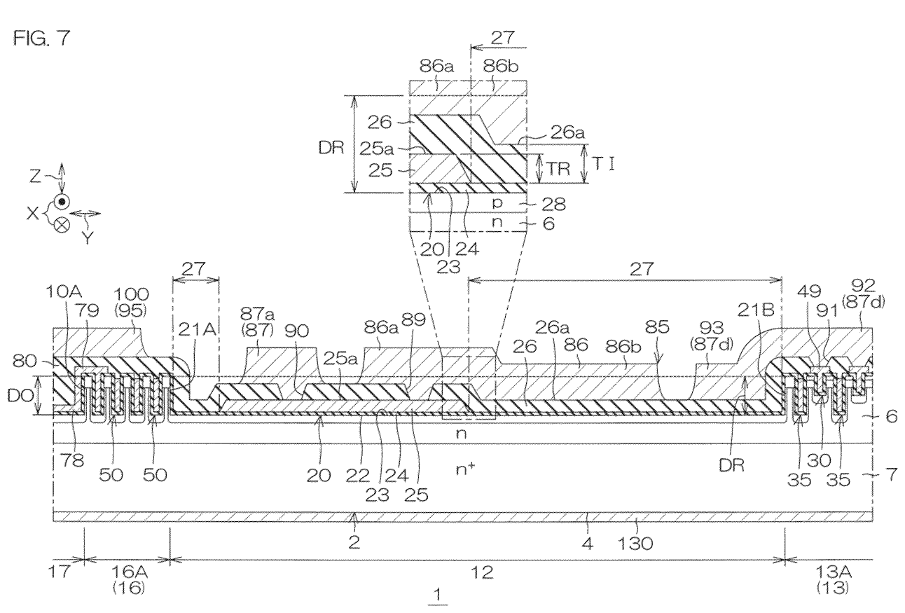

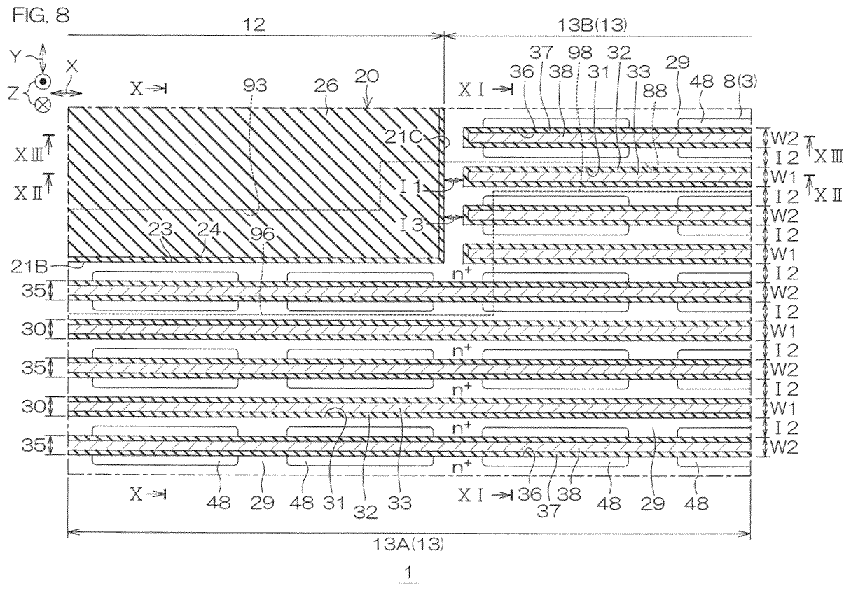

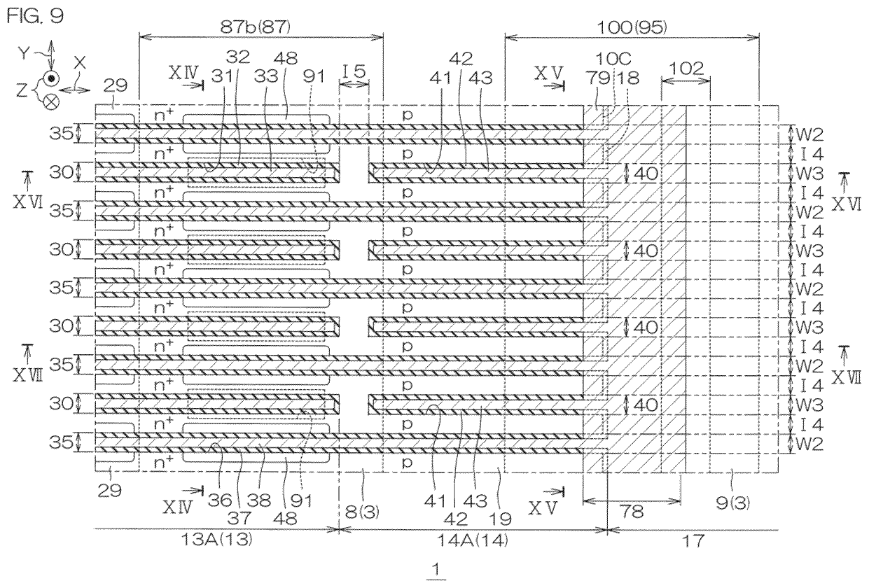

FIG. 5 is an enlarged plan view showing a neighborhood of the resistive region 12. FIG. 6 is an enlarged plan view showing a layout near the resistive region 12. FIG. 7 is a cross-sectional view along line VII-VII shown in FIG. 6. FIG. 8 is an enlarged plan view showing a layout of the resistive region 12 and the active region 13. FIG. 9 is an enlarged plan view showing a layout of the active region 13 and the peripheral edge region 14.

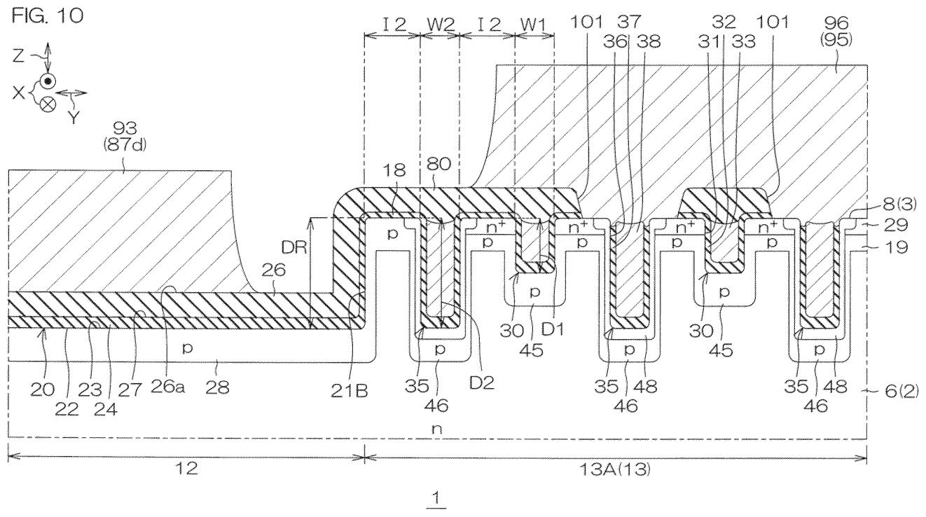

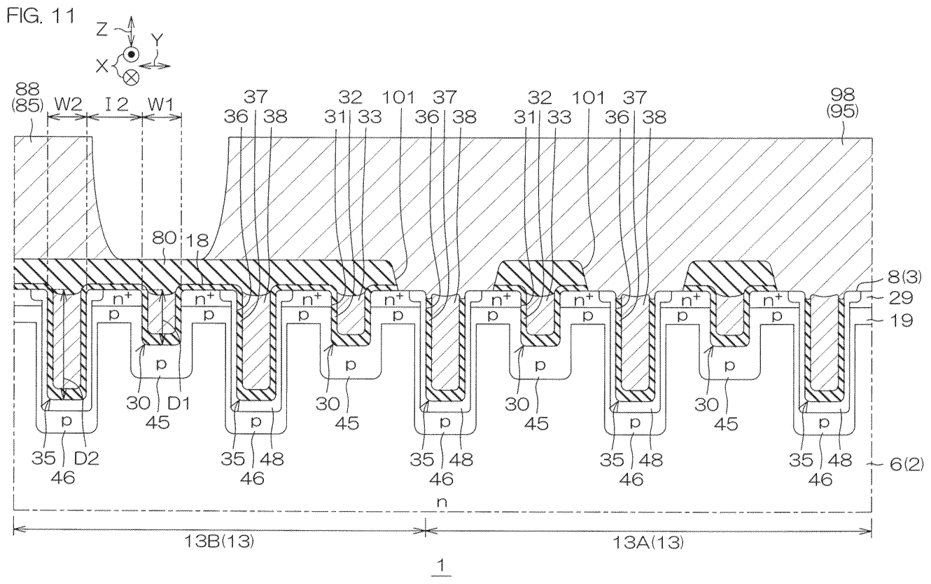

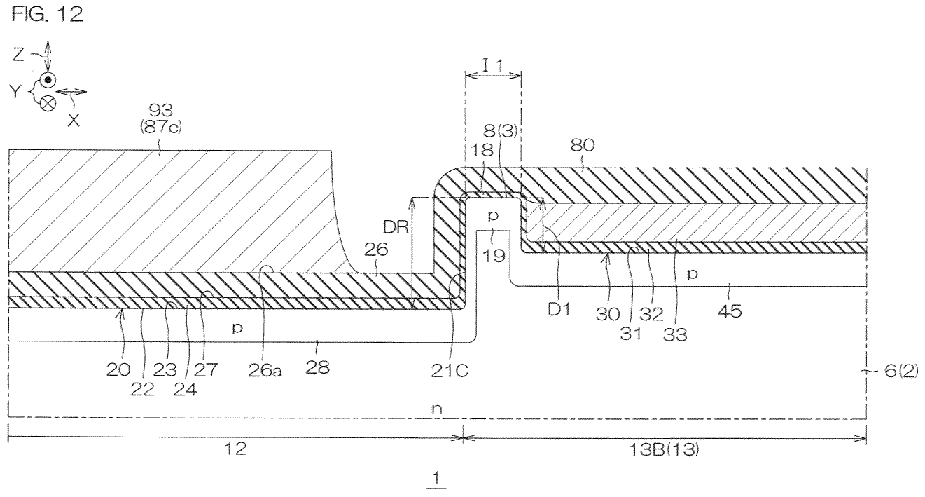

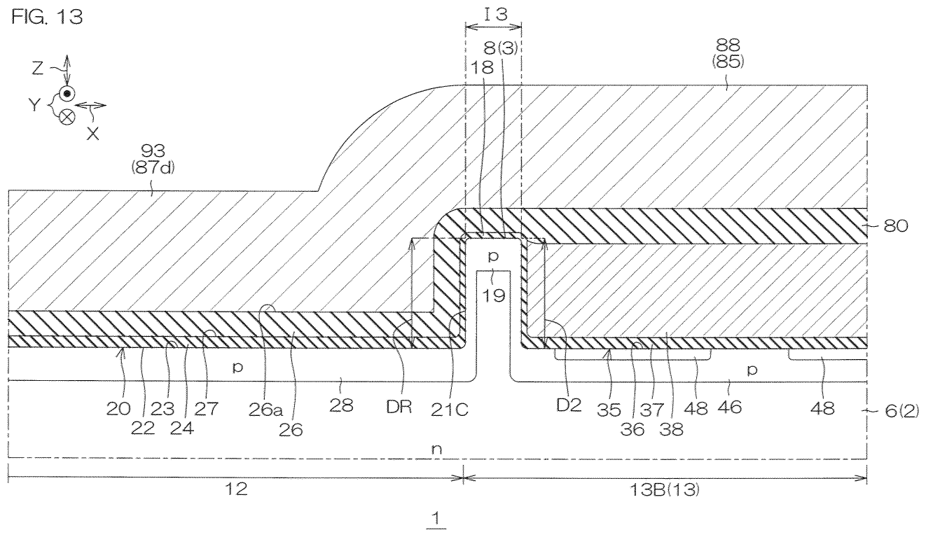

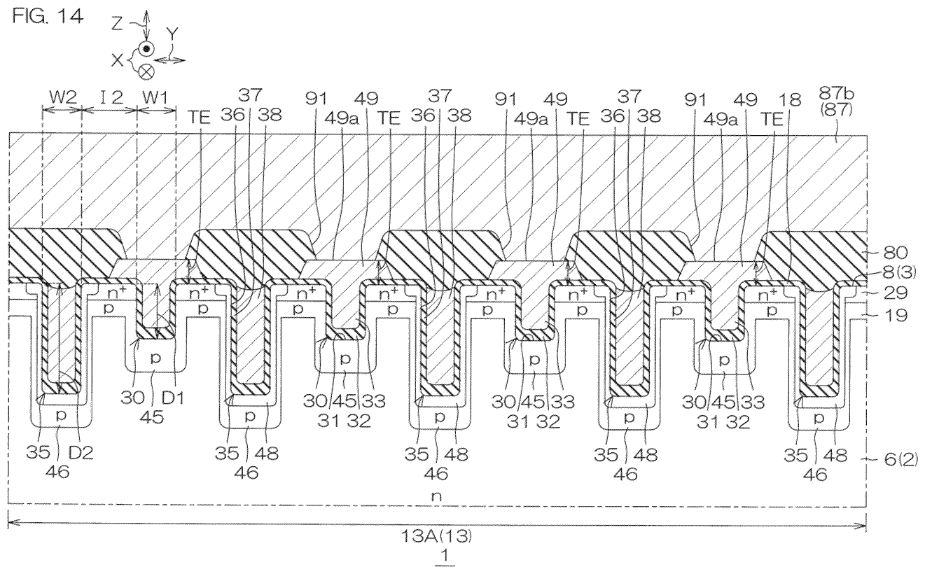

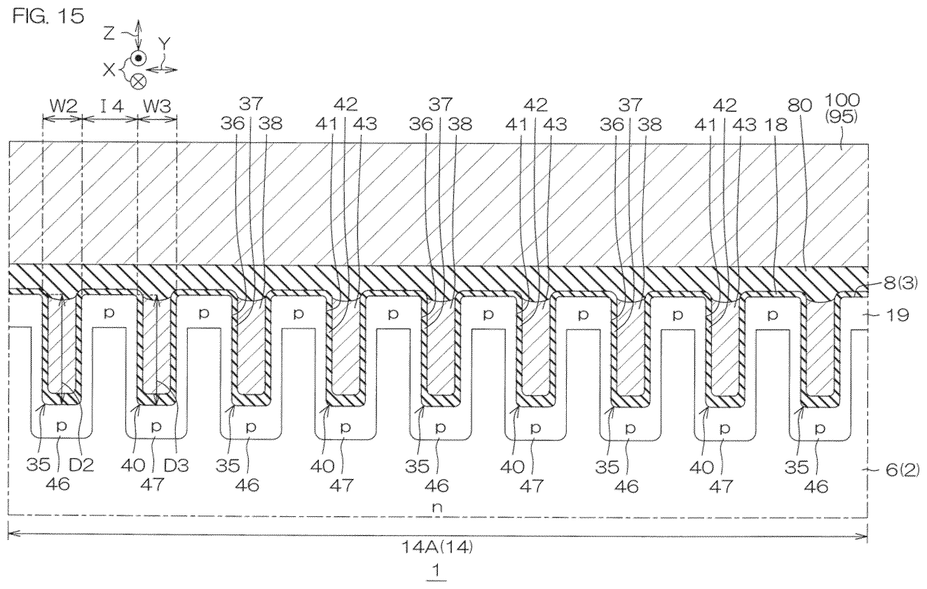

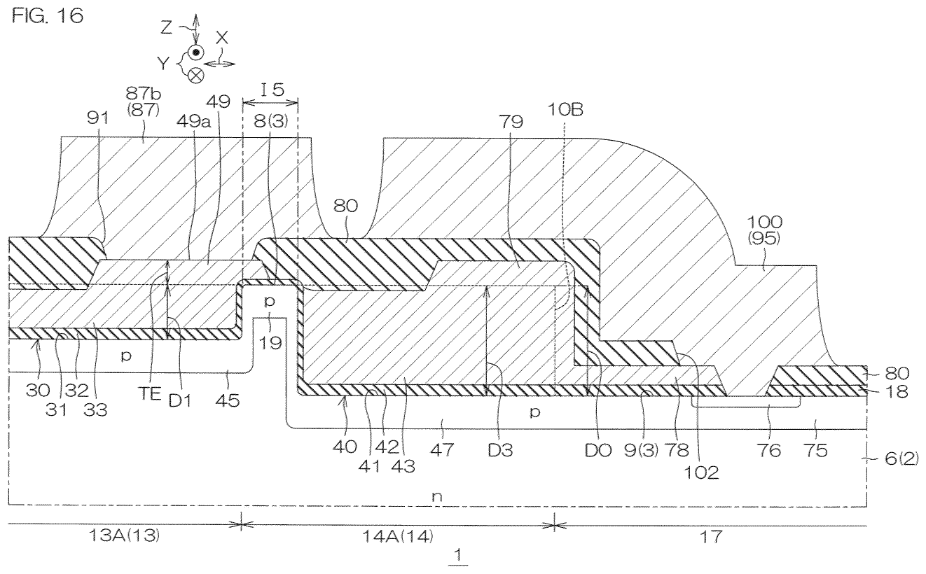

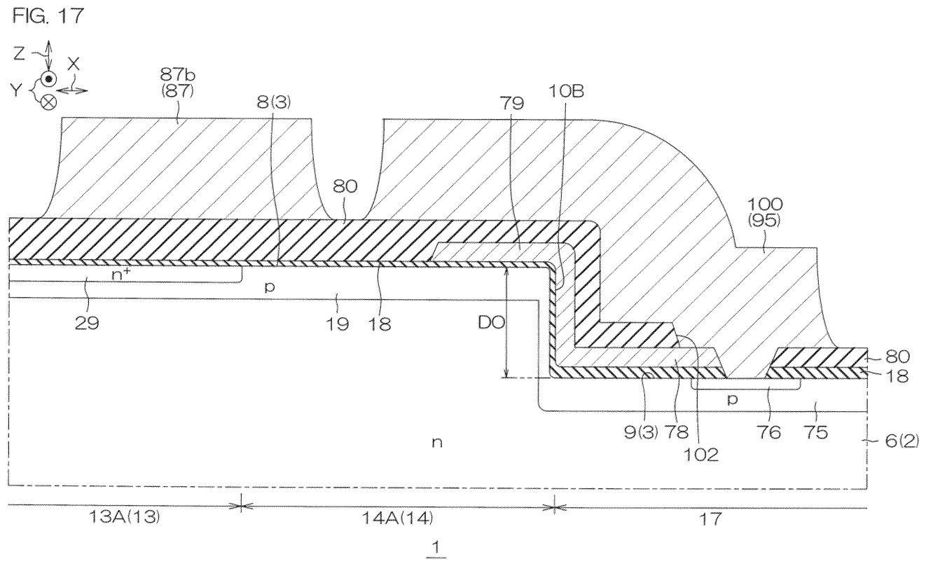

FIG. 10 is a cross-sectional view along line X-X shown in FIG. 8. FIG. 11 is a cross-sectional view along line XI-XI shown in FIG. 8. FIG. 12 is a cross-sectional view along line XII-XII shown in FIG. 8. FIG. 13 is a cross-sectional view along line XIII-XIII shown in FIG. 8. FIG. 14 is a cross-sectional view along line XIV-XIV shown in FIG. 9. FIG. 15 is a cross-sectional view along line XV-XV shown in FIG. 9. FIG. 16 is a cross-sectional view along line XVI-XVI shown in FIG. 9. FIG. 17 is a cross-sectional view along line XVII-XVII shown in FIG. 9.

Referring to FIG. 5 to FIG. 17, the semiconductor device 1 includes a p-type (second conductivity type) body region 19 formed in a surface layer portion of the first main surface 3 (active surface 8). The body region 19 is formed at a distance from a bottom portion of the first semiconductor region 6 toward the active surface 8 side. The body region 19 is formed in a layer shape extending along the active surface 8. The body region 19 may be formed in the whole area of the active surface 8, and may be exposed from the first to fourth connecting surfaces 10A to 10D.

The semiconductor device 1 includes a trench resistance structure 20 formed in the first main surface 3 (active surface 8) in the resistive region 12. In this embodiment, the single trench resistance structure 20 is formed in the first main surface 3 (active surface 8). The trench resistance structure 20 is incorporated in the chip 2 as a gate resistance R electrically connected to a gate of the MISFET. The trench resistance structure 20 does not contribute to the control of the channel although a gate potential VG is given to the trench resistance structure 20.

The trench resistance structure 20 is arranged in a region on the first connecting surface 10A side with respect to the active region 13, and faces the active region 13 in the second direction Y. The trench resistance structure 20 is arranged at a distance from the peripheral edge region 14 in the first direction X so as not to face the peripheral edge region 14 in the second direction Y. In this embodiment, the trench resistance structure 20 is arranged between the central portion of the first connecting surface 10A and the active region 13.

The trench resistance structure 20 passes through the body region 19 so as to reach the first semiconductor region 6, and is formed at a distance from the bottom portion of the first semiconductor region 6 toward the active surface 8 side. In this embodiment, the trench resistance structure 20 is formed in a quadrangular shape having four sides parallel to the peripheral edge of the active surface 8 in the plan view. The trench resistance structure 20 has first to fourth sidewalls 21A to 21D and a bottom wall 22.

The first sidewall 21A is located on the first connecting surface 10A side, the second sidewall 21B is located on the second connecting surface 10B side, the third sidewall 21C is located on the third connecting surface 10C side, and the fourth sidewall 21D is located on the fourth connecting surface 10D side. The first connecting surface 10A and the second connecting surface 10B extend in the first direction X, and face the second direction Y. The third connecting surface 10C and the fourth connecting surface 10D extend in the second direction Y, and face the first direction X. The bottom wall 22 connects the first to fourth sidewalls 21A to 21D, and extends in substantially parallel with the active surface 8.

Preferably, the trench resistance structure 20 has a planar area of not less than 1% and not more than 25% of the planar area of the first main surface 3. Preferably, the planar area of the trench resistance structure 20 is not less than 5% and not more than 20% of the planar area of the first main surface 3. The trench resistance structure 20 has a resistance depth DR in the normal direction Z. Preferably, the resistance depth DR is equal to or less than the aforementioned outer peripheral depth DO. In this embodiment, the resistance depth DR is substantially equal to the outer peripheral depth DO. The resistance depth DR may be not less than 0.1 μm and not more than 5 μm. Preferably, the resistance depth DR is 2.5 μm or less.

The trench resistance structure 20 includes a resistance trench 23, a resistance insulating film 24, a buried resistance 25, and a buried insulator 26. The resistance trench 23 is formed in the active surface 8, and defines a wall surface of the trench resistance structure (first to fourth sidewalls 21A to 21D and bottom wall 22).

The resistance insulating film 24 covers a wall surface of the resistance trench 23, and is connected to the main surface insulating film 18 in the active surface 8. The resistance insulating film 24 may include at least one among a silicon oxide film, a silicon nitride film, and a silicon oxynitride film. In this embodiment, the resistance insulating film 24 has a single-layer structure made of a silicon oxide film. Particularly preferably, the resistance insulating film 24 includes a silicon oxide film made of an oxide of the chip 2.

The buried resistance 25 is arranged in the resistance trench 23 with the resistance insulating film 24 between the buried resistance 25 and the resistance trench 23. The buried resistance 25 includes at least one of a conductive polysilicon film and an alloy crystal film. The alloy crystal film includes an alloy crystal composed of a metal element and a nonmetal element. The alloy crystal film may include at least one among a CrSi film, a CrSiN film, a CrSiO film, a TaN film, and a TiN film. In this embodiment, the buried resistance 25 includes conductive polysilicon.

The buried resistance 25 is arranged at an inward portion of the resistance trench 23 at a distance from a peripheral edge (first to fourth sidewalls 21A to 21D) of the resistance trench 23. That is, the buried resistance is formed as a resistive film that filmily extends in the resistance trench 23. The buried resistance 25 defines an insulating region 27 that exposes a part of the resistance insulating film 24 with the peripheral edge of the resistance trench 23. In this embodiment, the buried resistance 25 is formed at a distance inwardly from the entire periphery of the peripheral edge of the resistance trench 23. That is, the insulating region 27 is defined in an annular shape extending along the first to fourth sidewalls 21A to 21D in the plan view.

The buried resistance 25 may be unevenly distributed on the peripheral edge portion side of the trench resistance structure 20 with respect to a central portion of the resistance trench 23. That is, the buried resistance 25 may be deviated at least from a central portion of the trench resistance structure 20 toward at least one sidewall among the first to fourth sidewalls 21A to 21D. In this embodiment, the buried resistance 25 is unevenly distributed on the first sidewall 21A side with respect to the second sidewall 21B. That is, the distance between the first sidewall 21A and the buried resistance 25 is smaller than the distance between the second sidewall 21B and the buried resistance 25.

The buried resistance 25 has a resistance thickness TR smaller than the resistance depth DR of the resistance trench 23. The resistance trench 23 has a resistance end surface 25a formed at a distance from the height position of the active surface 8 toward the bottom wall 22 side of the resistance trench 23. The resistance end surface 25a extends in substantially parallel with the bottom wall 22. In this embodiment, the buried resistance is formed in a tapered shape in which its width becomes narrower toward the resistance end surface 25a in a cross-sectional view.

The resistance end surface 25a may be located on the bottom wall 22 side of the resistance trench 23 with respect to an intermediate portion in the depth direction of the resistance trench 23. As a matter of course, the resistance end surface 25a may be located on the active surface 8 side with respect to the intermediate portion in the depth direction of the resistance trench 23. Preferably, the resistance thickness TR is ¾ or less of the resistance depth DR. The resistance thickness TR may be ½ or less of the resistance depth DR. The resistance thickness TR may be ¼ or less of the resistance depth DR. As a matter of course, the resistance thickness TR may be larger than ½ of the resistance depth DR. The resistance thickness TR may be not less than 0.05 μm and not more than 2.5 μm.

The resistance thickness TR may be set at a value falling within the range of any one of not less than 0.05 μm and not more than 0.1 μm, not less than 0.1 μm and not more than 0.5 μm, not less than 0.5 μm and not more than 1 μm, not less than 1 μm and not more than 1.5 μm, not less than 1.5 μm and not more than 2 μm, and not less than 2 μm and not more than 2.5 μm. If the buried resistance 25 is made of an alloy crystal film, the resistance thickness TR may be not less than 0.1 nm and not more than 100 nm.

The planar shape and the planar area of the buried resistance 25 are optional, and are appropriately adjusted in accordance with a resistance value to be achieved. In this embodiment, the buried resistance 25 is formed in a quadrangular shape having four sides parallel to the first to fourth sidewalls 21A to 21D in the plan view. That is, the insulating region 27 is defined in a quadrangular annular shape extending along the first to fourth sidewalls 21A to 21D in the plan view. As a matter of course, the buried resistance 25 may be formed in a polygonal shape or a circular shape in the plan view.

Preferably, the buried resistance 25 has a planar area not less than 0.05 times and not more than 0.5 times as large as the planar area of the resistance trench 23. Particularly preferably, the planar area of the buried resistance 25 is not less than 0.1 times and not more than 0.25 times as large as the planar area of the resistance trench 23. Preferably, the planar area of the insulating region 27 is larger than the planar area of the buried resistance 25. As a matter of course, the planar area of the insulating region 27 may be set to be equal to or less than planar area of the buried resistance 25.

The buried insulator 26 covers the buried resistance 25 in the resistance trench 23. The buried insulator 26 may include at least one among a silicon oxide film, a silicon nitride film, and a silicon oxynitride film. In this embodiment, the buried insulator 26 includes a silicon oxide film. The buried insulator 26 covers the whole area of the buried resistance 25 and the whole area of the insulating region 27 in the resistance trench 23, and is connected to the resistance insulating film 24 in the peripheral edge (first to fourth sidewalls 21A to 21D) of the resistance trench 23.

In this embodiment, the buried insulator 26 has an insulation thickness TI that is equal to or less than the resistance depth DR of the resistance trench 23. The insulation thickness TI is the thickness of the buried insulator 26 based on the resistance insulating film 24. In this embodiment, the insulation thickness TI is less than the resistance depth DR. The buried insulator 26 has an insulation end surface 26a formed at a distance from the height position of the active surface 8 toward the bottom wall 22 side of the resistance trench 23. The insulation end surface 26a extends in substantially parallel with the resistance insulating film 24 and with the buried resistance 25.

The insulation thickness TI may be ¾ or less of the resistance depth DR. The insulation thickness TI may be ½ or less of the resistance depth DR. The insulation thickness TI may be ¼ or less of the resistance depth DR. Preferably, the insulation thickness TI is equal to or more than the resistance thickness TR of the buried resistance 25. As a matter of course, the insulation thickness TI may be equal to or less than the resistance thickness TR. The insulation thickness TI may be not less than 0.1 μm and not more than 2.5 μm. Preferably, the insulation thickness TI is not less than 0.5 μm and not more than 1.5 μm.

The semiconductor device 1 includes a p-type first well region 28 formed in a region along the trench resistance structure 20 in the resistive region 12. In this embodiment, the first well region 28 has a p-type impurity concentration higher than the body region 19. As a matter of course, the p-type impurity concentration of the first well region 28 may be lower than the body region 19.

The first well region 28 covers the wall surface (first to fourth sidewalls 21A to 21D and bottom wall 22) of the trench resistance structure 20, and is electrically connected to the body region 19 in a surface layer portion of the active surface 8. The first well region 28 faces the buried resistance 25 and the buried insulator 26 (insulating region 27) across the resistance insulating film 24. The first well region 28 is formed at a distance from the bottom portion of the first semiconductor region 6 toward the active surface 8 side, and faces the second semiconductor region 7 across a part of the first semiconductor region 6. The first well region 28 forms a p-n junction portion with the first semiconductor region 6.

The semiconductor device 1 includes an n-type source region 29 formed in the surface layer portion of the first main surface 3 (active surface 8) in the active region 13. In detail, the source region 29 is formed in a surface layer portion of the body region 19 at a distance from a bottom portion of the body region 19 toward the active surface 8 side. The source region 29 is not formed in all of the resistive region 12, the peripheral edge region 14, the dummy region 15, and the termination region 16. That is, the source region 29 is not formed in a region along the trench resistance structure 20.

As a matter of course, the source region 29 may be formed in the resistive region 12, the peripheral edge region 14, the dummy region 15, and the termination region 16 to the extent of not influencing the control of a channel. The source region 29 has an n-type impurity concentration higher than the first semiconductor region 6. The source region 29 forms a channel of the MISFET in the body region 19 with the first semiconductor region 6.

The semiconductor device 1 includes a plurality of trench gate structures 30 formed in the first main surface 3 (active surface 8) in the active region 13 (first to third active regions 13A to 13C). A gate potential VG is given to the plurality of trench gate structures 30. The plurality of trench gate structures 30 control the inversion and the non-inversion of the channel in the body region 19.

In this embodiment, the plurality of trench gate structures 30 are arranged at the inward portion of the active surface 8 at a distance from the peripheral edge of the active surface 8. Specifically, the plurality of trench gate structures 30 are arranged at a distance from the first to fourth connecting surfaces 10A to 10D in the first direction X and second direction Y, and define the active region 13 at the inward portion of the active surface 8, and define the peripheral edge region 14 at a peripheral edge portion of the active surface 8. The plurality of trench gate structures 30 pass through the body region 19 and through the source region 29 so as to reach the first semiconductor region 6, and are formed at a distance from the bottom portion of the first semiconductor region 6 toward the active surface 8 side.

The plurality of trench gate structures 30 on the first active region 13A side are each formed in a band shape extending in the first direction X in a region between the second connecting surface 10B and the trench resistance structure 20, and are arrayed at a distance from each other in the second direction Y. The plurality of trench gate structures 30 on the first active region 13A side are formed at a distance from the trench resistance structure 20 in the second direction Y, and face the trench resistance structure 20 in the second direction Y. The plurality of trench gate structures 30 are formed more widely than the trench resistance structure 20 in the first direction X in the first active region 13A.

The plurality of trench gate structures 30 on the second active region 13B side are each formed in a band shape extending in the first direction X in a region between the third connecting surface 10C and the trench resistance structure 20, and are arrayed at a distance from each other in the second direction Y. The plurality of trench gate structures 30 on the second active region 13B side are formed at a distance from the trench resistance structure in the first direction X, and face the trench resistance structure 20 in the first direction X. The plurality of trench gate structures 30 on the second active region 13B side are formed more widely than the trench resistance structure 20 in the first direction X. As a matter of course, the plurality of trench gate structures 30 on the second active region 13B side may be formed more narrowly than the trench resistance structure 20.

The trench resistance structure 20 on the third active region 13C side is formed in a band shape extending in the first direction X in a region between the fourth connecting surface 10D and the trench resistance structure 20, and is arrayed at a distance in the second direction Y. The plurality of trench gate structures 30 on the third active region 13C side are formed at a distance from the trench resistance structure 20 in the first direction X, and face the trench resistance structure 20 in the first direction X.

The plurality of trench gate structures 30 on the third active region 13C side may face the plurality of trench gate structures 30 on the second active region 13B side across the trench resistance structure 20 in a one-to-one correspondence relationship. The plurality of trench gate structures 30 on the third active region 13C side are formed more widely than the trench resistance structure 20 in the first direction X. As a matter of course, the plurality of trench gate structures 30 on the third active region 13C side may be formed more narrowly than the trench resistance structure 20.

The single trench gate structure 30 will be hereinafter described. The trench gate structure 30 has a first width W1 in the second direction Y, and has a first depth D1 in the normal direction Z. The first width W1 is less than the width of the trench resistance structure 20. The first width W1 may be not less than 1/1000 and not more than 1/10 of the width of the trench resistance structure 20. Preferably, the first width W1 is 1/100 or more of the width of the trench resistance structure 20.

The first width W1 may be not less than 0.1 μm and not more than 3 μm. Preferably, the first width W1 is not less than 0.5 μm and not more than 2 μm. The first depth D1 is less than the aforementioned resistance depth DR (outer peripheral depth DO). The first depth D1 may be not less than ⅓ and not more than ⅔ of the resistance depth DR. The first depth D1 may be not less than 0.1 μm and not more than 3 μm. Preferably, the first depth D1 is not less than 0.5 μm and not more than 1.5 μm.

In the second to third active regions 13B to 13C, the trench gate structure 30 is formed at a first distance I1 from the trench resistance structure 20 in the first direction X. Preferably, the first distance I1 is less than the distance between two trench gate structures 30 adjoining in the second direction Y. The first distance I1 may be the first width W1 or more, or may be less than the first width W1. Preferably, the first distance I1 is not less than 0.5 times and not more than 2 times as long as the first width W1. The first distance I1 may be not less than 0.1 μm and not more than 2.5 μm. Preferably, the first distance I1 is not less than 0.5 μm and not more than 1.5 μm.

The trench gate structure 30 includes a gate trench 31, a gate insulating film 32, and a gate buried electrode 33. The gate trench 31 is formed in the active surface 8, and defines a wall surface of the trench gate structure 30. The gate insulating film 32 covers a wall surface of the gate trench 31, and is connected to the main surface insulating film 18 in the active surface 8. The gate insulating film 32 may include at least one among a silicon oxide film, a silicon nitride film, and a silicon oxynitride film. In this embodiment, the gate insulating film 32 has a single-layer structure made of a silicon oxide film. Particularly preferably, the gate insulating film 32 includes a silicon oxide film made of an oxide of the chip 2.

The gate buried electrode 33 is arranged in the gate trench 31 with the gate insulating film 32 between the gate buried electrode 33 and the gate trench 31, and faces a channel across the gate insulating film 32. The gate buried electrode 33 may include conductive polysilicon. In this embodiment, the gate buried electrode 33 has an end surface located on the active surface 8 side with respect to a height position of the resistance end surface 25a of the buried resistance 25. The end surface of the gate buried electrode 33 may be located on the active surface 8 side with respect to a height position of the insulation end surface 26a of the buried insulator 26.

The semiconductor device 1 includes a plurality of first trench source structures 35 formed in the first main surface 3 (active surface 8) in the active region 13 (first to third active regions 13A to 13C). A source potential VS is given to the plurality of first trench source structures 35. The source potential VS may be a reference potential (for example, ground potential) serving as an operation standard. The plurality of first trench source structures 35 pass through the body region 19 and through the source region 29 so as to reach the first semiconductor region 6, and are formed at a distance from the bottom portion of the first semiconductor region 6 toward the active surface 8 side.

The plurality of first trench source structures on the first active region 13A side are each arranged in a region between two trench gate structures 30 adjoining each other in the second direction Y in a region between the second connecting surface 10B and the trench resistance structure 20. The plurality of first trench source structures 35 on the first active region 13A side are arrayed in the second direction Y alternately with the plurality of trench gate structures 30 in the plan view, and are each formed in a band shape extending in the first direction X. In this embodiment, the plurality of first trench source structures 35 on the first active region 13A side include the first trench source structure 35 arranged in a region between the trench resistance structure 20 and the trench gate structure 30.

The plurality of first trench source structures on the first active region 13A side are pulled out to at least one of the first peripheral edge region 14A and the second peripheral edge region 14B so as to be exposed from at least one of the third connecting surface 10C and the fourth connecting surface 10D. In this embodiment, the plurality of first trench source structures 35 on the first active region 13A side are exposed from both the third connecting surface 10C and the fourth connecting surface 10D. The plurality of first trench source structures 35 on the first active region 13A side face the trench gate structure 30 in the second direction Y, and do not face the trench gate structure 30 in the second direction Y in the peripheral edge region 14.

The plurality of first trench source structures on the second active region 13B side are each arranged in a region between two trench gate structures 30 adjoining each other in the second direction Y in a region between the third connecting surface 10C and the trench resistance structure 20. The plurality of first trench source structures 35 on the second active region 13B side are arrayed in the second direction Y alternately with the plurality of trench gate structures 30 in the plan view, and are each formed in a band shape extending in the first direction X.

The plurality of first trench source structures on the second active region 13B side are formed at a distance from the trench resistance structure 20 in the first direction X, and face the trench resistance structure in the first direction X. The plurality of first trench source structures 35 on the second active region 13B side are formed more widely in the first direction X than the trench resistance structure 20. As a matter of course, the plurality of first trench source structures 35 on the second active region 13B side may be formed more narrowly in the first direction X than the trench resistance structure 20.

The plurality of first trench source structures on the second active region 13B side are pulled out to the first peripheral edge region 14A, and are exposed from the third connecting surface 10C. The plurality of first trench source structures 35 on the second active region 13B side face the trench gate structure 30 in the second direction Y, and do not face the trench gate structure 30 in the second direction Y in the first peripheral edge region 14A.

The plurality of first trench source structures on the third active region 13C side are each arranged in a region between two trench gate structures 30 adjoining each other in the second direction Y in a region between the fourth connecting surface 10D and the trench resistance structure 20. The plurality of first trench source structures 35 on the third active region 13C side are arrayed in the second direction Y alternately with the plurality of trench gate structures 30 in the plan view, and are each formed in a band shape extending in the first direction X.

The plurality of first trench source structures on the third active region 13C side are formed at a distance from the trench resistance structure 20 in the first direction X, and face the trench resistance structure in the first direction X. The plurality of first trench source structures 35 on the third active region 13C side may face the plurality of first trench source structures 35 on the second active region 13B side across the trench resistance structure 20 in a one-to-one correspondence relationship.

The plurality of first trench source structures on the third active region 13C side are formed more widely in the first direction X than the trench resistance structure 20. As a matter of course, the plurality of first trench source structures 35 on the third active region 13C side may be formed more narrowly in the first direction X than the trench resistance structure 20.

The plurality of first trench source structures 35 on the third active region 13C side are pulled out to the second peripheral edge region 14B, and are exposed from the fourth connecting surface 10D. The plurality of first trench source structures 35 on the third active region 13C side face the trench gate structure 30 in the second direction Y, and do not face the trench gate structure 30 in the second direction Y in the second peripheral edge region 14B.

The single first trench source structure 35 will be hereinafter described. The first trench source structure has a second width W2 in the second direction Y, and has a second depth D2 in the normal direction Z. The second width W2 is less than the width of the trench resistance structure 20. The second width W2 may be not less than 1/1000 and not more than 1/10 of the width of the trench resistance structure 20. Preferably, the second width W2 is 1/100 or more of the width of the trench resistance structure 20. Preferably, the second width W2 is substantially equal to the first width W1. The second width W2 may be not less than 0.1 μm and not more than 3 μm. Preferably, the second width W2 is not less than 0.5 μm and not more than 2 μm.

The second depth D2 is equal to or more than the first depth D1. In this embodiment, the second depth D2 is larger than the first depth D1. Preferably, the second depth D2 is not less than 1.5 times and not more than 3 times as large as the first depth D1. Particularly preferably, the second depth D2 is substantially equal to the resistance depth DR (outer peripheral depth DO). The second depth D2 may be not less than 0.1 μm and not more than 5 μm. Particularly preferably, the second depth D2 is 2.5 μm or less.

The first trench source structure 35 is arranged at a second distance I2 from the trench resistance structure and from the trench gate structure 30 in the second direction Y. Preferably, the second distance I2 is not less than 0.5 times and not more than 2 times as large as the second width W2. Particularly preferably, the second distance I2 is less than the second width W2. The second distance I2 may be not less than 0.1 μm and not more than 2.5 μm. Preferably, the second distance I2 is not less than 0.5 μm and not more than 1.5 μm.

In the second to third active regions 13B to 13C, the first trench source structure 35 is arranged at a third distance I3 from the trench resistance structure 20 in the first direction X. Preferably, the third distance I3 is less than the distance between two first trench source structures 35 (trench gate structures 30) adjoining each other in the second direction Y.

The third distance I3 may be equal to or more than the second width W2, or may be less than the second width W2. Preferably, the third distance I3 is not less than 0.5 times and not more than 2 times as large as the second width W2. Preferably, the third distance I3 is substantially equal to the first distance I1. The third distance I3 may be not less than 0.1 μm and not more than 2.5 μm. Preferably, the third distance I3 is not less than 0.5 μm and not more than 1.5 μm.

The first trench source structure 35 includes a first source trench 36, a first source insulating film 37, and a first source buried electrode 38. The first source trench 36 is formed in the active surface 8, and defines a wall surface of the first trench source structure 35. A sidewall of the first source trench 36 is exposed from either one or both of the third connecting surface 10C and the fourth connecting surface 10D. A bottom wall of the first source trench 36 communicates with the outer peripheral surface 9.

The first source insulating film 37 covers a wall surface of the first source trench 36, and is connected to the main surface insulating film 18 in the active surface 8. The first source insulating film 37 is connected to the main surface insulating film 18 in a communication portion of the third connecting surface 10C (communication portion of the fourth connecting surface 10D) and in a communication portion of the outer peripheral surface 9. The first source insulating film 37 may include at least one among a silicon oxide film, a silicon nitride film, and a silicon oxynitride film. In this embodiment, the first source insulating film 37 has a single-layer structure made of a silicon oxide film. Particularly preferably, the first source insulating film 37 includes a silicon oxide film made of an oxide of the chip 2.

The first source buried electrode 38 is arranged in the first source trench 36 with the first source insulating film 37 between the first source buried electrode 38 and the first source trench 36. The first source buried electrode 38 may include conductive polysilicon. In this embodiment, the first source buried electrode 38 has an end surface located on the active surface 8 side with respect to the height position of the resistance end surface 25a of the buried resistance 25. The end surface of the first source buried electrode 38 may be located on the active surface 8 side with respect to the height position of the insulation end surface 26a of the buried insulator 26.

The semiconductor device 1 includes a plurality of second trench source structures 40 formed in the first main surface 3 (active surface 8) in the peripheral edge region 14 (first to second peripheral edge regions 14A to 14B). A source potential VS is given to the plurality of second trench source structures 40. The plurality of second trench source structures 40 pass through the body region 19 so as to reach the first semiconductor region 6, and are formed at a distance from the bottom portion of the first semiconductor region 6 toward the active surface 8 side.

The plurality of second trench source structures on the first peripheral edge region 14A side are arranged in a region between two first trench source structures 35 adjoining each other in the second direction Y in a region between the third connecting surface 10C and the plurality of trench gate structures 30, and face the plurality of trench gate structures 30 in the first direction X in a one-to-one correspondence relationship. The plurality of second trench source structures 40 on the first peripheral edge region 14A side are each formed in a band shape extending in the first direction X in the plan view. The plurality of second trench source structures 40 on the first peripheral edge region 14A side are exposed from the third connecting surface 10C.

The plurality of second trench source structures 40 on the second peripheral edge region 14B side are arranged in a region between two first trench source structures 35 adjoining each other in the second direction Y in a region between the fourth connecting surface 10D and the plurality of trench gate structures 30, and face the plurality of trench gate structures 30 in the first direction X in a one-to-one correspondence relationship. The plurality of second trench source structures 40 on the second peripheral edge region 14B side are each formed in a band shape extending in the first direction X in the plan view. The plurality of second trench source structures 40 on the second peripheral edge region 14B side are exposed from the fourth connecting surface 10D.

The single second trench source structure 40 will be hereinafter described. The second trench source structure 40 has a third width W3 in the second direction Y, and has a third depth D3 in the normal direction Z. Preferably, the third width W3 is substantially equal to the second width W2 (first width W1). The third width W3 may be not less than 0.1 μm and not more than 3 μm. Preferably, the third width W3 is not less than 0.5 μm and not more than 2 μm.

The third depth D3 is equal to or more than the first depth D1. In this embodiment, the third depth D3 is larger than the first depth D1. Preferably, the third depth D3 is not less than 1.5 times and not more than 3 times as large as the first depth D1. Particularly preferably, the third depth D3 is substantially equal to the second depth D2 (resistance depth DR). The third depth D3 may be not less than 0.1 μm and not more than 5 μm. Particularly preferably, the second depth D2 is 2.5 μm or less.

The second trench source structure 40 is arranged at a fourth distance I4 from the first trench source structure 35 in the second direction Y. Preferably, the fourth distance I4 is not less than 0.5 times and not more than 2 times as large as the third width W3 (second width W2). Particularly preferably, the fourth distance I4 is less than the third width W3 (second width W2). Preferably, the fourth distance I4 is substantially equal to the second distance I2. The fourth distance I4 may be not less than 0.1 μm and not more than 2.5 μm. Preferably, the fourth distance I4 is not less than 0.5 μm and not more than 1.5 μm.

The second trench source structure 40 is arranged at a fifth distance I5 from the trench gate structure 30 in the first direction X. Preferably, the fifth distance I5 is not less than 0.5 times and not more than 2 times as large as the third width W3 (second width W2). Preferably, the fifth distance I5 is not less than 0.5 times and not more than 2 times as large as the fourth distance I4. Particularly preferably, the fifth distance I5 is 1.5 times or less as large as the fourth distance I4. Preferably, the fifth distance I5 is substantially equal to the first distance I1 (third distance I3). The fifth distance I5 may be substantially equal to the fourth distance I4. The fifth distance I5 may be not less than 0.1 μm and not more than 2.5 μm. Preferably, the fifth distance I5 is not less than 0.5 μm and not more than 1.5 μm.

The second trench source structure 40 includes a second source trench 41, a second source insulating film 42, and a second source buried electrode 43. The second source trench 41 is formed in the active surface 8, and defines a wall surface of the second trench source structure 40. A sidewall of the second source trench 41 communicates with the third connecting surface 10C (fourth connecting surface 10D). A bottom wall of the second source trench 41 communicates with the outer peripheral surface 9.

The second source insulating film 42 covers a wall surface of the second source trench 41, and is connected to the main surface insulating film 18 in the active surface 8. The second source insulating film 42 is connected to the main surface insulating film 18 in the communication portion of the third connecting surface 10C (communication portion of the fourth connecting surface 10D) and in the communication portion of the outer peripheral surface 9. The second source insulating film 42 may include at least one among a silicon oxide film, a silicon nitride film, and a silicon oxynitride film. In this embodiment, the second source insulating film 42 has a single-layer structure made of a silicon oxide film. Particularly preferably, the second source insulating film 42 includes a silicon oxide film made of an oxide of the chip 2.

The second source buried electrode 43 is arranged in the second source trench 41 with the second source insulating film 42 between the second source buried electrode 43 and the second source trench 41. The second source buried electrode 43 may include conductive polysilicon. In this embodiment, the second source buried electrode 43 has an end surface located on the active surface 8 side with respect to the height position of the resistance end surface 25a of the buried resistance 25. The end surface of the second source buried electrode 43 may be located on the active surface 8 side with respect to the height position of the insulation end surface 26a of the buried insulator 26.

The semiconductor device 1 includes a plurality of p-type second well regions 45 formed in a region along the plurality of trench gate structures 30 in the active region 13. In this embodiment, the second well region 45 has a p-type impurity concentration higher than the body region 19. As a matter of course, the p-type impurity concentration of the second well region 45 may be lower than the body region 19. Preferably, the p-type impurity concentration of the second well region 45 is substantially equal to the p-type impurity concentration of the first well region 28.

The plurality of second well regions 45 cover the wall surface of a corresponding one of the trench gate structures 30 at a distance from the adjoining first trench source structure 35, and are electrically connected to the body region 19 in the surface layer portion of the active surface 8. The plurality of second well regions 45 are formed at a distance from the bottom portion of the first semiconductor region 6 toward the active surface 8 side, and face the second semiconductor region 7 across a part of the first semiconductor region 6. The bottom portions of the plurality of second well regions 45 are located on the active surface 8 side with respect to the depth position of the bottom portion of the first well region 28. The plurality of second well regions 45 form a p-n junction portion with the first semiconductor region 6.

The semiconductor device 1 includes a plurality of p-type third well regions 46 formed in a region along the plurality of first trench source structures 35 in both the active region 13 and the peripheral edge region 14. In this embodiment, the third well region 46 has a p-type impurity concentration higher than the body region 19. As a matter of course, the p-type impurity concentration of the third well region 46 may be lower than the body region 19. Preferably, the p-type impurity concentration of the third well region 46 is substantially equal to the p-type impurity concentration of the first well region 28 (second well region 45).

The plurality of third well regions 46 cover the wall surface of a corresponding one of the first trench source structures 35 at a distance from the adjoining trench gate structure 30, and are electrically connected to the body region 19 in the surface layer portion of the active surface 8. The plurality of third well regions 46 cover the wall surface of a corresponding one of the first trench source structures 35 in both the active region 13 and the peripheral edge region 14, and are exposed from the third connecting surface 10C and from the fourth connecting surface 10D.

The plurality of third well regions 46 are formed at a distance from the bottom portion of the first semiconductor region 6 toward the active surface 8 side, and face the second semiconductor region 7 across a part of the first semiconductor region 6. The bottom portions of the plurality of third well regions 46 are located on the bottom portion side of the first semiconductor region 6 with respect to the depth position of the bottom portions of the plurality of second well regions 45. The bottom portions of the plurality of third well regions 46 are formed at a depth substantially equal to the depth of the bottom portion of the first well region 28. The plurality of third well regions 46 form a p-n junction portion with the first semiconductor region 6.

The semiconductor device 1 includes a plurality of p-type fourth well regions 47 formed in a region along the plurality of second trench source structures 40 in the peripheral edge region 14. In this embodiment, the fourth well region 47 has a p-type impurity concentration higher than the body region 19. As a matter of course, the p-type impurity concentration of the fourth well region 47 may be lower than the body region 19. Preferably, the p-type impurity concentration of the fourth well region 47 is substantially equal to the p-type impurity concentration of the first well region 28 (third well region 46).

The plurality of fourth well regions 47 cover the wall surface of a corresponding one of the second trench source structures 40 at a distance from the adjoining trench gate structure 30 and from the first trench source structure 35, and are electrically connected to the body region 19 in the surface layer portion of the active surface 8. As a matter of course, the fourth well region 47 may be integrally united with the second well region 45 in a region between the trench gate structure 30 and the second trench source structure 40. The plurality of fourth well regions 47 are exposed from the third connecting surface 10C or from the fourth connecting surface 10D.

The plurality of fourth well regions 47 are formed at a distance from the bottom portion of the first semiconductor region 6 toward the active surface 8 side, and face the second semiconductor region 7 across a part of the first semiconductor region 6. The bottom portions of the plurality of fourth well regions 47 are located on the bottom portion side of the first semiconductor region 6 with respect to the depth position of the bottom portions of the plurality of second well regions 45. The bottom portions of the plurality of fourth well regions 47 are formed at a depth that is substantially equal to the depth of the bottom portion of the first well region 28 (third well region 46). The plurality of fourth well regions 47 form a p-n junction portion with the first semiconductor region 6.

The semiconductor device 1 includes a plurality of p-type first contact regions 48 formed in a region along the plurality of first trench source structures 35 in the active region 13. The first contact region 48 has a p-type impurity concentration higher than the body region 19. In this embodiment, the p-type impurity concentration of the first contact region 48 is higher than the third well region 46.

The plurality of first contact regions 48 cover the wall surface of a corresponding one of the first trench source structures 35 in a corresponding one of the third well regions 46. The plurality of first contact regions 48 are formed in a one-to-many correspondence relationship with respect to each of the first trench source structures 35. The plurality of first contact regions 48 are formed at a distance from each other along a corresponding one of the first trench source structures 35.

The plurality of first contact regions 48 are pulled out to the surface layer portion of the body region 19 from the inside of the corresponding third well region 46 along the wall surface of the corresponding first trench source structure 35, and are exposed from the active surface 8. The plurality of first contact regions 48 are formed in the active region 13, and are not formed in the peripheral edge region 14. That is, the plurality of first contact regions 48 face the trench gate structure 30 in the second direction Y, and do not face the second trench source structure 40 in the second direction Y. The first contact regions 48 are not formed in the fourth well region 47.

In this embodiment, the plurality of first contact regions 48 are each formed in a band shape extending in the first direction X in the plan view. Preferably, the length in the first direction X of the plurality of first contact regions 48 is equal to or more than the second width W2 of the first trench source structure 35. Preferably, the length of the plurality of first contact regions 48 is larger than the distance between two first contact regions 48 adjoining each other in the first direction X.

The plurality of first contact regions 48 along the single first trench source structure 35 face the plurality of first contact regions 48 along the other first trench source structure 35 in the second direction Y. That is, in this embodiment, the plurality of first contact regions 48 are arrayed in a matrix manner at a distance from each other in the first direction X and second direction Y as a whole in the plan view.

The plurality of first contact regions 48 along the single first trench source structure 35 may be arrayed in a deviated state in the first direction X so as to face a region between the plurality of first contact regions 48 along the other first trench source structure 35 in the second direction Y. That is, the plurality of first contact regions 48 may be arrayed in a staggered manner at a distance from each other in the first direction X and second direction Y as a whole in the plan view.

Referring to FIG. 7, FIG. 9, and FIG. 14, the semiconductor device 1 includes a plurality of gate connection electrode films 49 each of which covers an end portion and an intermediate portion of the plurality of trench gate structures 30 on the first main surface 3 (active surface 8) in the active region 13. In detail, the plurality of gate connection electrode films 49 are arranged on the main surface insulating film 18. The plurality of gate connection electrode films 49 each cover an end portion and an intermediate portion of a corresponding one of the trench gate structures 30 at a distance from the plurality of first trench source structures 35 and from the plurality of second trench source structures 40.

The plurality of gate connection electrode films 49 are arrayed alternately with the plurality of first trench source structures 35 in the second direction Y in the plan view. In this embodiment, the plurality of gate connection electrode films 49 are each formed in a band shape extending in the first direction X. The plurality of gate connection electrode films 49 do not face the plurality of second trench source structures 40 in the second direction Y in the plan view. The single gate connection electrode film 49 will be hereinafter described.

The gate connection electrode film 49 is connected to the corresponding gate buried electrode 33 at a portion where the gate connection electrode film 49 covers the corresponding trench gate structure 30. In this embodiment, the gate connection electrode film 49 is formed integrally with the corresponding gate buried electrode 33. That is, the gate connection electrode film 49 is a portion formed by filmily pulling out a part of the gate buried electrode 33 onto the active surface 8 (main surface insulating film 18). As a matter of course, the gate connection electrode film 49 may be formed structurally independently of the gate buried electrode 33.

The gate connection electrode film 49 has an electrode surface 49a extending along the active surface 8. The electrode surface 49a is located at a higher position than the resistance end surface 25a of the buried resistance 25. The electrode surface 49a is located at a higher position than the insulation end surface 26a of the buried insulator 26. In this embodiment, the gate connection electrode film 49 is formed in a tapered shape whose width becomes narrower toward the electrode surface 49a in a cross-sectional view.

Preferably, the electrode surface 49a is formed more widely than the trench gate structure 30 with respect to the second direction Y. Preferably, the electrode surface 49a has a portion that faces the trench gate structure 30 in the normal direction Z and a portion that faces a region located outside the trench gate structure 30 (i.e., main surface insulating film 18) in the normal direction Z.

In this embodiment, the gate connection electrode film 49 includes conductive polysilicon. The gate connection electrode film 49 has an electrode thickness TE. Preferably, the electrode thickness TE is 0.5 times or more as large as the first width W1. Preferably, the electrode thickness TE is equal to or less than the resistance depth DR (second depth D2). Particularly preferably, the electrode thickness TE is less than the resistance depth DR (second depth D2).

Preferably, the electrode thickness TE is equal to or less than the first depth D1. Particularly preferably, the electrode thickness TE is less than the first depth D1. The electrode thickness TE may be substantially equal to the resistance thickness TR. The electrode thickness TE may be equal to or more than the resistance thickness TR. The electrode thickness TE may be less than the resistance thickness TR. The electrode thickness TE may be not less than 0.05 μm and not more than 2.5 μm. Preferably, the electrode thickness TE is not less than 0.5 μm and not more than 1.5 μm. As a matter of course, the electrode thickness TE may be larger than the first depth D1. Also, the electrode thickness TE may be equal to or more than the resistance depth DR (second depth D2).

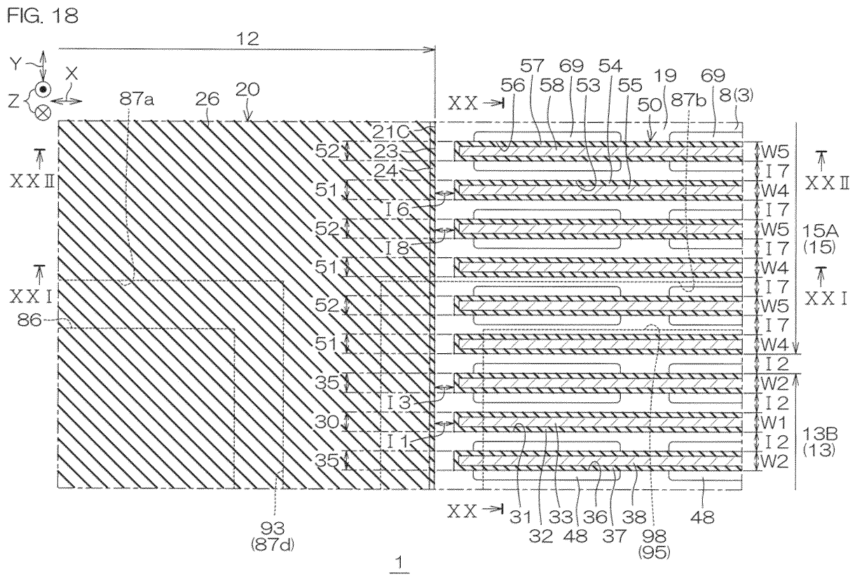

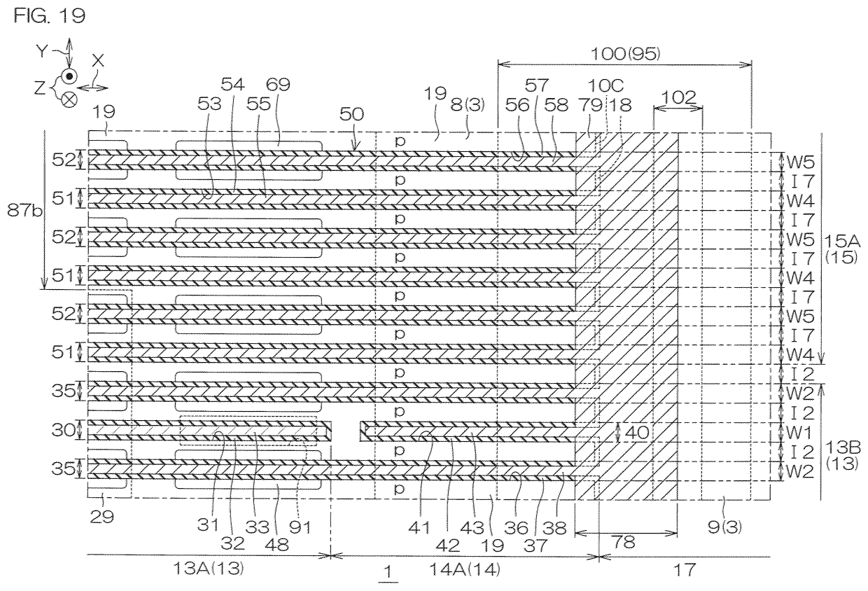

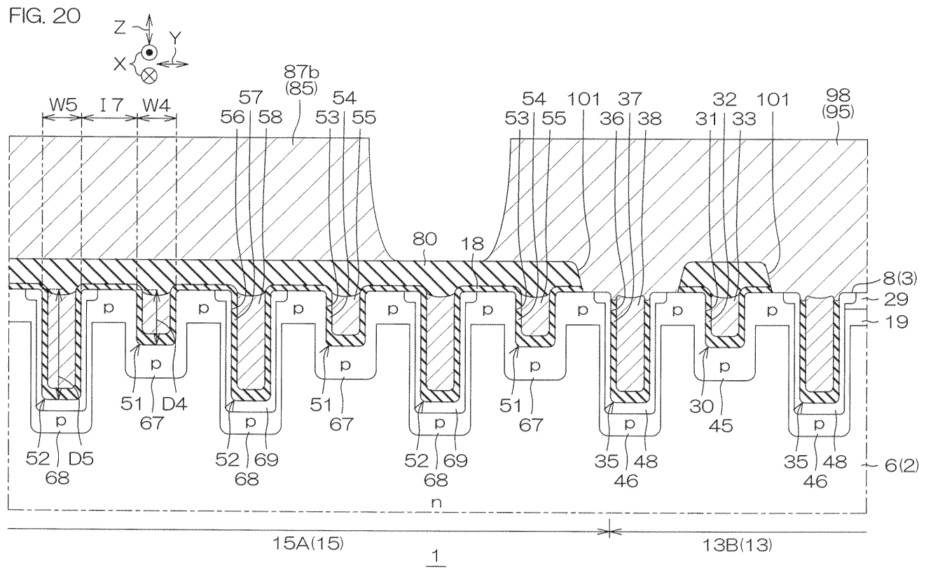

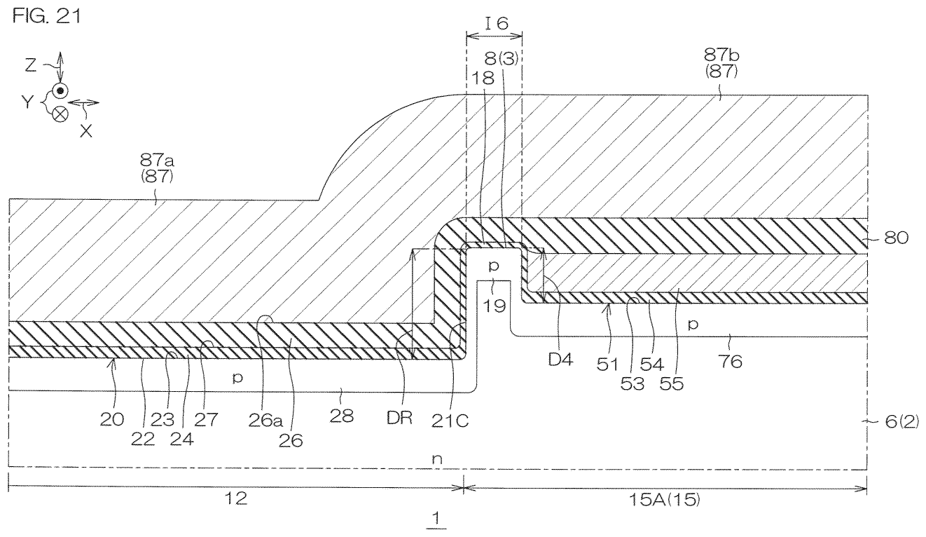

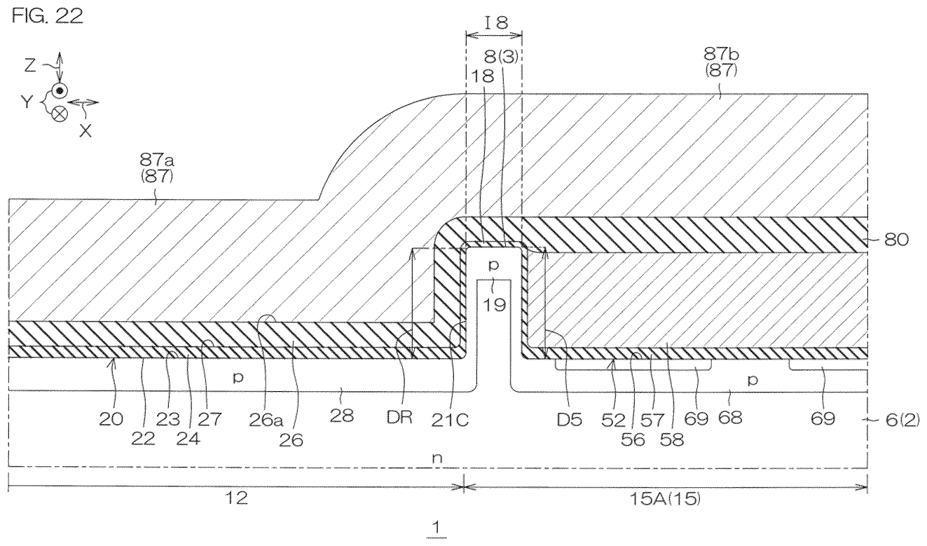

FIG. 18 is an enlarged plan view showing a layout of the resistive region 12, the active region 13, and the dummy region 15. FIG. 19 is an enlarged plan view showing a layout of the active region 13, the peripheral edge region 14, and the dummy region 15. FIG. 20 is a cross-sectional view along line XX-XX shown in FIG. 18. FIG. 21 is a cross-sectional view along line XXI-XXI shown in FIG. 18. FIG. 22 is a cross-sectional view along line XXII-XXII shown in FIG. 18.

Referring to FIG. 18 to FIG. 22, the semiconductor device 1 includes a plurality of dummy trench structures 50 formed in the first main surface 3 (active surface 8) in the dummy region 15 (first to third dummy regions 15A to 15C). A potential differing from that of the trench resistance structure 20 is given to the plurality of dummy trench structures 50. A source potential VS is given to the plurality of dummy trench structures 50. The plurality of dummy trench structures 50 pass through the body region 19 so as to reach the first semiconductor region 6, and are formed at a distance from the bottom portion of the first semiconductor region 6 toward the active surface 8 side.

The plurality of dummy trench structures 50 are incorporated into the active surface 8 for the single purpose of relaxing a local electric field concentration near the active region 13 and near the trench resistance structure 20 and improving a withstand voltage (for example, breakdown voltage). The presence or absence of the plurality of dummy trench structures 50 (dummy region 15) is optional, and a form that does not include the plurality of dummy trench structures 50 (dummy region 15) may be employed.

The plurality of dummy trench structures 50 on the first dummy region 15A side are each formed in a band shape extending in the first direction X in a region between the third connecting surface 10C and the trench resistance structure 20, and are arrayed at a distance from each other in the second direction Y. The plurality of dummy trench structures 50 on the first dummy region 15A side are formed at a distance from the trench resistance structure 20 in the first direction X, and face the trench resistance structure 20 in the first direction X.

The plurality of dummy trench structures 50 on the first dummy region 15A side face the plurality of trench gate structures 30 and the plurality of first trench source structures 35 in the second direction Y. The plurality of dummy trench structures 50 on the first dummy region 15A side pass through the third connecting surface 10C, and are exposed from the third connecting surface 10C. That is, the plurality of dummy trench structures 50 on the first dummy region 15A side face the plurality of second trench source structures 40 in the second direction Y.

The plurality of dummy trench structures 50 on the second dummy region 15B side are each formed in a band shape extending in the first direction X in a region between the fourth connecting surface 10D and the trench resistance structure 20, and are arrayed at a distance from each other in the second direction Y. The plurality of dummy trench structures 50 on the second dummy region 15B side are formed at a distance from the trench resistance structure 20 in the first direction X, and face the trench resistance structure 20 in the first direction X. The plurality of dummy trench structures 50 on the second dummy region 15B side may face the plurality of dummy trench structures 50 on the first dummy region 15A side across the trench resistance structure 20 in a one-to-one correspondence relationship.

The plurality of dummy trench structures 50 on the second dummy region 15B side face the plurality of trench gate structures 30 and the plurality of first trench source structures 35 in the second direction Y. The plurality of dummy trench structures 50 on the second dummy region 15B side pass through the fourth connecting surface 10D, and are exposed from the fourth connecting surface 10D. That is, the plurality of dummy trench structures 50 on the second dummy region 15B side face the plurality of second trench source structures 40 in the second direction Y.

The plurality of dummy trench structures 50 on the third dummy region 15C side are each formed in a band shape extending in the first direction X in a region between the second connecting surface 10B and the first active region 13A, and are arrayed at a distance from each other in the second direction Y. The plurality of dummy trench structures 50 on the third dummy region 15C side pass through at least either one of the third connecting surface 10C and the fourth connecting surface 10D, and are exposed from at least either one of the third connecting surface 10C and the fourth connecting surface 10D.

In this embodiment, the plurality of dummy trench structures 50 on the third dummy region 15C side are exposed from both the third connecting surface 10C and the fourth connecting surface 10D. The plurality of dummy trench structures 50 on the third dummy region 15C side face the plurality of trench gate structures 30, the plurality of first trench source structures 35, and the plurality of second trench source structures 40 in the second direction Y.

In this embodiment, the plurality of dummy trench 50 include a plurality of first dummy trench structures 51 and a plurality of second dummy trench structures structures 52 deeper than the plurality of first dummy trench structures 51. The plurality of first dummy trench structures 51 are each formed in a band shape extending in the first direction X, and are arrayed at a distance from each other in the second direction Y. The plurality of first dummy trench structures 51 are exposed from either one or both of the third connecting surface 10C and the fourth connecting surface 10D in the first to third dummy regions 15A to 15C.

The plurality of first dummy trench structures 51 face the trench resistance structure 20 in the first direction X in the first to second dummy regions 15A to 15B, and face the plurality of trench gate structures 30, the plurality of first trench source structures 35, and the plurality of second trench source structures 40 in the second direction Y. The plurality of first dummy trench structures 51 pass through the body region 19 so as to reach the first semiconductor region 6. The plurality of first dummy trench structures 51 are formed at a distance from the bottom portion of the first semiconductor region 6 toward the active surface 8 side.

The single first dummy trench structure 51 will be hereinafter described. The first dummy trench structure 51 has a fourth width W4 in the second direction Y, and has a fourth depth D4 in the normal direction Z. Preferably, the fourth width W4 is substantially equal to the first width W1. The fourth width W4 may be not less than 0.1 μm and not more than 3 μm. Preferably, the fourth width W4 is not less than 0.5 μm and not more than 2 μm.

The fourth depth D4 is less than the resistance depth DR (second depth D2). The fourth depth D4 may be not less than ⅓ and not more than ⅔ of the resistance depth DR (second depth D2). Preferably, the fourth depth D4 is substantially equal to the first depth D1. The fourth depth D4 may be not less than 0.1 μm and not more than 3 μm. Preferably, the fourth depth D4 is not less than 0.5 μm and not more than 1.5 μm.

The first dummy trench structure 51 is arranged at a sixth distance I6 from the trench resistance structure in the first direction X. Preferably, the sixth distance 16 is not less than 0.5 times and not more than 2 times as large as the fourth width W4. The sixth distance I6 may be substantially equal to the first distance I1. The sixth distance I6 may be not less than 0.1 μm and not more than 2.5 μm. Preferably, the sixth distance I6 is not less than 0.5 μm and not more than 1.5 μm. In this embodiment, the outermost first dummy trench structure 51 on the active region 13 side is arranged at the second distance I2 from the outermost first trench source structure 35 so as to adjoin the outermost first trench source structure 35 in the second direction Y.

The first dummy trench structure 51 includes a first dummy trench 53, a first dummy insulating film 54, and a first dummy buried electrode 55. The first dummy trench 53 is formed in the active surface 8, and defines a wall surface of the first dummy trench structure 51. A sidewall and a bottom wall of the first dummy trench 53 communicate with the third connecting surface 10C (fourth connecting surface 10D).

The first dummy insulating film 54 covers the wall surface of the first dummy trench 53, and is connected to the main surface insulating film 18 in the active surface 8. The first dummy insulating film 54 is connected to the main surface insulating film 18 in the communication portion of the third connecting surface 10C (communication portion of the fourth connecting surface 10D). The first dummy insulating film 54 may include at least one among a silicon oxide film, a silicon nitride film, and a silicon oxynitride film. In this embodiment, the first dummy insulating film 54 has a single-layer structure made of a silicon oxide film. Particularly preferably, the first dummy insulating film 54 includes a silicon oxide film made of an oxide of the chip 2.

The first dummy buried electrode 55 is arranged in the first dummy trench 53 with the first dummy insulating film 54 between the first dummy buried electrode 55 and the first dummy trench 53. The first dummy buried electrode 55 may include conductive polysilicon. The first dummy buried electrode 55 has an end surface located on the active surface 8 side with respect to the height position of the resistance end surface 25a of the buried resistance 25. The end surface of the first dummy buried electrode 55 may be located on the active surface 8 side with respect to the height position of the insulation end surface 26a of the buried insulator 26.

The plurality of second dummy trench structures 52 are arranged in a region between two first dummy trench structures 51 adjoining each other in the second direction Y. The plurality of second dummy trench structures 52 are arrayed alternately with the plurality of first dummy trench structures 51 in the second direction Y, and are each formed in a band shape extending in the first direction X. The plurality of second dummy trench structures 52 are exposed from either one or both of the third connecting surface 10C and the fourth connecting surface 10D in the first to third dummy regions 15A to 15C.

The plurality of second dummy trench structures 52 face the trench resistance structure 20 in the first direction X in the first to second dummy regions 15A to 15B, and face the plurality of trench gate structures 30, the plurality of first trench source structures 35, the plurality of second trench source structures 40, and the plurality of first dummy trench structures 51 in the second direction Y. The plurality of second dummy trench structures 52 pass through the body region 19 so as to reach the first semiconductor region 6. The plurality of second dummy trench structures 52 are formed at a distance from the bottom portion of the first semiconductor region 6 toward the active surface 8 side.

The single second dummy trench structure 52 will be hereinafter described. The second dummy trench structure 52 has a fifth width W5 in the second direction Y, and has a fifth depth D5 in the normal direction Z. Preferably, the fifth width W5 is substantially equal to the second width W2 (first width W1). The fifth width W5 may be not less than 0.1 μm and not more than 3 μm. Preferably, the fifth width W5 is not less than 0.5 μm and not more than 2 μm.

The fifth depth D5 is equal to or more than the fourth depth D4 (first depth D1). In this embodiment, the fifth depth D5 is larger than the fourth depth D4 (first depth D1). Preferably, the fifth depth D5 is not less than 1.5 times and not more than 3 times as large as the fourth depth D4 (first depth D1). Particularly preferably, the fifth depth D5 is substantially equal to the resistance depth DR (outer peripheral depth DO). The fifth depth D5 may be not less than 0.1 μm and not more than 5 μm. Particularly preferably, the fifth depth D5 is 2.5 μm or less.

The second dummy trench structure 52 is arranged at a seventh distance I7 from the first dummy trench structure 51 in the second direction Y. Preferably, the seventh distance I7 is not less than 0.5 times and not more than 2 times as large as the fifth width W5. Particularly preferably, the seventh distance I7 is less than the fifth width W5. Preferably, the seventh distance I7 is substantially equal to the second distance I2. The seventh distance I7 may be not less than 0.1 μm and not more than 2.5 μm. Preferably, the seventh distance I7 is not less than 0.5 μm and not more than 1.5 μm.

The second dummy trench structure 52 is arranged t an eighth distance I8 from the trench resistance structure 20 in the first direction X. Preferably, the eighth distance I8 is not less than 0.5 times and not more than 2 times as large as the fifth width W5. The eighth distance I8 may be substantially equal to the first distance I1. The eighth distance I8 may be not less than 0.1 μm and not more than 2.5 μm. Preferably, the eighth distance I8 is not less than 0.5 μm and not more than 1.5 μm.

The second dummy trench structure 52 includes a second dummy trench 56, a second dummy insulating film 57, and a second dummy buried electrode 58. The second dummy trench 56 is formed in the active surface 8, and defines a wall surface of the second dummy trench structure 52. A sidewall of the second dummy trench 56 communicates with the third connecting surface 10C (fourth connecting surface 10D). Also, a bottom wall of the second dummy trench 56 communicates with the outer peripheral surface 9.

The second dummy insulating film 57 covers the wall surface of the second dummy trench 56, and is connected to the main surface insulating film 18 in the active surface 8. The second dummy insulating film 57 is connected to the main surface insulating film 18 in the communication portion of the third connecting surface 10C (communication portion of the fourth connecting surface 10D) and in the communication portion of the outer peripheral surface 9. The second dummy insulating film 57 may include at least one among a silicon oxide film, a silicon nitride film, and a silicon oxynitride film. In this embodiment, the second dummy insulating film 57 has a single-layer structure made of a silicon oxide film. Particularly preferably, the second dummy insulating film 57 includes a silicon oxide film made of an oxide of the chip 2.

The second dummy buried electrode 58 is arranged in the second dummy trench 56 with the second dummy insulating film 57 between the second dummy buried electrode 58 and the second dummy trench 56. The second dummy buried electrode 58 may include conductive polysilicon. The second dummy buried electrode 58 has an end surface located on the active surface 8 side with respect to the height position of the resistance end surface 25a of the buried resistance 25. The end surface of the second dummy buried electrode 58 may be located on the active surface 8 side with respect to the height position of the insulation end surface 26a of the buried insulator 26.

The semiconductor device 1 includes a plurality of p-type fifth well regions 67 formed in a region along the plurality of first dummy trench structures 51 in the dummy region 15. In this embodiment, the fifth well region 67 has a p-type impurity concentration higher than the body region 19. As a matter of course, the p-type impurity concentration of the fifth well region 67 may be lower than the body region 19. Preferably, the p-type impurity concentration of the fifth well region 67 is substantially equal to the p-type impurity concentration of the first well region 28.

The plurality of fifth well regions 67 cover the wall surface of the corresponding first dummy trench structure 51 at a distance from the adjoining second dummy trench structure 52, and are electrically connected to the body region 19 in the surface layer portion of the active surface 8. The plurality of fifth well regions 67 are exposed from the third connecting surface 10C or from the fourth connecting surface 10D.

The plurality of fifth well regions 67 are formed at a distance from the bottom portion of the first semiconductor region 6 toward the active surface 8 side, and face the second semiconductor region 7 across a part of the first semiconductor region 6. The bottom portion of the plurality of fifth well regions 67 is located on the active surface 8 side with respect to the depth position of the bottom portion of the first well region 28. The bottom portions of the plurality of fifth well regions 67 are formed at a depth that is substantially equal to the depth of the bottom portion of the second well region 45. The plurality of fifth well regions 67 form a p-n junction portion with the first semiconductor region 6.

The semiconductor device 1 includes a plurality of p-type sixth well regions 68 formed in a region along the plurality of second dummy trench structures 52 in the dummy region 15. In this embodiment, the sixth well region 68 has a p-type impurity concentration higher than the body region 19. As a matter of course, the p-type impurity concentration of the sixth well region 68 may be lower than the body region 19. Preferably, the p-type impurity concentration of the sixth well region 68 is substantially equal to the p-type impurity concentration of the first well region 28 (fifth well region 67).

The plurality of sixth well regions 68 cover the wall surface of the corresponding second dummy trench structure 52 at a distance from the adjoining first dummy trench structure 51, and are electrically connected to the body region 19 in the surface layer portion of the active surface 8. The plurality of sixth well regions 68 are exposed from the third connecting surface 10C or from the fourth connecting surface 10D. The plurality of sixth well regions 68 are formed at a distance from the bottom portion of the first semiconductor region 6 toward the active surface 8 side, and face the second semiconductor region 7 across a part of the first semiconductor region 6.

The bottom portion of the plurality of sixth well regions 68 is located on the bottom portion of the first semiconductor region 6 side with respect to the depth position of the bottom portion of the plurality of fifth well regions 67 (the second well region 45). The bottom portions of the plurality of sixth well regions 68 are formed at a depth that is substantially equal to the depth of the bottom portion of the first well region 28 (third well region 46). The plurality of sixth well regions 68 form a p-n junction portion with the first semiconductor region 6.

The semiconductor device 1 includes a plurality of p-type second contact regions 69 formed in a region along the plurality of second dummy trench structures 52 in the dummy region 15. The second contact region 69 has a p-type impurity concentration higher than the body region 19. The p-type impurity concentration of the second contact region 69 is higher than the sixth well region 68. Preferably, the p-type impurity concentration of the second contact region 69 is substantially equal to the p-type impurity concentration of the first contact region 48.

The plurality of second contact regions 69 cover the wall surface of a corresponding one of the second dummy trench structures 52 in a corresponding one of the sixth well regions 68. The plurality of second contact regions 69 are formed in a one-to-many correspondence relationship with respect to each of the second dummy trench structures 52. The plurality of second contact regions 69 are formed at a distance from each other along the corresponding second dummy trench structure 52. The plurality of second contact regions 69 are pulled out to the surface layer portion of the body region 19 along the wall 1 surface of the corresponding second dummy trench structure 52 in the corresponding sixth well region 68, and are exposed from the active surface 8.

In this embodiment, the plurality of second contact regions 69 are each formed in a band shape extending in the first direction X in the plan view. Preferably, the length in the first direction X of the plurality of second contact regions 69 is equal to or more than the fifth width W5 of the second dummy trench structure 52. Preferably, the length of the plurality of second contact regions 69 is larger than the distance between two second contact regions X. 69 adjoining each other in the first direction Preferably, the length of the plurality of second contact regions 69 is substantially equal to the length of the plurality of first contact regions 48.

The plurality of second contact regions 69 along the single second dummy trench structure 52 face the plurality of second contact regions 69 along another second dummy trench structure 52 in the second direction Y. That is, in this embodiment, the plurality of second contact regions 69 are arrayed in a matrix manner at a distance from each other in the first direction X and second direction Y as a whole in the plan view. In this case, the plurality of second contact regions 69 may be arrayed in a matrix manner together with the plurality of first contact regions 48. Also, the plurality of second contact regions 69 may be arrayed in a matrix manner together with the plurality of first contact regions 48.

The plurality of second contact regions 69 along the single second dummy trench structure 52 may be arrayed in a deviated state in the first direction X so as to face a region between the plurality of second contact regions 69 along another second dummy trench structure 52 in the second direction Y. That is, the plurality of second contact regions 69 may be arrayed in a staggered manner at a distance from each other in the first direction X and second direction Y as a whole in the plan view. In this case, the plurality of second contact regions 69 may be arrayed in a staggered manner together with the plurality of first contact regions 48. Also, the plurality of second contact regions 69 may be arrayed in a staggered manner together with the plurality of first contact regions 48.

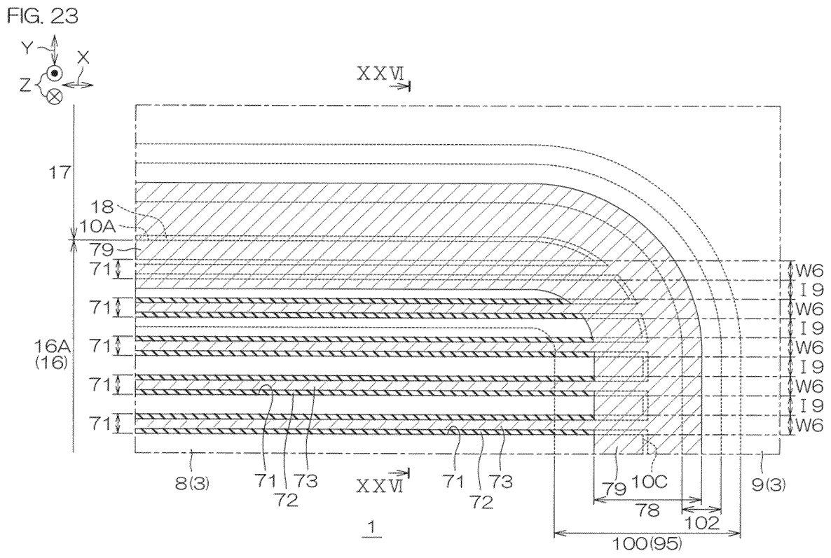

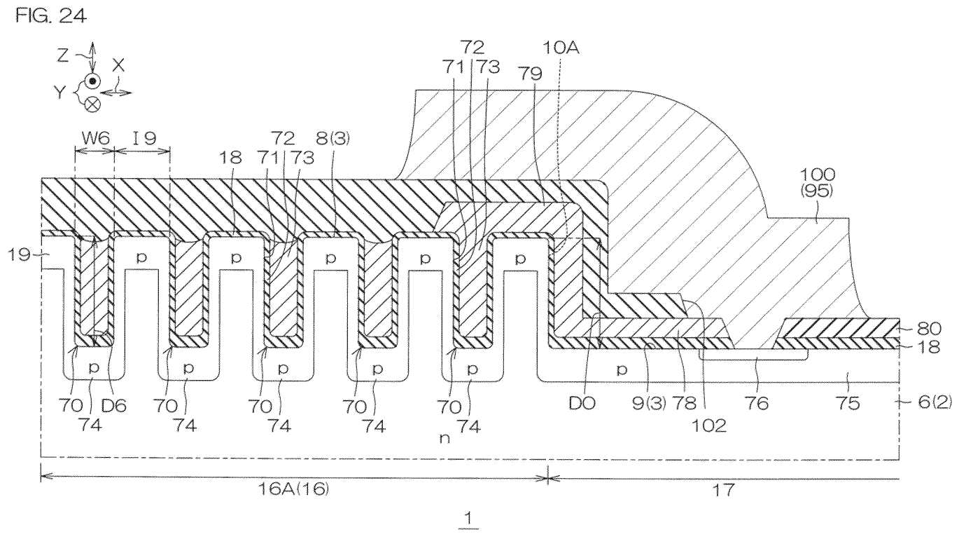

FIG. 23 is an enlarged plan view showing a layout of the termination region 16. FIG. 24 is a cross-sectional view along line XXIV-XXIV shown in FIG. 23. Referring to FIG. 23 and FIG. 24, the semiconductor device 1 includes a plurality of trench termination structures 70 formed in the first main surface 3 (active surface 8) in the termination region 16. A potential differing from that of the trench resistance structure 20 is given to the plurality of trench termination structures 70. A source potential VS is given to the plurality of trench termination structures 70. The plurality of trench termination structures 70 pass through the body region 19 so as to reach the first semiconductor region 6, and are formed at a distance from the bottom portion of the first semiconductor region 6 toward the active surface 8 side.

The plurality of trench termination structures 70 are incorporated into the active surface 8 for the single purpose of relaxing a local electric field concentration at the peripheral edge of the active surface 8 and near the trench resistance structure 20 and improving a withstand voltage (for example, breakdown voltage). The presence or absence of the plurality of trench termination structures 70 (termination region 16) is optional, and a form that does not include the plurality of trench termination structures 70 (termination region 16) may be employed.

The plurality of trench termination structures 70 on the first termination region 16A side are each formed in a band shape extending in the first direction X in a region between the first connecting surface 10A and the trench resistance structure 20, and are arrayed at a distance from each other in the second direction Y. The plurality of trench termination structures 70 on the first termination region 16A side are formed at a distance from the trench resistance structure 20 in the second direction Y, and face the trench resistance structure 20 in the second direction Y. The plurality of trench termination structures 70 on the first termination region 16A side are further formed at a distance from the outermost dummy trench structure 50 (in this embodiment, first dummy trench structure 51) in the second direction Y, and face the outermost dummy trench structure 50 in the second direction Y.

The plurality of trench termination structures 70 on the first termination region 16A side pass through at least either one of the third connecting surface 10C and the fourth connecting surface 10D, and are exposed from at least either one of the third connecting surface 10C and the fourth connecting surface 10D. In this embodiment, the plurality of trench termination structures 70 on the first termination region 16A side are exposed from both the third connecting surface 10C and the fourth connecting surface 10D.

The plurality of trench termination structures 70 on the second termination region 16B side are each formed in a band shape extending in the first direction X in a region between the second connecting surface 10B and the third dummy region 15C, and are arrayed at a distance from each other in the second direction Y. The plurality of trench termination structures 70 on the second termination region 16B side are formed at a distance from the outermost dummy trench structure 50 (in this embodiment, first dummy trench structure 51) in the second direction Y, and face the outermost dummy trench structure 50 in the second direction Y.

The plurality of trench termination structures 70 on the second termination region 16B side pass through at least either one of the third connecting surface 10C and the fourth connecting surface 10D, and are exposed from at least either one of the third connecting surface 10C and the fourth connecting surface 10D. In this embodiment, the plurality of trench termination structures 70 on the second termination region 16B side are exposed from both the third connecting surface 10C and the fourth connecting surface 10D.

The single trench termination structure 70 will be hereinafter described. The trench termination structure 70 has a sixth width W6 in the second direction Y, and has a sixth depth D6 in the normal direction Z. Preferably, the sixth width W6 is substantially equal to the first width W1 (second width W2). The sixth width W6 may be not less than 0.1 μm and not more than 3 μm. Preferably, the sixth width W6 is not less than 0.5 μm and not more than 2 μm.

The sixth depth D6 is equal to or more than the first depth D1. In this embodiment, the sixth depth D6 is larger than the first depth D1. Preferably, the sixth depth D6 is not less than 1.5 times and not more than 3 times as large as the first depth D1. Particularly preferably, the sixth depth D6 is substantially equal to the resistance depth DR (outer peripheral depth DO). The sixth depth D6 may be not less than 0.1 μm and not more than 5 μm. Particularly preferably, the second depth D2 is 2.5 μm or less.

The plurality of trench termination structures 70 are arrayed at a ninth distance I9 from each other in the second direction Y. Also, in this embodiment, the outermost trench termination structure 70 on the trench resistance structure 20 side is arranged at the ninth distance I9 from the trench resistance structure 20 and from the outermost dummy trench structure 50 (in this embodiment, first dummy trench structure 51) in the second direction Y.

Preferably, the ninth distance I9 is not less than 0.5 times and not more than 2 times as large as the sixth width W6. Particularly preferably, the ninth distance 19 is less than the sixth width W6. Preferably, the ninth distance I9 is substantially equal to the second distance 12. The ninth distance I9 may be not less than 0.1 μm and not more than 2.5 μm. Preferably, the ninth distance I9 is not less than 0.5 μm and not more than 1.5 μm.

The trench termination structure 70 includes a termination trench 71, a termination insulating film 72, and a termination buried electrode 73. The termination trench 71 is formed in the active surface 8, and defines a wall surface of the trench termination structure 70. A sidewall of the termination trench 71 communicates with the third connecting surface 10C and with the fourth connecting surface 10D. A bottom wall of the termination trench 71 communicates with the outer peripheral surface 9.

The termination insulating film 72 covers the wall surface of the termination trench 71, and is connected to the main surface insulating film 18 in the active surface 8. The termination insulating film 72 is connected to the main surface insulating film 18 in the communication portion of the third connecting surface 10C, in the communication portion of the fourth connecting surface 10D, and in the communication portion of the outer peripheral surface 9. The termination insulating film 72 may include at least one among a silicon oxide film, a silicon nitride film, and a silicon oxynitride film. In this embodiment, the termination insulating film 72 has a single-layer structure made of a silicon oxide film. Particularly preferably, the termination insulating film 72 includes a silicon oxide film made of an oxide of the chip 2.

The termination buried electrode 73 is arranged in the termination trench 71 with the termination insulating film 72 between the termination buried electrode 73 and the termination trench 71. The termination buried electrode 73 may include conductive polysilicon. The termination buried electrode 73 has an end surface located on the active surface 8 side with respect to the height position of the resistance end surface 25a of the buried resistance 25. The end surface of the termination buried electrode 73 may be located on the active surface 8 side with respect to the height position of the insulation end surface 26a of the buried insulator 26.

The semiconductor device 1 includes a plurality of p-type seventh well regions 74 formed in a region along the plurality of trench termination structures 70 in the termination region 16. In this embodiment, the seventh well region 74 has a p-type impurity concentration higher than the body region 19. As a matter of course, the p-type impurity concentration of the seventh well region 74 may be lower than the body region 19. Preferably, the p-type impurity concentration of the seventh well region 74 is substantially equal to the p-type impurity concentration of the first well region 28.

The plurality of seventh well regions 74 cover the wall surface of corresponding one of the trench termination structures 70 at a distance from the adjoining trench termination structure 70, and are electrically connected to the body region 19 in the surface layer portion of the active surface 8. The plurality of seventh well regions 74 extend in a band shape along the corresponding trench termination structure 70 in the plan view, and are exposed from the third connecting surface 10C and from the fourth connecting surface 10D.

The plurality of seventh well regions 74 are formed at a distance from the bottom portion of the first semiconductor region 6 toward the active surface 8 side, and face the second semiconductor region 7 across a part of the first semiconductor region 6. The bottom portions of the plurality of seventh well regions 74 are located on the bottom portion side of the first semiconductor region 6 with respect to the depth position of the bottom portions of the plurality of second well regions 45. The bottom portions of the plurality of seventh well regions 74 are formed at a depth that is substantially equal to the depth of the bottom portion of the first well region 28 (third well region 46). The plurality of seventh well regions 74 form a p-n junction portion with the first semiconductor region 6.

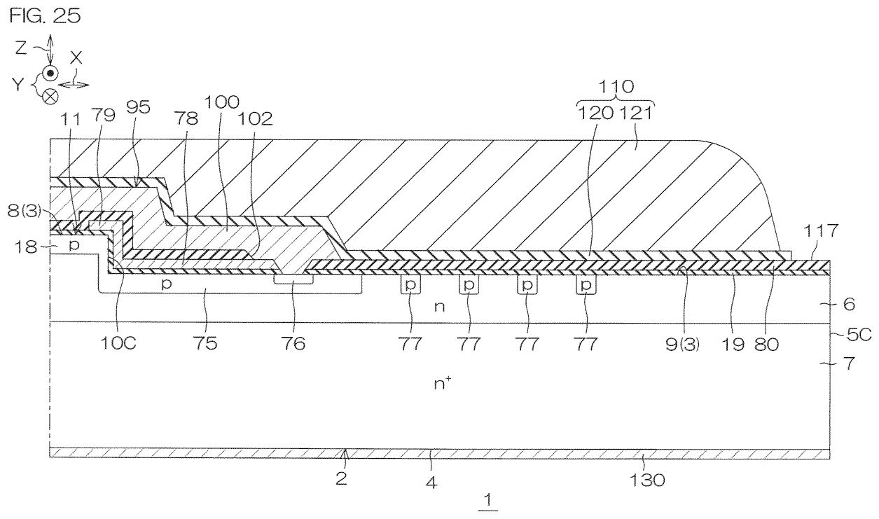

Next, a structure of the outer peripheral region 17 will be described with reference to the cross-sectional view of FIG. 25. Referring to FIG. 25, the semiconductor device 1 includes a p-type outer well region 75 formed in the surface layer portion of the outer peripheral surface 9. The outer well region 75 has a p-type impurity concentration lower than the first contact region 48. In this embodiment, the p-type impurity concentration of the outer well region 75 is higher than the body region 19. As a matter of course, the p-type impurity concentration of the outer well region 75 may be lower than the body region 19. Preferably, the outer well region 75 has a p-type impurity concentration that is substantially equal to that of the first well region 28.

The outer well region 75 is formed at a distance from the peripheral edge (first to fourth side surfaces 5A to 5D) of the outer peripheral surface 9 toward the active surface 8 side in the plan view, and extends in a band shape along the active surface 8. In this embodiment, the outer well region 75 is formed in an annular shape (in detail, rectangularly annular shape) surrounding the active surface 8 in the plan view. The outer well region 75 extends from the surface layer portion of the outer peripheral surface 9 toward the surface layer portion of the first to fourth connecting surfaces 10A to 10D.

The outer well region 75 is electrically connected to the body region 19 in the surface layer portion of the active surface 8. The outer well region 75 is connected to the third well region 46 in the communication portion of the third connecting surface 10C (fourth connecting surface 10D) and in the communication portion of the first trench source structure 35. The outer well region 75 is connected to the fourth well region 47 in the communication portion of the third connecting surface 10C (fourth connecting surface 10D) and in the communication portion of the second trench source structure 40.

The outer well region 75 is connected to the fifth well region 67 in the communication portion of the third connecting surface 10C (fourth connecting surface 10D) and in the communication portion of the first dummy trench structure 51. The outer well region 75 is connected to the sixth well region 68 in the communication portion of the third connecting surface 10C (fourth connecting surface 10D) and in the communication portion of the second dummy trench structure 52. The outer well region 75 is connected to the seventh well region 74 in the communication portion of the third connecting surface 10C (fourth connecting surface 10D) and in the communication portion of the trench termination structure 70.

The outer well region 75 is formed at a distance from the bottom portion of the first semiconductor region 6 toward the outer peripheral surface 9 side, and faces the second semiconductor region 7 across a part of the first semiconductor region 6. The outer well region 75 is located closer to the bottom portion of the first semiconductor region 6 than the bottom wall 22 of the trench resistance structure 20. The outer well region 75 is located closer to the bottom portion of the first semiconductor region 6 than the bottom wall of the first trench source structure 35.

The bottom portion of the outer well region 75 is located closer to the bottom portion of the first semiconductor region 6 than the bottom portion of the first contact region 48. Preferably, the bottom portion of the outer well region 75 is formed at a depth position that is substantially equal to that of the bottom portion of the first well region 28 (third well region 46). The outer well region 75 forms a p-n junction portion with the first semiconductor region 6.

The semiconductor device 1 includes a p-type outer contact region 76 formed in the surface layer portion of the outer well region 75. The outer contact region 76 has a p-type impurity concentration higher than the body region 19. The p-type impurity concentration of the outer contact region 76 is higher than the outer well region 75. Preferably, the p-type impurity concentration of the outer contact region 76 is substantially equal to the p-type impurity concentration of the first contact regions 48.

The outer contact region 76 is formed in the surface layer portion of the outer well region 75 at a distance from the peripheral edge of the active surface 8 (first to fourth connecting surfaces 10A to 10D) and from the peripheral edge of the outer peripheral surface 9 (first to fourth side surfaces 5A to 5D) in the plan view, and is formed in a band shape extending along the active surface 8. In this embodiment, the outer contact region 76 is formed in an annular shape (in detail, rectangularly annular shape) surrounding the active surface 8 in the plan view.

The outer contact region 76 is formed at a distance from the bottom portion of the outer well region 75 toward the outer peripheral surface 9 side, and faces the first semiconductor region 6 across a part of the outer well region 75. The outer contact region 76 is located closer to the bottom portion of the first semiconductor region 6 than the bottom wall 22 of the trench resistance structure 20. The outer contact region 76 is located closer to the bottom portion of the first semiconductor region 6 than the bottom wall of the first trench source structure 35. Preferably, the bottom portion of the outer contact region 76 is formed at a depth position that is substantially equal to that of the bottom portion of the first contact regions 48.

The semiconductor device 1 includes at least one (preferably, not less than two and not more than twenty) p-type field region 77 formed in a region between the peripheral edge of the outer peripheral surface 9 and the outer well region 75 in the surface layer portion of the outer peripheral surface 9. In this embodiment, the semiconductor device 1 includes four field regions 77. The plurality of field regions 77 are formed in an electrically floating state, and relax the electric field in the chip 2 in the outer peripheral surface 9.

The number, the width, the depth, the p-type impurity concentration, etc., of the field region 77 are optional, and various values are taken in accordance with the electric field to be relaxed. The field region 77 may have a p-type impurity concentration lower than the outer contact region 76. The field region 77 may have a p-type impurity concentration higher than the outer well region 75. The field region 77 may have a p-type impurity concentration lower than the outer well region 75.

The plurality of field regions 77 are arrayed at a distance from the outer well region 75 side toward the peripheral edge side of the outer peripheral surface 9. The plurality of field regions 77 are formed in a band shape extending along the active surface 8 in the plan view. In this embodiment, the plurality of field regions 77 are formed in an annular shape (in detail, rectangularly annular shape) surrounding the active surface 8 in the plan view.

The plurality of field regions 77 are formed at a distance from the bottom portion of the first semiconductor region 6 toward the outer peripheral surface 9 side, and face the second semiconductor region 7 across a part of the first semiconductor region 6. The plurality of field regions 77 are located closer to the bottom portion of the first semiconductor region 6 than the bottom wall 22 of the trench resistance structure 20.

The plurality of field regions 77 are located closer to the bottom portion of the first semiconductor region 6 than the bottom wall of the first trench source structure 35. The bottom portion of the plurality of field regions 77 is located closer to the bottom portion of the first semiconductor region 6 than the bottom portion of the first contact region 48. The bottom portion of the plurality of field regions 77 may be formed at a depth position that is substantially equal to that of the bottom portion of the third well region 46.

The semiconductor device 1 includes a sidewall wiring line 78 formed on the outer peripheral surface 9 so as to cover at least one among the first to fourth connecting surfaces 10A to 10D. In detail, the sidewall wiring line 78 is arranged on the main surface insulating film 18. The sidewall wiring line 78 functions also as a sidewall structure that lessens a level difference formed between the active surface 8 and the outer peripheral surface 9.

Preferably, the sidewall wiring line 78 is formed in a band shape extending along at least either one of the third connecting surface 10C and the fourth connecting surface 10D. In this embodiment, the sidewall wiring line 78 is formed in an annular shape (in detail, rectangularly annular shape) extending along the first to fourth connecting surfaces 10A to 10D so as to surround the active surface 8 in the plan view. A part, which covers four corners of the active surface 8, of the sidewall wiring line 78 is formed in a curved shape toward the outer peripheral surface 9 side.

The sidewall wiring line 78 includes a portion that filmily extends along the outer peripheral surface 9 and a portion that filmily extends along the first to fourth connecting surfaces 10A to 10D. A portion, which is located on the outer peripheral surface 9, of the sidewall wiring line 78 may filmily cover the outer peripheral surface 9 in a region on the outer peripheral surface 9 side with respect to the active surface 8. The portion, which is located on the outer peripheral surface 9, of the sidewall wiring line 78 may have a thickness less than the thickness of the active mesa 11 (outer peripheral depth DO).

The sidewall wiring line 78 faces the outer well region 75 across the main surface insulating film 18 in the outer peripheral surface 9. The sidewall wiring line 78 may face the outer contact region 76 across the main surface insulating film 18. In this embodiment, the sidewall wiring line 78 is formed at a distance from the field region 77 toward the active surface 8 side in the plan view.

The sidewall wiring line 78 faces the third well region 46, the fourth well region 47, the fifth well region 67, the sixth well regions 68, the seventh well region 74, and the outer well region 75 across the main surface insulating film 18 in the first to fourth connecting surfaces 10A to 10D. In this embodiment, the sidewall wiring line 78 also faces the body region 19 across the main surface insulating film 18.

The sidewall wiring line 78 covers an exposed portion of the first trench source structure 35, an exposed portion of the second trench source structure 40, an exposed portion of the first dummy trench structure 51, an exposed portion of the second dummy trench structure 52, and an exposed portion of the trench termination structure 70 in the first to fourth connecting surfaces 10A to 10D.

Hence, the sidewall wiring line 78 is electrically connected to the first trench source structure 35, to the second trench source structure 40, to the first dummy trench structure 51, to the second dummy trench structure 52, and to the trench termination structure 70. That is, the sidewall wiring line 78 gives a source potential VS to a to-be-connected object from the outer peripheral surface 9 side.

The sidewall wiring line 78 has an overlap portion 79 that rides on an edge portion of the active surface 8 from at least one among the first to fourth connecting surfaces 10A to 10D. The overlap portion 79 filmily covers the active surface 8 in the plan view, and is formed in a band shape extending along the edge portion of the active surface 8. In this embodiment, the overlap portion 79 is formed in an annular shape (in detail, rectangularly annular shape) surrounding the inward portion of the active surface 8 in the plan view.

The overlap portion 79 is formed at a distance from the trench resistance structure 20 toward the peripheral edge side of the active surface 8 on the active surface 8. The overlap portion 79 is electrically connected to the first trench source structure 35, to the second trench source structure 40, to the first dummy trench structure 51, to the second dummy trench structure 52, and to the trench termination structure 70.

In this embodiment, the sidewall wiring line 78 includes conductive polysilicon, and is formed integrally with the first source buried electrode 38, the second source buried electrode 43, the first dummy buried electrode 55, the second dummy buried electrode 58, and the termination buried electrode 73. As a matter of course, the sidewall wiring line 78 may be formed structurally independently of the first source buried electrode 38, the second source buried electrode 43, the first dummy buried electrode 55, the second dummy buried electrode 58, and the termination buried electrode 73.

The semiconductor The device 1 includes an interlayer insulating film 80 covering the main surface insulating film 18. The interlayer insulating film 80 covers the active surface 8, the outer peripheral surface 9, and the first to fourth connecting surfaces 10A to 10D with the main surface insulating film 18 between the interlayer insulating film 80 and each of the active surface 8, the outer peripheral surface 9, and the first to fourth connecting surfaces 10A to 10D. The interlayer insulating film 80 covers the trench resistance structure 20, the trench gate structure 30, the first trench source structure 35, the second trench source structure 40, the first dummy trench structure 51, the second dummy trench structure 52, and the trench termination structure 70 in the active surface 8.

The interlayer insulating film 80 enters the resistance trench 23 from above the main surface insulating film 18 in the resistive region 12. The interlayer insulating film 80 enters the resistance trench 23 from the entire periphery (first to fourth sidewalls 21A to 21D) of the resistance trench 23. The interlayer insulating film 80 covers the resistance insulating film 24 in the peripheral edge (first to fourth sidewalls 21A to 21D) of the resistance trench 23, and is connected to the buried insulator 26.

Preferably, the interlayer insulating film 80 is connected to the resistance insulating film 24 at a distance from the peripheral edge of the buried resistance 25 in the plan view. In this embodiment, the interlayer insulating film 80 forms a single insulating film together with the buried insulator 26. That is, in this embodiment, the buried insulator 26 is formed by use of a part of the interlayer insulating film 80. As a matter of course, the interlayer insulating film 80 may be formed structurally independently of the buried insulator 26.

The interlayer insulating film 80 covers the outer well region 75, the outer contact region 76, and the plurality of field regions 77 with the main surface insulating film 18 between the interlayer insulating film 80 and each of the outer well region 75, the outer contact region 76, and the field regions 77 in the outer peripheral region 17. The interlayer insulating film 80 covers the sidewall wiring line 78 in the first to fourth connecting surfaces 10A to 10D.

In this embodiment, the interlayer insulating film 80 is continuous with the first to fourth side surfaces 5A to 5D. As a matter of course, a wall portion of the interlayer insulating film 80 may be formed at a distance inwardly from the peripheral edge of the outer peripheral surface 9, and may expose the first semiconductor region 6 from the peripheral edge portion of the outer peripheral surface 9. The interlayer insulating film 80 may include at least one among a silicon oxide film, a silicon nitride film, and a silicon oxynitride film. In this embodiment, the interlayer insulating film 80 includes a silicon oxide film.

Referring to FIG. 1 to FIG. 17 (particularly, FIG. 5 and FIG. 6), the semiconductor device 1 includes a gate electrode 85 arranged on the trench resistance structure 20. The gate electrode 85 has a resistance value lower than the resistance value of the trench resistance structure 20. In detail, the gate electrode 85 has a resistance value lower than the resistance value of the buried resistance 25.

Preferably, the gate electrode 85 is thicker than the buried resistance 25. Particularly preferably, the gate electrode 85 is thicker than the buried insulator 26. Preferably, the gate electrode 85 is thicker than the interlayer insulating film 80. Preferably, the gate electrode 85 has a thickness larger than the first depth D1. Preferably, the gate electrode 85 has a thickness larger than the resistance depth DR (outer peripheral depth DO, second depth D2). The gate electrode 85 may have a thickness of not less than 0.5 μm and not more than 10 μm. Preferably, the thickness of the gate electrode 85 is not less than 1 μm and not more than 5 μm.

The gate electrode 85 may include at least one among a Ti film, a TiN film, a W film, an Al film, a Cu film, an Al alloy film, a Cu alloy film, and a conductive polysilicon film. The gate electrode 85 may include at least one among a pure Cu film (whose purity is 99% or more), a pure Al film (whose purity is 99% or more), an AlCu alloy film, an AlSi alloy film, and an AlsiCu alloy film. In this embodiment, the gate electrode 85 has a layered structure including a Ti film and an Al alloy film (in this embodiment, AlSiCu alloy film) stacked in this order from the chip 2 side. The gate electrode 85 may be referred to as a “gate metal.”

In this embodiment, the gate electrode 85 includes a gate pad 86, a gate wiring line 87, and a gate subpad 88. A gate potential VG is given to the gate pad 86 from the outside. The gate pad 86 is arranged directly on the trench resistance structure 20 in the resistive region 12. In this embodiment, the gate pad 86 is arranged on the inward portion of the active surface 8 at a distance from the peripheral edge of the active surface 8, and is not arranged on the outer peripheral surface 9.

In this embodiment, the gate pad 86 has a planar area less than the planar area of the trench resistance structure 20 (resistance trench 23), and is arranged only in a region surrounded by the peripheral edge of the trench resistance structure 20 at a distance inwardly from the peripheral edge of the trench resistance structure 20. That is, the gate pad 86 is arranged directly on the trench resistance structure 20 at a distance from the active region 13 (first to third active regions 13A to 13C), from the dummy region 15, and from the termination region 16, does not face the active region 13, the dummy region 15, and the termination region 16 in the normal direction Z.

Preferably, the gate pad 86 has a planar area of not less than 1% and not more than 25% of the planar area of the first main surface 3. Preferably, the planar area of the gate pad 86 is not less than 5% and not more than 20% of the planar area of the first main surface 3. As a matter of course, the gate pad 86 may have a planar area larger than the planar area of the trench resistance structure 20. In this case, the gate pad 86 may face at least one among the active region 13, the dummy region 15, and the termination region 16 in the normal direction Z.

In detail, the gate pad 86 is arranged on the buried insulator 26 so as to face the buried resistance 25. The gate pad 86 has a planar area that is equal to or more than the planar area of the buried resistance 25. Preferably, the planar area of the gate pad 86 is larger than the planar area of the buried resistance 25. As a matter of course, the planar area of the gate pad 86 may be set to be less than the planar area of the buried resistance 25.

The gate pad 86 is arranged at the inward portion of the resistance trench 23 at a distance from the peripheral edge (first to fourth sidewalls 21A to 21D) of the resistance trench 23. That is, the gate pad 86 is arranged so as to avoid a stepped portion formed between the active surface 8 and the resistance trench 23.

In this embodiment, the gate pad 86 is formed at a distance inwardly from the entire periphery of the first to fourth sidewalls 21A to 21D. That is, the gate pad 86 is arranged only on the buried insulator 26, and is not arranged on the interlayer insulating film 80. In this embodiment, the gate pad 86 is formed in a quadrangular shape having four sides parallel to the peripheral edge of the resistance trench 23 in the plan view. As a matter of course, the gate pad 86 may be formed in a polygonal shape or in a circular shape in the plan view.

The gate pad 86 has a first covering portion 86a covering the buried resistance 25 with the buried insulator 26 between the gate pad 86 and the first covering portion 86a, and has a second covering portion 86b covering the insulating region 27 with the buried insulator 26 between the gate pad 86 and the second covering portion 86b. Preferably, the facing area of the second covering portion 86b with respect to the insulating region 27 is larger than the facing area of the first covering portion 86a with respect to the buried resistance 25. This structure is particularly preferable if the planar area of the insulating region 27 is larger than the planar area of the buried resistance 25. As a matter of course, the facing area of the second covering portion 86b with respect to the insulating region 27 may be smaller than the facing area of the first covering portion 86a with respect to the buried resistance 25.

In this embodiment, the gate pad 86 has a portion that is located on the bottom wall 22 side of the resistance trench 23 with respect to the height position of the active surface 8 and a portion that protrudes upwardly with respect to the height position of the active surface 8. The gate pad 86 passes through the buried insulator 26 in the portion located on the bottom wall 22 side of the resistance trench 23, and is electrically connected to the buried resistance 25. In detail, the gate pad 86 is connected to the buried resistance 25 through a first resistance opening 89 formed in the buried resistance 25.

The first resistance opening 89 is formed in a band shape extending in the first direction X in the plan view. The planar shape and the number of the first resistance opening 89 are optional. For example, the plurality of first resistance openings 89 each of which has a quadrangular shape in the plan view may be formed at a distance from each other in either one or both of the first direction X and second direction Y.

Preferably, the planar area of a connection portion of the gate pad 86 with respect to the buried resistance 25 is less than the planar area of a non-connection portion of the gate pad 86 with respect to the buried resistance 25. As a matter of course, the planar area of the connection portion of the gate pad 86 with respect to the buried resistance 25 may be larger than the planar area of the non-connection portion of the gate pad 86 with respect to the buried resistance 25.

The gate wiring line 87 is electrically connected to the gate pad 86 in the resistive region 12 via the trench resistance structure 20, and is electrically connected to the plurality of trench gate structures 30 in the active region 13. The gate wiring line 87 transmits a gate potential VG given to the gate pad 86 to the plurality of trench gate structures 30.

The gate wiring line 87 is arranged directly on the trench resistance structure 20 at a distance from the gate pad 86 in the resistive region 12, and is selectively drawn around from the resistive region 12 to the active region 13. In this embodiment, the gate wiring line 87 is arranged on the inward portion of the active surface 8 at a distance from the peripheral edge of the active surface 8, and is not arranged on the outer peripheral surface 9.

In this embodiment, the gate wiring line 87 includes a resistance wiring line 87a, a first gate wiring line 87b, a second gate wiring line 87c, and a third gate wiring line 87d. The resistance wiring line 87a is a portion that is located directly on the trench resistance structure 20 and that is connected to the trench resistance structure 20. In this embodiment, the resistance wiring line 87a is formed in a band shape extending in the first direction X so as to intersect (in detail, perpendicularly intersect) the trench resistance structure 20 in the plan view, and is arranged in a region between the first sidewall 21A of the trench resistance structure 20 and the gate pad 86.

In detail, the resistance wiring line 87a is formed in a band shape narrower than the trench resistance structure 20 with respect to the second direction Y, and is arranged in a region between the first sidewall 21A and the gate pad 86 at a distance from the first sidewall 21A and from the gate pad 86. That is, the resistance wiring line 87a has two sides that cross an inward portion of the trench resistance structure 20 in the plan view.

In this embodiment, the two sides of the resistance wiring line 87a intersect (in detail, perpendicularly intersect) the third sidewall 21C and the fourth sidewall 21D of the trench resistance structure 20. As a matter of course, the resistance wiring line 87a may have a side that crosses the inward portion of the trench resistance structure 20 and a side that is located outside the trench resistance structure 20.

In detail, the resistance wiring line 87a is arranged on the buried insulator 26 so as to face the buried resistance 25 at a position differing from that of the gate pad 86. The resistance wiring line 87a may have a planar area that is equal to or more than the planar area of the buried resistance 25, and may have a planar area less than the planar area of the buried resistance 25. The resistance wiring line 87a is arranged in a region between the first sidewall 21A and the gate pad 86 at a distance from the first sidewall 21A and from the gate pad 86 in the plan view.

The resistance wiring line 87a has two sides that cross an inward portion of the buried resistance 25 in the plan view. As a matter of course, the resistance wiring line 87a may have a side that crosses the inward portion of the buried resistance 25 and a side that is located outside the buried resistance 25. The buried resistance 25 has a portion that faces the buried resistance 25 across the buried insulator 26 and a portion that faces the insulating region 27 across the buried insulator 26. The two sides of the buried resistance 25 intersect (in detail, perpendicularly intersect) the third sidewall 21C and the fourth sidewall 21D of the resistance trench 23, and are pulled out onto the interlayer insulating film 80 from above the buried insulator 26.

In this embodiment, the resistance wiring line 87a has a portion that is located on the bottom wall 22 side of the resistance trench 23 with respect to the height position of the active surface 8 and a portion that protrudes upwardly with respect to the height position of the active surface 8. The resistance wiring line 87a passes through the buried insulator 26 in a portion located on the bottom wall 22 side of the resistance trench 23, and is electrically connected to the buried resistance 25. In detail, the resistance wiring line 87a is connected to the buried resistance 25 through the second resistance opening 90 formed in the buried insulator 26 at a distance from the first resistance opening 89 toward the first sidewall 21A side.

In this embodiment, the second resistance opening 90 is formed in a band shape extending in the first direction X in the plan view. That is, the second resistance opening 90 extends in substantially parallel with the first resistance opening 89. The planar shape and the number of the second resistance openings 90 are optional. For example, the plurality of second resistance openings 90 each of which has a quadrangular shape in the plan view may be formed at a distance from each other in either one or both of the first direction X and second direction Y.

Preferably, the planar area of a connection portion of the resistance wiring line 87a with respect to the buried resistance 25 is less than the planar area of a non-connection portion of the resistance wiring line 87a with respect to the buried resistance 25. As a matter of course, the planar area of the connection portion of the resistance wiring line 87a with respect to the buried resistance 25 may be larger than the planar area of the non-connection portion of the resistance wiring line 87a with respect to the buried resistance 25.

The facing area of the resistance wiring line 87a (gate wiring line 87) with respect to the buried resistance 25 may be larger than the facing area of the gate pad 86 with respect to the buried resistance 25. As a matter of course, the facing area of the resistance wiring line 87a (gate wiring line 87) with respect to the buried resistance 25 may be less than the facing area of the gate pad 86 with respect to the buried resistance 25.

The first gate wiring line 87b is arranged on the interlayer insulating film 80. The first gate wiring line 87b is pulled out from the resistance wiring line 87a to a region on the third connecting surface 10C side, and linearly extends along the first connecting surface 10A and along the third connecting surface 10C. The first gate wiring line 87b is electrically connected to the trench resistance structure 20 through the resistance wiring line 87a in the resistive region 12, and is electrically connected to the plurality of trench gate structures 30 in the active region 13.

In detail, the first gate wiring line 87b is pulled out in a linear shape extending in the first direction X from the resistance wiring line 87a (resistive region 12) to the first dummy region 15A, and covers the plurality of dummy trench structures 50 with the interlayer insulating film 80 between the first gate wiring line 87b and the dummy trench structures 50 in the first dummy region 15A. In this embodiment, the first gate wiring line 87b covers the plurality of first dummy trench structures 51 and the plurality of second dummy trench structures 52 with the interlayer insulating film 80 between the first gate wiring line 87b and the first and second dummy trench structures 51 and 52.

The first gate wiring line 87b is drawn around in a linear shape extending along the second direction Y from the first dummy region 15A toward the active region 13 side, and intersects (in detail, perpendicularly intersects) the plurality of trench gate structures 30 in the first active region 13A and in the second active region 13B. The first gate wiring line 87b is electrically connected to the plurality of gate connection electrode films 49 through the plurality of gate openings 91 formed in the interlayer insulating film 80 in the active region 13. Hence, the first gate wiring line 87b is electrically connected to the plurality of trench gate structures 30 through the plurality of gate connection electrode films 49.

The second gate wiring line 87c is arranged on the interlayer insulating film 80. The second gate wiring line 87c is pulled out from the resistance wiring line 87a to a region on the fourth connecting surface 10D side, and linearly extends along the first connecting surface 10A and along the fourth connecting surface 10D. The second gate wiring line 87c is electrically connected to the trench resistance structure 20 through the resistance wiring line 87a in the resistive region 12, and is electrically connected to the plurality of trench gate structures 30 in the active region 13.

The second gate wiring line 87c is pulled out in a linear shape extending in the first direction X from the resistance wiring line 87a (resistive region 12) toward the second dummy region 15B, and covers the plurality of dummy trench structures 50 with the interlayer insulating film 80 between the second gate wiring line 87c and the dummy trench structures 50 in the second dummy region 15B. In this embodiment, the second gate wiring line 87c covers the plurality of first dummy trench structures 51 and the plurality of second dummy trench structures 52 with the interlayer insulating film 80 between the second gate wiring line 87c and the first and second dummy trench structures 51 and 52.

The second gate wiring line 87c is drawn around in a linear shape extending along the second direction Y from the second dummy region 15B toward the active region 13 side, and intersects (in detail, perpendicularly intersects) the plurality of trench gate structures 30 in the first active region 13A and the third active region 13C. The second gate wiring line 87c is electrically connected to the plurality of gate connection electrode films 49 through the plurality of gate openings 91 formed in the interlayer insulating film 80 in the active region 13.

The second gate wiring line 87c is electrically connected to the plurality of trench gate structures 30 through the plurality of gate connection electrode films 49. In this embodiment, the second gate wiring line 87c is electrically connected to the plurality of trench gate structures 30 that are electrically connected to the first gate wiring line 87b.

The third gate wiring line 87d is arranged on the buried insulator 26 and on the interlayer insulating film 80. The third gate wiring line 87d is pulled out from the resistance wiring line 87a to a region on the second connecting surface 10B side with respect to the gate pad 86, and linearly extends along the second direction Y through a region between the resistance wiring line 87a and the second connecting surface 10B. The third gate wiring line 87d is electrically connected to the trench resistance structure through the resistance wiring line 87a in the resistive region 12, and is electrically connected to the plurality of trench gate structures 30 in the active region 13 (first active region 13A).

In detail, the third gate wiring line 87d includes a line portion 92, a first branch portion 93, and a second branch portion 94. The line portion 92 linearly extends along the second direction Y in a region between the gate pad 86 and the second connecting surface 10B on the interlayer insulating film 80. The line portion 92 has a first end portion on the second connecting surface 10B side and a second end portion on the gate pad 86 side. The first end portion is arranged on the interlayer insulating film 80 at a distance from the second connecting surface 10B toward the gate pad 86 side.

The second end portion is arranged directly on the trench resistance structure 20 at a distance from the gate pad 86 toward the second connecting surface 10B side. In detail, the second end portion is arranged on the buried insulator 26. In more detail, the second end portion is arranged on the buried insulator 26 at a distance from the buried resistance 25 in the plan view.

That is, the line portion 92 faces the insulating region 27 across the buried insulator 26, and does not face the buried resistance 25 across the buried insulator 26. In this embodiment, the line portion 92 (second end portion) has a portion that is located on the bottom wall 22 side of the resistance trench 23 with respect to the height position of the active surface 8 and a portion that protrudes upwardly with respect to the height position of the active surface 8.

The line portion 92 is electrically connected to the plurality of gate connection electrode films 49 through the plurality of gate openings 91 formed in the interlayer insulating film 80 in the active region 13 (first active region 13A). Hence, the line portion 92 is electrically connected to the plurality of trench gate structures 30 through the plurality of gate connection electrode films 49. In this embodiment, the line portion 92 is electrically connected to the plurality of trench gate structures 30 that are connected to the first gate wiring line 87b and to the second gate wiring line 87c.

The first branch portion 93 connects the resistance wiring line 87a and the line portion 92. In detail, the first branch portion 93 is pulled out from the second end portion of the line portion 92 toward one side (third connecting surface 10C side), and extends in a band shape along the gate pad 86. In this embodiment, the first formed directly on the trench branch portion 93 is resistance structure 20.

In detail, the first branch portion 93 is arranged only in a region surrounded by the peripheral edge of the resistance trench 23 at a distance inwardly from the peripheral edge of the resistance trench 23 (first to fourth sidewalls 21A to 21D). That is, the first branch portion 93 is arranged directly on the trench resistance structure at a distance from the active region 13, from the dummy region 15, and from the termination region 16, and does not face the active region 13, the dummy region 15, and the termination region 16 in the normal direction Z.

In this embodiment, the first branch portion 93 is arranged on the buried insulator 26 at a distance from the peripheral edge of the resistance trench 23, and extends in a band shape along the second sidewall 21B and the third sidewall 21C of the resistance trench 23. The first branch portion 93 is arranged on the buried insulator 26 at a distance from the buried resistance 25 in the plan view. The first branch portion 93 faces the insulating region 27 across the buried insulator 26, and does not face the buried resistance 25 across the buried insulator 26.

The first branch portion 93 is connected to the resistance wiring line 87a in a region on the first sidewall 21A side of the resistance trench 23. That is, the first branch portion 93 is connected to the resistance wiring line 87a directly on the insulating region 27. In this embodiment, the first branch portion 93 has a portion that is located on the bottom wall 22 side of the resistance trench 23 with respect to the height position of the active surface 8 and a portion that protrudes upwardly with respect to the height position of the active surface 8.

As a matter of course, the first branch portion 93 may be pulled out onto the interlayer insulating film 80 from above the buried insulator 26, and may have a portion that faces a region located outside the trench resistance structure 20 in the normal direction Z. In this case, the first branch portion 93 may face at least one among the active region 13, the dummy region 15, and the termination region 16 in the normal direction Z. Also, the first branch portion 93 may be connected to the first gate wiring line 87b, and may be electrically connected to the resistance wiring line 87a through the first gate wiring line 87b.

The second branch portion 94 connects the resistance wiring line 87a and the line portion 92. The second branch portion 94 is pulled out from the first end portion of the line portion 92 to the other side (fourth connecting surface 10D side), and extends in a band shape along the gate pad 86. In this embodiment, the second branch portion 94 is formed directly on the trench resistance structure 20.

In detail, the second branch portion 94 is arranged only in a region surrounded by the peripheral edge of the trench resistance structure 20 at a distance inwardly from the peripheral edge of the trench resistance structure (first to fourth sidewalls 21A to 21D). That is, the second branch portion 94 is arranged directly on the trench resistance structure 20 at a distance from the active region 13, from the dummy region 15, and from the termination region 16, and does not face the active region 13, the dummy region 15, and the termination region 16 in the normal direction Z.

In this embodiment, the second branch portion 94 is arranged on the buried insulator 26 at a distance from the peripheral edge of the resistance trench 23, and extends in a band shape along the second sidewall 21B and the fourth sidewall 21D of the resistance trench 23. The second branch portion 94 is arranged on the buried insulator 26 at a distance from the buried resistance 25 in the plan view. That is, the second branch portion 94 faces the insulating region 27 across the buried insulator 26, and does not face the buried resistance 25 across the buried insulator 26.

The second branch portion 94 is connected to the resistance wiring line 87a in a region on the first sidewall 21A side of the resistance trench 23. The second branch portion 94 is connected to the resistance wiring line 87a directly on the insulating region 27. The second branch portion 94 surrounds the gate pad 86 together with the resistance wiring line 87a and the first branch portion 93. In this embodiment, the second branch portion 94 has a portion that is located on the bottom wall 22 side of the resistance trench 23 with respect to the height position of the active surface 8 and a portion that protrudes upwardly with respect to the height position of the active surface 8.

As a matter of course, the second branch portion 94 may be pulled out onto the interlayer insulating film 80 from above the buried insulator 26, and may have a portion that faces a region located outside the trench resistance structure 20 in the normal direction Z. In this case, the second branch portion 94 may face at least one among the active region 13, the dummy region 15, and the termination region 16 in the normal direction Z. Also, the second branch portion 94 may be connected to the second gate wiring line 87c, and may be electrically connected to the resistance wiring line 87a through the second gate wiring line 87c.

A gate potential VG is given to the gate subpad 88 from the outside. The gate subpad 88 is formed more narrowly than the gate pad 86, and is formed more widely than the gate wiring line 87. A part or all of the gate subpad 88 is arranged in a region located outside the trench resistance structure 20 in the plan view.

The gate subpad 88 is arranged on the interlayer insulating film 80 so as to be electrically connected to the gate pad 86 via the trench resistance structure 20. In this embodiment, the gate subpad 88 is arranged at a distance from the gate pad 86 to the third connecting surface 10C side, and face the gate pad 86 in the first direction X.

The gate subpad 88 is arranged on a part, which covers the active region 13, of the interlayer insulating film 80 at a distance from the dummy region 15 (first dummy region 15A) in the plan view. The gate subpad 88 faces the plurality of trench gate structures 30 and the plurality of first trench source structures 35 across the interlayer insulating film 80. The gate subpad 88 faces the dummy region 15 (first dummy region 15A) in the second direction Y in the plan view.

In this embodiment, the gate subpad 88 is electrically connected to the gate wiring line 87. In detail, the gate subpad 88 is pulled out from the third gate wiring line 87d (first branch portion 93) to a region located outside the trench resistance structure 20, and has a portion that faces the trench resistance structure 20 across the buried resistance 25.

The gate subpad 88 is merely required to be connected to at least one among the first to third gate wiring lines 87b to 87d, and the arrangement place of the gate subpad 88 is optional. As a matter of course, the gate subpad 88 may be connected to the resistance wiring line 87a. Also, the gate subpad 88 may be arranged in a region that faces at least one among the first dummy region 15A, the second dummy region 15B, and the first termination region 16A.

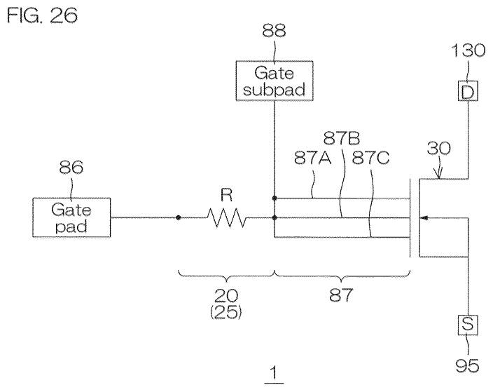

A connection mode of both the gate electrode 85 and the trench resistance structure 20 will be hereinafter described with reference to FIG. 26. FIG. 26 is an electric circuit diagram showing a connection mode of both the gate electrode 85 and the trench resistance structure 20. In FIG. 26, the trench gate structure 30 is shown by a circuit symbol showing a MISFET.

Referring to FIG. 26, the gate wiring line 87 is electrically connected to the gate pad 86 via a gate resistance R. The gate resistance R is formed by a part, which is located between the connection portion of the gate pad 86 and a connection portion of the first gate wiring line 87b, of the trench resistance structure 20 (i.e., is formed by a part of the buried resistance 25). The resistance value of the gate resistance R is adjusted by increasing or decreasing the distance between the connection portion of the gate pad 86 and the connection portion of the first gate wiring line 87b.

The gate resistance R (trench resistance structure 20) delays a switching speed when a switching operation is performed, and restrains a surge current. That is, the gate resistance R restrains a noise caused by the surge current. The gate resistance R is formed in the first main surface 3 (active surface 8), and hence is not externally connected to the semiconductor device 1. Therefore, the number of components mounted on a circuit board is reduced by allowing the gate resistance R to be incorporated into the first main surface 3.

The gate resistance R includes the trench resistance structure 20 incorporated in the thickness direction of the chip 2, and therefore the exclusive area of the gate resistance R with respect to the first main surface 3 becomes limited. Therefore, a reduction in the area of the active region 13, which is caused by introducing the gate resistance R, is restrained. Also, the thickening (enlargement) in the thickness direction of the chip 2 of the semiconductor device 1 is restrained. The gate wiring line 87 is not necessarily required to simultaneously include all of the first to third gate wiring lines 87b to 87d, and is merely required to include at least one among the first to third gate wiring lines 87b to 87d.

Referring again to FIG. 1 to FIG. 25, the semiconductor device 1 includes the source electrode 95 arranged on the interlayer insulating film 80 at a distance from the gate electrode 85. The source electrode 95 is arranged on the interlayer insulating film 80 at a distance from the trench resistance structure 20 in the plan view. The source electrode 95 does not cover the buried insulator 26.

The source electrode 95 has a resistance value lower than the resistance value of the trench resistance structure 20. In detail, the source electrode 95 has a resistance value lower than the resistance value of the buried resistance 25. Preferably, the source electrode 95 is thicker than the buried resistance 25. Particularly preferably, the source electrode 95 is thicker than the buried insulator 26. Preferably, the source electrode 95 is thicker than the interlayer insulating film 80.

Preferably, the source electrode 95 has a thickness larger than the first depth D1. Preferably, the source electrode 95 has a thickness larger than the resistance depth DR (outer peripheral depth DO, second depth D2). The source electrode 95 may have a thickness of not less than 0.5 μm and not more than 10 μm. Preferably, the thickness of the source electrode 95 is not less than 1 μm and not more than 5 μm. Preferably, the thickness of the source electrode 95 is substantially equal to the thickness of the gate electrode 85.

The source electrode 95 may include at least one among a Ti film, a TiN film, a W film, an Al film, a Cu film, an Al alloy film, a Cu alloy film, and a conductive polysilicon film. The source electrode 95 may include at least one among a pure Cu film (whose purity is 99% or more), a pure Al film (whose purity is 99% or more), an AlCu alloy film, an AlSi alloy film, and an AlSiCu alloy film. In this embodiment, the source electrode 95 has a layered structure including a Ti film and an Al alloy film (in this embodiment, AlsiCu alloy film) that are stacked in this order from the chip 2 side. The source electrode 95 may be referred to as a “source metal.”

In this embodiment, the source electrode 95 includes a first source pad 96, a second source pad 97, a first source subpad 98, a second source subpad 99, and a source wiring line 100. A source potential VS for a main source is given to the first source pad 96 from the outside. The first source pad 96 is arranged in a region between the first gate wiring line 87b and the third gate wiring line 87d on a part, which covers the first active region 13A, of the interlayer insulating film 80.

The first source pad 96 faces the plurality of trench gate structures 30 across the interlayer insulating film 80. The first source pad 96 is electrically connected to the plurality of first trench source structures 35, to the source region 29, and to the plurality of first contact regions 48 through the plurality of source openings 101 formed in the interlayer insulating film 80. Preferably, the first source pad 96 has a planar area larger than the planar area of the gate pad 86.

A source potential VS for a main source is given to the second source pad 97 from the outside. The second source pad 97 is arranged in a region between the second gate wiring line 87c and the third gate wiring line 87d on the part, which covers the first active region 13A, of the interlayer insulating film 80. The second source pad 97 faces the plurality of trench gate structures 30 across the interlayer insulating film 80.

The second source pad 97 is electrically connected to the plurality of first trench source structures 35, to the source region 29, and to the plurality of first contact regions 48 through the plurality of source openings 101 formed in the interlayer insulating film 80. Preferably, the second source pad 97 has a planar area larger than the planar area of the gate pad 86. The second source pad 97 may be formed integrally with the first source pad 96 if the third gate wiring line 87d is not formed.

A source potential VS for a source sense is given to the first source subpad 98 from the outside. In this embodiment, the first source subpad 98 is arranged in a region between the gate pad 86 and the first gate wiring line 87b (third connecting surface 10C) on the part, which covers the second active region 13B, of the interlayer insulating film 80. In detail, the first source subpad 98 is arranged in a region between the first gate wiring line 87b and the first branch portion 93 of the third gate wiring line 87d.

The first source subpad 98 has a planar area less than the planar area of the first source pad 96, and is formed integrally with the first source pad 96. Preferably, the planar area of the first source subpad 98 is larger than the planar area of the gate subpad 88. Particularly preferably, the planar area of the first source subpad 98 is larger than the planar area of the gate pad 86.

The first source subpad 98 faces the plurality of trench gate structures 30 across the interlayer insulating film 80. The first source subpad 98 is electrically connected to the plurality of first trench source structures 35, to the source region 29, and to the plurality of first contact regions 48 through the plurality of source openings 101 formed in the interlayer insulating film 80.

A source potential VS for a source sense is given to the second source subpad 99 from the outside. In this embodiment, the second source subpad 99 is arranged in a region between the gate pad 86 and the second gate wiring line 87c (fourth connecting surface 10D) on the part, which covers the third active region 13C, of the interlayer insulating film 80. In detail, the second source subpad 99 is arranged in a region between the second gate wiring line 87c and the second branch portion 94 of the third gate wiring line 87d.

In this embodiment, the second source subpad 99 has a planar area less than the planar area of the second source pad 97, and is formed integrally with the second source pad 97. Preferably, the planar area of the second source subpad 99 is larger than the planar area of the gate subpad 88. Particularly preferably, the planar area of the second source subpad 99 is larger than the planar area of the gate pad 86.

The second source subpad 99 faces the plurality of trench gate structures 30 across the interlayer insulating film 80. The second source subpad 99 is electrically connected to the plurality of first trench source structures 35, to the source region 29, and to the plurality of first contact regions 48 through the plurality of source openings 101 formed in the interlayer insulating film 80.

Preferably, the total planar area of the first source pad 96, the second source pad 97, the first source subpad 98, and the second source subpad 99 is not less than 50% and not more than 90% of the planar area of the first main surface 3. Particularly preferably, the total planar area is 75% or more of the planar area of the first main surface 3.

The source wiring line 100 transmits a source potential VS given to the first and second source pads 96 and 97 to other regions. In this embodiment, the source wiring line 100 is pulled out from the first and second source pads 96 and 97 so as to be located closer to the outer peripheral region 17 than the gate wiring line 87. The source wiring line 100 passes through the first to fourth connecting surfaces 10A to 10D from the active surface 8 side, and is pulled out to the outer peripheral surface 9 side. The source wiring line 100 is formed in a band shape extending along the first to fourth connecting surfaces 10A to 10D. That is, the source wiring line 100 faces the sidewall wiring line 78 across the interlayer insulating film 80. In this embodiment, the source wiring line 100 is formed in an annular shape (in detail, rectangularly annular shape) extending along the first to fourth connecting surfaces 10A to 10D, and surrounds the gate wiring line 87.

The source wiring line 100 is electrically connected to the sidewall wiring line 78 and to the outer contact region 76 through an outer opening 102 formed in the interlayer insulating film 80. The outer opening 102 is formed in a band shape or an annular shape extending along the sidewall wiring line 78 and along the outer contact region 76. A source potential VS given to the source wiring line 100 is transmitted to the first trench source structure 35, to the second trench source structure 40, to the first dummy trench structure 51, to the second dummy trench structure 52, and to the trench termination structure 70 via the sidewall wiring line 78.

The semiconductor device 1 includes an upper insulating film 110 that selectively covers the gate electrode 85, the source electrode 95, and the interlayer insulating film 80 on the first main surface 3. The upper insulating film 110 includes a gate pad opening 111 that exposes an inward portion of the gate pad 86 and a gate subpad opening 112 that exposes an inward portion of the gate subpad 88.

The upper insulating film 110 covers a peripheral edge portion of the gate pad 86, a peripheral edge portion of the gate subpad 88, and the whole area of the gate wiring line 87. That is, the upper insulating film 110 covers the buried insulator 26, the peripheral edge portion of the gate pad 86, the resistance wiring line 87a, the first branch portion 93, and the second branch portion 94 in the resistance trench 23.

The gate pad opening 111 is formed in a quadrangular shape in the plan view. The gate subpad opening 112 is formed in a quadrangular shape in the plan view. The gate subpad opening 112 has a planar area smaller than the planar area of the gate pad opening 111.

The upper insulating film 110 includes a first source pad opening 113 that exposes an inward portion of the first source pad 96, a second source pad opening 114 that exposes an inward portion of the second source pad 97, a first source subpad opening 115 that exposes an inward portion of the first source subpad 98, and a second source subpad opening 116 that exposes an inward portion of the second source subpad 99. The upper insulating film 110 covers a peripheral edge portion of the first source pad 96, a peripheral edge portion of the second source pad 97, a peripheral edge portion of the first source subpad 98, a peripheral edge portion of the second source subpad 99, and the whole area of the source wiring line 100.

The first source pad opening 113 is formed in a quadrangular shape in the plan view. The first source pad opening 113 has a planar area larger than the planar area of the gate subpad opening 112. Preferably, the planar area of the first source pad opening 113 is larger than the planar area of the gate pad opening 111.

The second source pad opening 114 is formed in a quadrangular shape in the plan view. The second source pad opening 114 has a planar area larger than the planar area of the gate subpad opening 112. Preferably, the planar area of the second source pad opening 114 is larger than the planar area of the gate pad opening 111. Preferably, the planar area of the second source pad opening 114 is substantially equal to the planar area of the first source pad opening 113.

The first source subpad opening 115 is formed in a quadrangular shape in the plan view. The first source subpad opening 115 has a planar area smaller than the planar area of the first source pad opening 113. Preferably, the planar area of the first source subpad opening 115 is larger than the planar area of the gate subpad opening 112. In this embodiment, the planar area of the first source subpad opening 115 is larger than the planar area of the gate pad opening 111. As a matter of course, the planar area of the first source subpad opening 115 may be less than the planar area of the gate pad opening 111.

The second source subpad opening 116 is formed in a quadrangular shape in the plan view. The second source subpad opening 116 has a planar area smaller than the planar area of the second source pad opening 114. Preferably, the planar area of the second source subpad opening 116 is larger than the planar area of the gate subpad opening 112. In this embodiment, the planar area of the second source subpad opening 116 is larger than the planar area of the gate pad opening 111. As a matter of course, the planar area of the second source subpad opening 116 may be less than the planar area of the gate pad opening 111. Preferably, the planar area of the second source subpad opening 116 is substantially equal to the planar area of the first source subpad opening 115.

It is recommended to form the first source pad opening 113 that exposes both the first source pad 96 and the first source subpad 98 if a source sense using the first source subpad 98 is not needed. It is recommended to form the second source pad opening 114 that exposes both the second source pad 97 and the second source subpad 99 if a source sense using the second source subpad 99 is not needed.

The upper insulating film 110 is formed at a distance inwardly from the peripheral edge (first to fourth side surfaces 5A to 5D) of the chip 2, and defines a dicing street 117 with the peripheral edge of the chip 2. The dicing street 117 is formed in a band shape extending along the peripheral edge of the chip 2 in the plan view. In this embodiment, the dicing street 117 is formed in an annular shape (in detail, rectangularly annular shape) surrounding the active surface 8 in the plan view. In this embodiment, the dicing street 117 exposes the interlayer insulating film 80.

As a matter of course, the dicing street 117 may expose the outer peripheral surface 9 if the main surface insulating film 18 and the interlayer insulating film 80 expose the outer peripheral surface 9. The dicing street 117 may have a width of not less than 1 μm and not more than 200 μm. The width of the dicing street 117 is a width in a direction perpendicular to the extending direction of the dicing street 117. Preferably, the width of the dicing street 117 is not less than 5 μm and not more than 50 μm.

Preferably, the upper insulating film 110 has a thickness exceeding the thickness of the gate electrode 85 and exceeding the thickness of the source electrode 95. Preferably, the thickness of the upper insulating film 110 is less than the thickness of the chip 2. The thickness of the upper insulating film 110 may be not less than 3 μm and not more than 35 μm. Preferably, the thickness of the upper insulating film 110 is 25 μm or less.

In this embodiment, the upper insulating film 110 has a layered structure including an inorganic insulating film 120 and an organic insulating film 121 that are stacked in this order from the chip 2 side. The upper insulating film 110 is merely required to include at least either one of the inorganic insulating film 120 and the organic insulating film 121, and is not necessarily required to simultaneously include the inorganic insulating film 120 and the organic insulating film 121.

The inorganic insulating film 120 selectively covers the gate electrode 85, the source electrode 95, and the interlayer insulating film 80, and defines a part of the gate pad opening 111, a part of the gate subpad opening 112, a part of the first source pad opening 113, a part of the second source pad opening 114, a part of the first source subpad opening 115, a part of the second source subpad opening 116, and a part of the dicing street 117.

The inorganic insulating film 120 may include at least one among a silicon oxide film, a silicon nitride film, and a silicon oxynitride film. Preferably, the inorganic insulating film 120 an includes insulation material differing from that of the interlayer insulating film 80. Preferably, the inorganic insulating film 120 includes a silicon nitride film. Preferably, the inorganic insulating film 120 has a thickness less than the thickness of the interlayer insulating film 80. The thickness of the inorganic insulating film 120 may be not less than 0.1 μm and not more than 5 μm.

The organic insulating film 121 selectively covers the inorganic insulating film 120, and defines a part of the gate pad opening 111, a part of the gate subpad opening 112, a part of the first source pad opening 113, a part of the second source pad opening 114, a part of the first source subpad opening 115, a part of the second source subpad opening 116, and a part of the dicing street 117.

The organic insulating film 121 may expose the inorganic insulating film 120 in a wall surface of the gate pad opening 111. The organic insulating film 121 may expose the inorganic insulating film 120 in a wall surface of the gate subpad opening 112. The organic insulating film 121 may expose the inorganic insulating film 120 in a wall surface of the first source pad opening 113. The organic insulating film 121 may expose the inorganic insulating film 120 in a wall surface of the second source pad opening 114.

The organic insulating film 121 may expose the inorganic insulating film 120 in a wall surface of the first source subpad opening 115. The organic insulating film 121 may expose the inorganic insulating film 120 in a wall surface of the second source subpad opening 116. The organic insulating film 121 may expose the inorganic insulating film 120 in a wall surface of the dicing street 117. As a matter of course, the organic insulating film 121 may cover the whole area of the inorganic insulating film 120 so as not to expose the inorganic insulating film 120.

Preferably, the organic insulating film 121 is made of a resin film other than thermosetting resin. The organic insulating film 121 may be made of a translucent resin or a transparent resin. The organic insulating film 121 may be made of a negative type photopolymer film or a positive type photopolymer film. Preferably, the organic insulating film 121 is made of a polyimide film, a polyamide film, or a polybenzoxazole film. In this embodiment, the organic insulating film 121 includes a polybenzoxazole film.

Preferably, the organic insulating film 121 has a thickness exceeding the thickness of the inorganic insulating film 120. Preferably, the thickness of the organic insulating film 121 exceeds the thickness of the interlayer insulating film 80. Particularly preferably, the thickness of the organic insulating film 121 exceeds the thickness of the gate electrode 85 and the thickness of the source electrode 95. The thickness of the organic insulating film 121 may be not less than 3 μm and not more than 30 μm. Preferably, the thickness of the organic insulating film 121 is 20 μm or less.

The semiconductor device 1 includes a drain electrode 130 covering the second main surface 4. The drain electrode 130 forms an ohmic contact with the second semiconductor region 7 exposed from the second main surface 4. The drain electrode 130 may cover the whole area of the second main surface 4 so as to be continuous with the peripheral edge (first to fourth side surfaces 5A to 5D) of the chip 2. A breakdown voltage that is applicable between the source electrode 95 and the drain electrode 130 (between the first main surfaces 3 and second main surfaces 4) may be not less than 500 V and not more than 3000 V.

As described above, the semiconductor device 1 includes the chip 2, the trench resistance structure 20, the gate pad 86, and the gate wiring line 87. The chip 2 has the first main surface 3. The trench resistance structure 20 is formed in the first main surface 3. The gate pad 86 has a resistance value lower than that of the trench resistance structure 20, and is arranged on the trench resistance structure 20 so as to be electrically connected to the trench resistance structure 20. The gate wiring line 87 has a resistance value lower than that of the trench resistance structure 20, and is arranged on the trench resistance structure 20 so as to be electrically connected to the gate pad 86 via the trench resistance structure 20.

This structure makes it possible to prevent a device from being enlarged (from being thickened) in the normal direction Z of the first main surface 3 since the trench resistance structure 20 serving as the gate resistance R is incorporated into the chip 2. Also, the gate pad 86 and the gate wiring line 87 are arranged on the trench resistance structure 20, and therefore it is possible to reduce the exclusive area of the trench resistance structure 20, the gate pad 86, and the gate wiring line 87 with respect to the first main surface 3 in the plan view. Therefore, it is possible to provide the semiconductor device 1 having a novel layout that contributes to a size reduction in a configuration including the gate resistance R.

Preferably, the gate pad 86 has a planar area less than the planar area of the trench resistance structure 20. This structure makes it possible to arrange the gate pad 86 in a region surrounded by of the wall surface of the trench resistance structure 20 at a distance from the wall surface of the trench resistance structure 20 in the plan view. Also, it is possible to restrain the enlargement of the gate pad 86, and it is possible to limit the arrangement place of the gate pad 86 directly on the trench resistance structure 20, and therefore it is possible to relax the limitation of a design rule caused by the layout of the gate pad 86 (for example, the limitation of the layout of a structural component formed on the chip 2 side).

Preferably, the gate wiring line 87 extends in a band shape narrower than the trench resistance structure 20 in the plan view. Preferably, the gate wiring line 87 has two sides that cross the inward portion of the trench resistance structure 20 in the plan view. These structures make it possible to prevent the gate wiring line 87 from being enlarged, thus making it possible to relax the limitation of a design rule caused by the layout of the gate wiring line 87 (for example, the limitation of the layout of a structural component formed on the chip 2 side).

Preferably, the trench resistance structure 20 includes the resistance trench 23 formed in the first main surface 3, the resistance insulating film 24 covering the wall surface of the resistance trench 23, and the buried resistance 25 arranged in the resistance trench 23 with the resistance insulating film 24 between the buried resistance and the resistance trench 23. In this case, preferably, the gate pad 86 has a resistance value lower than that of the buried resistance 25, and is electrically connected to the buried resistance 25. Also, preferably, the gate wiring line 87 has a resistance value lower than that of the buried resistance 25, and is electrically connected to the buried resistance 25.

Preferably, the buried resistance 25 is arranged in the inward portion of the resistance trench 23 at a distance from the peripheral edge of the resistance trench 23. This structure makes it possible to define the insulating region 27 in which the resistance insulating film 24 is exposed between the buried resistance 25 and the peripheral edge of the resistance trench 23. This structure enables the buried resistance 25 (trench resistance structure 20) to become appropriately electrically independent of the chip 2 and other structural components.

This makes it possible to reduce the electrical impact of the gate resistance R on other structural components, and makes it possible to reduce the electrical impact of other structural components on the gate resistance R. For example, it is possible to restrain the malfunction of a channel caused by the buried resistance 25. Therefore, it is possible to appropriately incorporate the gate resistance R into the chip 2.

Particularly preferably, the buried resistance is arranged in the inward portion of the resistance trench 23 at a distance from the entire periphery of the resistance trench 23. This structure makes it possible to define the insulating region 27 that surrounds the buried resistance 25 in an annular shape in the plan view. Preferably, the planar area of the insulating region 27 is equal to or more than the planar area of the buried resistance 25.

The buried resistance 25 may be unevenly distributed on the peripheral edge side of the resistance trench 23 with respect to a central portion of the resistance trench 23. This structure makes it possible to appropriately adjust the connection position of the gate pad 86 with respect to the buried resistance 25 and the connection position of the gate wiring line 87 with respect to the buried resistance 25. That is, it is possible to relax the limitations of a design rule imposed on the buried resistance 25, the gate pad 86, and the gate wiring line 87.

Preferably, the gate pad 86 has a planar area larger than the planar area of the buried resistance 25. This structure makes it possible to appropriately give a gate potential VG to the gate pad 86 from the outside. Preferably, the gate wiring line 87 is formed in a band shape narrower than the buried resistance 25 in the plan view. Preferably, the gate wiring line 87 has two sides that cross the inward portion of the buried resistance 25 in the plan view. These structures make it possible to appropriately prevent the gate wiring line 87 from being enlarged.

Preferably, the buried resistance 25 has a thickness smaller than the depth of the resistance trench 23, and is arranged in the resistance trench 23 at a distance from the height position of the first main surface 3 toward the bottom wall 22 side of the resistance trench 23. This structure makes it possible to house the buried resistance in the resistance trench 23, thus making it possible to restrain the enlargement caused by the thickness of the buried resistance 25.

Preferably, in the thus formed structure, the gate pad 86 is connected to the buried resistance 25 in a region on the bottom wall 22 side of the resistance trench 23 with respect to the height position of the first main surface 3. In this case, preferably, the gate pad 86 has a portion that protrudes toward a position higher than the first main surface 3. This structure makes it possible to appropriately give a gate potential VG to the gate pad 86 from the outside.

Also, preferably, the gate wiring line 87 is connected to the buried resistance 25 in a region on the bottom wall 22 side of the resistance trench 23 with respect to the height position of the first main surface 3. In this case, the gate wiring line 87 may have a portion that protrudes toward a position higher than the first main surface 3.

Preferably, the trench resistance structure 20 includes the buried insulator 26 covering the buried resistance 25 in the resistance trench 23. This structure makes it possible to appropriately insulate the buried resistance 25 from other structural components with the buried insulator 26 and to protect the buried resistance 25. In this case, preferably, the gate pad 86 is arranged on the buried insulator 26 so as to be electrically connected to the buried resistance 25 through the buried insulator 26. Also, preferably, the gate wiring line 87 is arranged to be electrically connected to the buried resistance 25 through the buried insulator 26 on the buried insulator 26.

Preferably, the semiconductor device 1 includes the interlayer insulating film 80 covering the first main surface 3 so as to be connected to the buried insulator 26. In this case, preferably, the interlayer insulating film 80 is connected to the buried insulator 26. This structure makes it possible to protect the resistance trench 23 and the buried resistance 25 with the buried insulator 26 and the interlayer insulating film 80.

Preferably, the semiconductor device 1 includes the dummy trench structure 50 formed in the first main surface 3 at a distance from the trench resistance structure so as to adjoin the trench resistance structure 20. This structure makes it possible to relax an electric field near the trench resistance structure 20 by use of the dummy trench structure 50. Preferably, a potential differing from that of the trench resistance structure 20 is given to the dummy trench structure 50. That is, preferably, the dummy trench structure 50 does not contribute to the control of a channel. In this case, preferably, a source potential VS is given to the dummy trench structure 50.

In this case, the gate wiring line 87 may coincide with the dummy trench structure 50 in the plan view. This structure makes it possible to limit the arrangement place of the gate wiring line 87 directly on the dummy trench structure 50, thus making it possible to relax the limitation of a design rule caused by the layout of the gate wiring line 87 (for example, the limitation of the layout of a structural component formed on the chip 2 side). Preferably, the plurality of dummy trench structures 50 are formed in the first main surface 3. This structure makes it possible to relax an electric field near the trench resistance structure 20 by use of the plurality of dummy trench structures 50.

Preferably, the semiconductor device 1 includes the trench gate structure 30 formed in the first main surface 3 at a distance from the trench resistance structure so as to adjoin the trench resistance structure 20. In this case, preferably, the gate wiring line 87 is electrically connected to the trench gate structure 30. This structure makes it possible to electrically interpose the trench resistance structure 20 (gate resistance R) between the gate pad 86 and the trench gate structure 30.

Preferably, the semiconductor device 1 includes the first trench source structure 35 formed in the first main surface 3 so as to adjoin the trench resistance structure 20 and the trench gate structure 30. The trench resistance structure 20 may be formed more shallowly than the trench resistance structure 20. The first trench source structure 35 may be formed more deeply than the trench gate structure 30. The first trench source structure 35 may be formed at a depth that is substantially equal to that of the trench resistance structure 20.

The thus formed structure is effective to restrain electric field concentration with respect to the trench resistance structure 20 and to improve the withstand voltage (breakdown voltage). In the thus formed structure, preferably, the plurality of dummy trench structures 50 include the first dummy trench structure 51 formed comparatively shallowly correspondingly to the trench gate structure 30 and the second dummy trench structure 52 formed comparatively deeply correspondingly to the trench resistance structure 20.

Preferably, the semiconductor device 1 includes the n-type first semiconductor region 6 formed in the surface layer portion of the first main surface 3. In this case, the trench resistance structure 20 is formed in the first main surface 3 so as to be located in the first semiconductor region 6. In the thus formed structure, preferably, the semiconductor device 1 includes the p-type first well region 28 formed in a region along the trench resistance structure 20 in the first semiconductor region 6 so as to form a p-n junction portion with the first semiconductor region 6. This structure makes it possible to improve the withstand voltage (for example, breakdown voltage) with a depletion layer spreading while setting the first well region 28 as a starting point.

The semiconductor device 1 may include the active mesa 11 defined in the first main surface 3 by the active surface 8 formed in the inward portion of the first main surface 3, the outer peripheral surface 9 formed in the peripheral edge portion of the first main surface 3 so as to be hollowed in the thickness direction of the chip 2 from the active surface 8, and the first to fourth connecting surfaces 10A to 10D connecting the active surface 8 and the outer peripheral surface 9. In this case, preferably, the trench resistance structure 20 is formed in the active surface 8.

The semiconductor device 1 may include a sidewall structure arranged on the outer peripheral surface 9 so as to cover at least one among the first to fourth connecting surfaces 10A to 10D. The first trench source structure 35 may be exposed from at least one among the first to fourth connecting surfaces 10A to 10D. In this case, the sidewall structure may be formed of the sidewall wiring line 78 electrically connected to the first trench source structure 35.

This structure makes it possible to give a potential differing from the potential of the trench resistance structure 20 to the first trench source structure from the outer peripheral surface 9 side with the sidewall wiring line 78. As a matter of course, the dummy trench structure 50 may be exposed from at least one among the first to fourth connecting surfaces 10A to 10D, and the sidewall wiring line 78 may be electrically connected to the dummy trench structure 50.

The semiconductor device 1 may include the gate subpad 88 that has a resistance value lower than that of the trench resistance structure 20 and that is arranged on the first main surface 3 so as to be electrically connected to the gate pad 86 via the trench resistance structure 20. This structure makes it possible to indirectly measure a resistance value between the gate pad 86 and the gate wiring line 87 by measuring a resistance value between the gate pad 86 and the gate subpad 88.

Preferably, the gate subpad 88 is arranged in a region located outside the trench resistance structure 20 in the plan view. Preferably, the gate subpad 88 is formed more narrowly than the gate pad 86, and is formed more widely than the gate wiring line 87. The gate subpad 88 may be connected to the gate wiring line 87.

The semiconductor device 1 may include the p-type outer well region 75 formed in the surface layer portion of the first main surface 3 in the outer peripheral region 17. This structure makes it possible to relax the electric field of the outer peripheral region 17 with the outer well region 75. The semiconductor device 1 may include at least one p-type field region 77 formed in the surface layer portion of the first main surface 3 in the outer peripheral region 17. This structure makes it possible to relax the electric field of the outer peripheral region 17 with the field region 77.

Preferably, the chip 2 includes a single crystal of a wide bandgap semiconductor. The single crystal of the wide bandgap semiconductor is effective to improve electrical properties. Also, the single crystal of the wide bandgap semiconductor makes it possible to achieve the thinning of the chip 2 and an increase in planar area of the chip 2 while restraining the deformation of the chip 2 with comparatively high hardness.

The thinning of the chip 2 and the expansion of the planar area of the chip 2 are effective to improve electrical properties. For example, the chip 2 may have the first main surface 3 having an area equal to or more than 1 mm angle in the plan view. For example, the chip 2 may have a thickness of 200 μm or less. Preferably, the chip 2 has a thickness of 100 μm or less in a cross-sectional view.

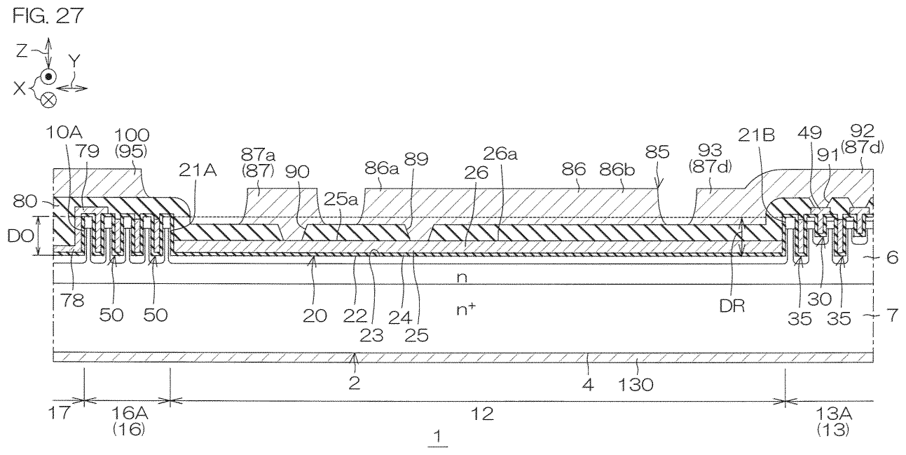

Various modifications applicable to the embodiment will be hereinafter described with reference to FIG. 27 to FIG. 32. FIG. 27 is a cross-sectional view showing a trench resistance structure 20 according to a first modification. The trench resistance structure 20 according to the aforementioned embodiment had the insulating region 27. On the other hand, the trench resistance structure 20 according to the first modification does not have the insulating region 27. That is, the buried resistance 25 covers the whole area of the bottom wall 22 of the resistance trench 23 so as to be connected to the resistance insulating film 24 in the peripheral edge of the resistance trench 23.

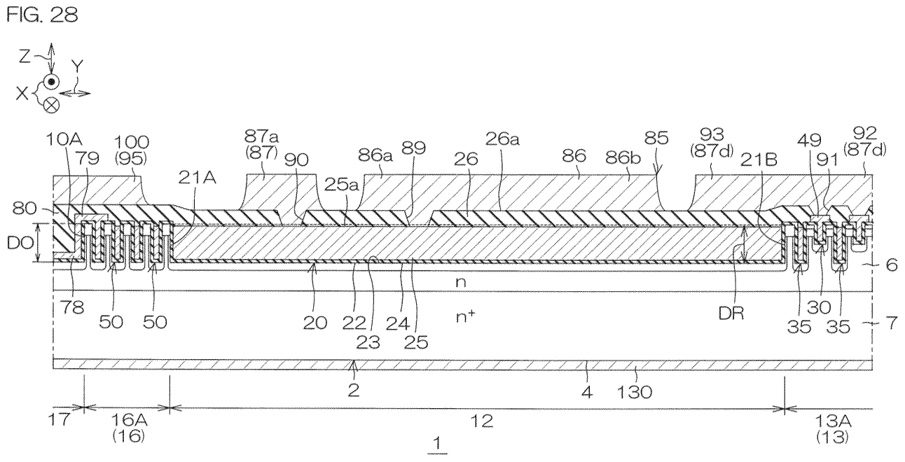

FIG. 28 is a cross-sectional view showing a trench resistance structure 20 according to a second modification. The trench resistance structure 20 according to the second modification has a form in which the buried resistance 25 has been thickened in the trench resistance structure 20 according to the first modification. In this form, the buried resistance 25 has the resistance end surface 25a located closer to the active surface 8 than the intermediate portion in the depth direction of the resistance trench 23. In this case, the end surface of the gate buried electrode 33 may be formed in a height position substantially equal to that of the resistance end surface 25a of the buried resistance 25. Also, the end surface of the first source buried electrode 38 may be formed in a height position substantially equal to that of the resistance end surface 25a of the buried resistance 25.

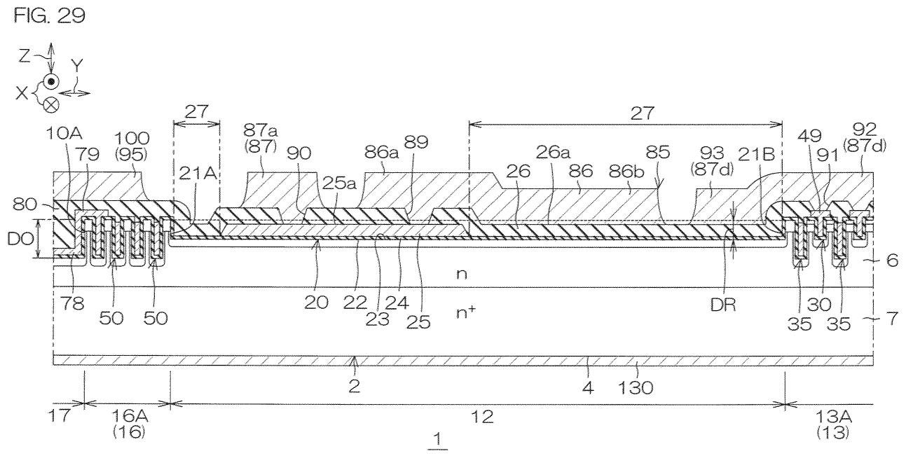

FIG. 29 is a cross-sectional view showing a trench resistance structure 20 according to a third modification. The trench resistance structure 20 according to the aforementioned embodiment had a depth substantially equal to the outer peripheral depth DO of the outer peripheral surface 9. On the other hand, the trench resistance structure 20 according to the third modification has a resistance depth DR less than the outer peripheral depth DO. In this case, the resistance depth DR may be not less than 0.1 μm and not more than 3 μm. Preferably, the resistance depth DR is not less than 0.5 μm and not more than 1.5 μm.

In this case, the trench gate structure 30 may have a first depth D1 substantially equal to the resistance depth DR. Also, the first trench source structure 35 may have a second depth D2 larger than the resistance depth DR. In this embodiment, the bottom portion of the second well region 45 is formed at a depth substantially equal to that of the bottom portion of the first well region 28. In this embodiment, the bottom portion of the third well region 46 is formed on the bottom portion side of the first semiconductor region 6 with respect to the bottom portion of the first well region 28.

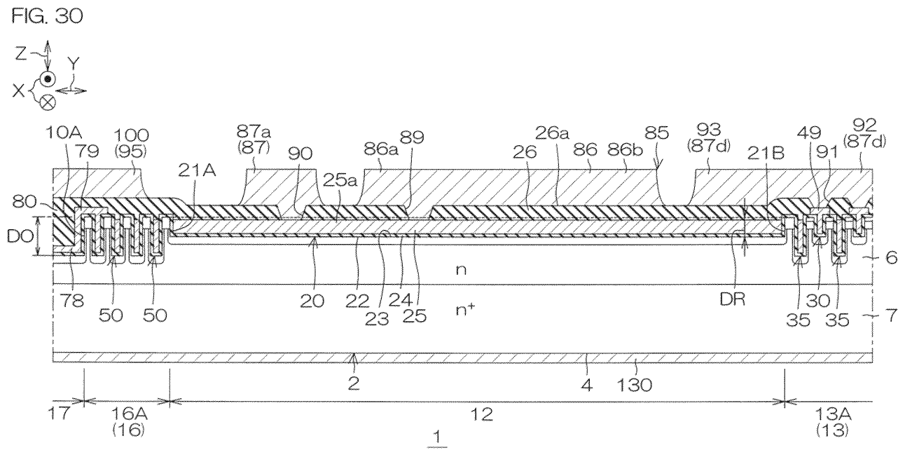

FIG. 30 is a cross-sectional view showing a trench resistance structure according to a fourth modification. The trench resistance structure 20 according to the fourth modification has a form in which the insulating region 27 has been excluded in the third modification. That is, the buried resistance 25 covers the whole area of the bottom wall 22 of the resistance trench 23 so as to be connected to the resistance insulating film 24 in the peripheral edge of the resistance trench 23.

In this case, the buried resistance 25 may have the resistance end surface 25a located closer to the active surface 8 than the intermediate portion in the depth direction of the resistance trench 23. The end surface of the gate buried electrode 33 may be formed in a height position substantially equal to that of the resistance end surface 25a of the buried resistance 25. Also, the end surface of the first source buried electrode 38 may be formed in a height position substantially equal to that of the resistance end surface 25a of the buried resistance 25.

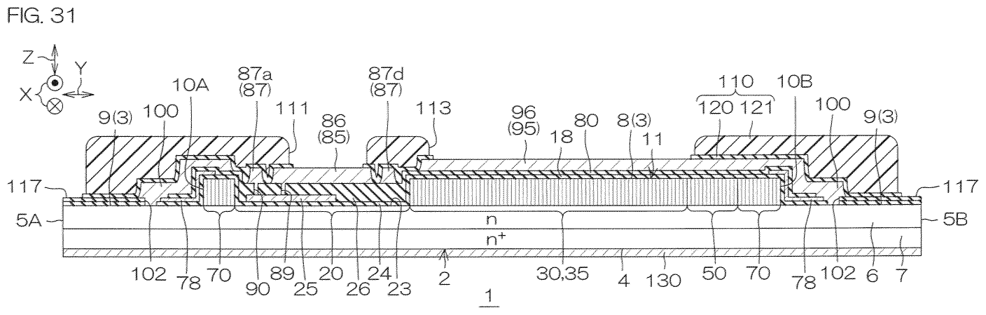

FIG. 31 is a cross-sectional view showing a chip 2 according to the first modification. Referring to FIG. 31, the semiconductor device 1 may include the second semiconductor region 7 having a thickness smaller than the thickness of the first semiconductor region 6 inside the chip 2. That is, the chip 2 may include an epitaxial layer thicker than the semiconductor substrate.

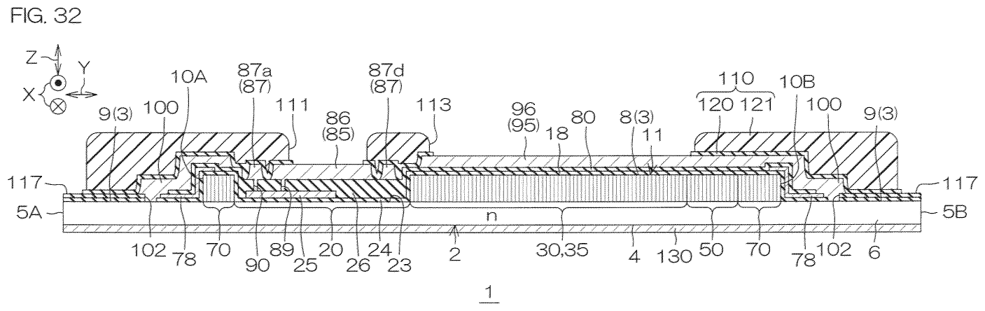

FIG. 32 is a cross-sectional view showing a chip 2 according to the second modification. Referring to FIG. 32, the semiconductor device 1 may not have the second semiconductor region 7, and may include only the first semiconductor region 6 inside the chip 2. In this case, the first semiconductor region 6 is exposed from the first main surface 3, the second main surface 4, and the first to fourth side surfaces 5A to 5D of the chip 2. That is, in this embodiment, the chip 2 does not have a semiconductor substrate, and has a single-layer structure made of an epitaxial layer.

The aforementioned embodiments can be carried out in other forms. The “first conductivity type” is an “n-type,” and the “second conductivity type” is a “p-type” as shown in each of the aforementioned embodiments. However, in each of the aforementioned embodiments, a form may be employed in which the “first conductivity type” is a “p-type,” and the “second conductivity type” is an “n-type.” A concrete configuration in this case can be obtained by replacing the “n-type” with the “p-type” and, simultaneously, replacing the “p-type” with the “n-type” in the description given above and in the accompanying drawings.

In the aforementioned embodiment, the n-type second semiconductor region 7 was shown. However, a p-type second semiconductor region 7 may be employed. In this case, an IGBT (Insulated Gate Bipolar Transistor) is formed instead of a MISFET. In this case, the “source” of the MISFET is replaced by the “emitter” of the IGBT, and the “drain” of the MISFET is replaced by the “collector” of the IGBT in the foregoing description. The p-type second semiconductor region 7 may be an impurity region including a p-type impurity implanted into the surface layer portion of the second main surface 4 of the chip 2 according to an ion implantation method.

Characteristic examples extracted from this description and from the drawings are hereinafter shown. Hereinafter, alphanumeric characters etc., in parentheses represent corresponding components in the aforementioned embodiments, and yet this representation does not denote that the scope of each clause is limited to the embodiments. The “semiconductor device” according to the following clauses may be replaced with a “wide bandgap semiconductor device,” an “SiC semiconductor device,” a “semiconductor switching device,” or an “SiC-MISFET,” etc., if necessary.

[A1] A semiconductor device (1) comprising: a chip (2) having a main surface (3); a trench resistance structure (20) formed in the main surface (3); a gate pad (86) that has a resistance value lower than that of the trench resistance structure (20) and that is arranged on the trench resistance structure (20) SO as to be electrically connected to the trench resistance structure (20); and a gate wiring line (87, 87a to 87d) that has a resistance value lower than that of the trench resistance structure (20) and that is arranged on the trench resistance structure (20) so as to be electrically connected to the gate pad (86) via the trench resistance structure (20).

[A2] The semiconductor device (1) according to A1, wherein the gate pad (86) has a planar area less than a planar area of the trench resistance structure (20).

[A3] The semiconductor device (1) according to A1 or A2, wherein the gate pad (86) is arranged in a region surrounded by a wall surface of the trench resistance structure (20) at a distance from the wall surface of the trench resistance structure (20) as viewed in plan.

[A4] The semiconductor device (1) according to any one of A1 to A3, wherein the gate wiring line (87, 87a to 87d) is formed in a band shape narrower than the trench resistance structure (20) as viewed in plan.

[A5] The semiconductor device (1) according to A4, wherein the gate wiring line (87, 87a to 87d) has two sides that cross an inward portion of the trench resistance structure (20) as viewed in plan.

[A6] The semiconductor device (1) according to any one of A1 to A5, wherein the trench resistance structure (20) includes a trench (23) formed in the main surface (3), an insulating film (24) covering a wall surface of the trench (23), and a buried resistance (25) arranged in the trench (23) with the insulating film (24) between the buried resistance (25) and the trench (23); the gate pad (86) has a resistance value lower than that of the buried resistance (25), and is electrically connected to the buried resistance (25); and the gate wiring line (87, 87a to 87d) has a resistance value lower than that of the buried resistance (25), and is electrically connected to the buried resistance (25).

[A7] The semiconductor device (1) according to A6, wherein the buried resistance (25) is arranged in an inward portion of the trench (23) at a distance from a peripheral edge (21A to 21D) of the trench (23), and defines an insulating region (27) that exposes the insulating film (24) with the peripheral edge (21A to 21D) of the trench (23).

[A8] The semiconductor device (1) according to A7, wherein the gate pad (86) has a planar area larger than a planar area of the buried resistance (25).

[A9] The semiconductor device (1) according to A7 or A8, wherein the gate wiring line (87, 87a to 87d) is formed in a band shape narrower than the buried resistance (25) as viewed in plan.

[A10] The semiconductor device (1) according to any one of A7 to A9, wherein the gate wiring line (87, 87a to 87d) has two sides that cross the buried resistance (25) in the trench (23) as viewed in plan.

[A11] The semiconductor device (1) according to any one of A6 to A10, wherein the buried resistance (25) has a thickness smaller than a depth of the trench (23), and is arranged in the trench (23) at a distance from a height position of the main surface (3) toward a bottom wall (22) side of the trench (23), the gate pad (86) is connected to the buried resistance (25) in a region on the bottom wall (22) side of the trench (23) with respect to the height position of the main surface (3), and the gate wiring line (87, 87a to 87d) is connected to the buried resistance (25) in the region on the bottom wall (22) side of the trench (23) with respect to the height position of the main surface (3).

[A12] The semiconductor device (1) according to A11, wherein the gate pad (86) has a portion that protrudes to a higher position than the main surface (3).

[A13] The semiconductor device (1) according to A11 or A12, wherein the trench resistance structure (20) includes a buried insulator (26) covering the buried resistance (25) in the trench (23), the gate pad (86) is arranged on the buried insulator (26) so as to be electrically connected to the buried resistance (25) through the buried insulator (26), and the gate wiring line (87, 87a to 87d) is arranged on the buried insulator (26) so as to be electrically connected to the buried resistance (25) through the buried insulator (26).

[A14] The semiconductor device (1) according to A13, further comprising: an interlayer insulating film (80) that covers the main surface (3) so as to be connected to the buried insulator (26).

[A15] The semiconductor device (1) according to any one of A1 to A14, further comprising: a dummy trench structure (50 to 52) that is formed in the main surface (3) at a distance from the trench resistance structure (20) so as to adjoin the trench resistance structure (20) and to which a potential differing from a potential of the trench resistance structure (20) is given.

[A16] The semiconductor device (1) according to any one of A1 to A15, further comprising: a trench gate structure (30) that is formed in the main surface (3) at a distance from the trench resistance structure (20) so as to adjoin the trench resistance structure (20); wherein the gate wiring line (87, 87a to 87d) is electrically connected to the trench gate structure (30).

[A17] The semiconductor device (1) according to A16, further comprising: a trench source structure (35) formed in the main surface (3) so as to adjoin the trench resistance structure (20) and the trench gate structure (30).

[A18] The semiconductor device (1) according to any one of A1 to A17, further comprising: a first conductivity type (n-type) semiconductor region (6) formed in a surface layer portion of the main surface (3); the trench resistance structure (20) formed in the main surface (3) so as to be located in the semiconductor region (6); and a second conductivity type (p-type) well region (28) formed in a region along the trench resistance structure (20) in the semiconductor region (6) so as to form a p-n junction portion with the semiconductor region (6).

[A19] The semiconductor device (1) according to any one of A1 to A18, further comprising: a mesa (11) defined in the main surface (3) by a first surface portion (8) formed in an inward portion of the main surface (3), a second surface portion (9) formed in a peripheral edge portion of the main surface (3) so as to be hollowed in a thickness direction of the chip (2) from the first surface portion (8), and a connecting surface portion (10A to 10D) connecting the first surface portion (8) and the second surface portion (9); wherein the trench resistance structure (20) is formed in the first surface portion (8).

[A20] The semiconductor device (1) according to any one of A1 to A19, further comprising: a gate subpad (88) that has a resistance value lower than that of the trench resistance structure (20) and that is arranged on the main surface (3) so as to be electrically connected to the gate pad (86) via the trench resistance structure (20).

Although the embodiments have been described in detail as above, these are merely concrete examples that specify technical contents. Various technical ideas extracted from this description can be appropriately combined together without being limited to the sequential descriptive order in this description, the sequential order of the embodiments, or the like.

What is claimed is:

1. A semiconductor device comprising:
a chip having a main surface;
a trench resistance structure formed in the main surface;
a gate pad that has a resistance value lower than that of the trench resistance structure and that is arranged on the trench resistance structure so as to be electrically connected to the trench resistance structure; and
a gate wiring line that has a resistance value lower than that of the trench resistance structure and that is arranged on the trench resistance structure so as to be electrically connected to the gate pad via the trench resistance structure.

2. The semiconductor device according to claim 1,
wherein the gate pad has a planar area less than a planar area of the trench resistance structure.

3. The semiconductor device according to claim 1,
wherein the gate pad is arranged in a region surrounded by a wall surface of the trench resistance structure at a distance from the wall surface of the trench resistance structure as viewed in plan.

4. The semiconductor device according to claim 1,
wherein the gate wiring line is formed in a band shape narrower than the trench resistance structure as viewed in plan.

5. The semiconductor device according to claim 4,
wherein the gate wiring line has two sides that cross an inward portion of the trench resistance structure as viewed in plan.

6. The semiconductor device according to claim 1,
wherein the trench resistance structure includes a trench formed in the main surface, an insulating film covering a wall surface of the trench, and a buried resistance arranged in the trench with the insulating film between the buried resistance and the trench,
the gate pad has a resistance value lower than that of the buried resistance, and is electrically connected to the buried resistance, and
the gate wiring line has a resistance value lower than that of the buried resistance, and is electrically connected to the buried resistance.

7. The semiconductor device according to claim 6,
wherein the buried resistance is arranged in an inward portion of the trench at a distance from a peripheral edge of the trench, and defines an insulating region that exposes the insulating film with the peripheral edge of the trench.

8. The semiconductor device according to claim 7,
wherein the gate pad has a planar area larger than a planar area of the buried resistance.

9. The semiconductor device according to claim 7,
wherein the gate wiring line is formed in a band shape narrower than the buried resistance as viewed in plan.

10. The semiconductor device according to claim 7,
wherein the gate wiring line has two sides that cross the buried resistance in the trench as viewed in plan.

11. The semiconductor device according to claim 6,
wherein the buried resistance has a thickness smaller than a depth of the trench, and is arranged in the trench at a distance from a height position of the main surface toward a bottom wall side of the trench,
the gate pad is connected to the buried resistance in a region on the bottom wall side of the trench with respect to the height position of the main surface, and
the gate wiring line is connected to the buried resistance in the region on the bottom wall side of the trench with respect to the height position of the main surface.

12. The semiconductor device according to claim 11,
wherein the gate pad has a portion that protrudes to a higher position than the main surface.

13. The semiconductor device according to claim 11,
wherein the trench resistance structure includes a buried insulator covering the buried resistance in the trench,
the gate pad is arranged on the buried insulator so as to be electrically connected to the buried resistance through the buried insulator, and
the gate wiring line is arranged on the buried insulator so as to be electrically connected to the buried resistance through the buried insulator.

14. The semiconductor device according to claim 13, further comprising:
an interlayer insulating film that covers the main surface so as to be connected to the buried insulator.

15. The semiconductor device according to claim 1, further comprising:
a dummy trench structure that is formed in the main surface at a distance from the trench resistance structure so as to adjoin the trench resistance structure and to which a potential differing from a potential of the trench resistance structure is given.

16. The semiconductor device according to claim 1, further comprising:
a trench gate structure that is formed in the main surface at a distance from the trench resistance structure so as to adjoin the trench resistance structure;
wherein the gate wiring line is electrically connected to the trench gate structure.

17. The semiconductor device according to claim 16, further comprising:
a trench source structure formed in the main surface so as to adjoin the trench resistance structure and the trench gate structure.

18. The semiconductor device according to claim 1, further comprising:
a first conductivity type semiconductor region formed in a surface layer portion of the main surface;
the trench resistance structure formed in the main surface so as to be located in the semiconductor region; and
a second conductivity type well region formed in a region along the trench resistance structure in the semiconductor region so as to form a p-n junction portion with the semiconductor region.

19. The semiconductor device according to claim 1, further comprising:
a mesa defined in the main surface by a first surface portion formed in an inward portion of the main surface, a second surface portion formed in a peripheral edge portion of the main surface so as to be hollowed in a thickness direction of the chip from the first surface portion, and a connecting surface portion connecting the first surface portion and the second surface portion;
wherein the trench resistance structure is formed in the first surface portion.

20. The semiconductor device according to claim 1, further comprising:
a gate subpad that has a resistance value lower than that of the trench resistance structure and that is arranged on the main surface so as to be electrically connected to the gate pad via the trench resistance structure.
